(19) United States
(12) Patent Application Publication
(10) Pub. No.: US 2025/0081629 A1
(43) Pub. Date: Mar. 6, 2025

(54) METHOD FOR FABRICATING SEMICONDUCTOR DEVICE

(71) Applicant: SEMICONDUCTOR ENERGY LABORATORY CO., LTD., Atsugi-shi (JP)

(72) Inventors: Ryota HODO, Atsugi (JP); Shinya SASAGAWA, Chigasaki (JP); Motomu KURATA, Isehara (JP); Shunpei YAMAZAKI, Tokyo (JP)

(21) Appl. No.: 18/818,925

(22) Filed: Aug. 29, 2024

(30) Foreign Application Priority Data
Sep. 4, 2023 (JP) 2023-143046

(51) Int. Cl. H01L 29/66; H01L 21/02

(52) U.S. Cl. CPC H10D 99/00; H01L 21/02554; H01L 21/02565; H01L 21/0262; H01L 21/02631

(57) ABSTRACT

A semiconductor device that operates at high speed is provided. The semiconductor device is fabricated in the following manner: a first coating film over a first insulator and a second coating film over the first coating film are formed; a first layer is formed by partly removing the second coating film; a second layer is formed by partly removing the first coating film using the first layer as a mask; heat treatment is performed; a first oxide semiconductor is formed to cover a top surface of the first insulator, a side surface of the second layer, and a side surface and a top surface of the first layer; a second oxide semiconductor is formed in contact with the side surface of the second layer by processing the first oxide semiconductor by anisotropic etching; the first layer is removed; and a side surface of the second oxide semiconductor that is covered with the second layer is exposed by removing the second layer.

### BACKGROUND OF THE INVENTION

### 1. Field of the Invention

One embodiment of the present invention relates to a semiconductor device, a memory device, and an electronic device each including an oxide semiconductor layer. One embodiment of the present invention relates to a method for fabricating the semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

In this specification and the like, a semiconductor device generally means a device that can function by utilizing semiconductor characteristics. A semiconductor element such as a transistor, a semiconductor circuit, an arithmetic device, and a memory device are each one mode of a semiconductor device. A display device (e.g., a liquid crystal display device and a light-emitting display device), a projection device, a lighting device, an electro-optical device, a power storage device, a memory device, a semiconductor circuit, an imaging device, an electronic device, and the like may include a semiconductor device.

### 2. Description of the Related Art

In recent years, semiconductor devices have been developed, and LSIs, CPUs, memories, and the like are mainly used in semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an IC and an image display device (also simply referred to as a display device). A silicon-based semiconductor material is widely known as a material of a semiconductor thin film that can be used in a transistor. As another material, an oxide semiconductor has been attracting attention.

It is known that a transistor including an oxide semiconductor has an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

### REFERENCES

### Patent Documents

[Patent Document 1] Japanese Published Patent Application No. 2012-257187
[Patent Document 2] Japanese Published Patent Application No. 2011-151383

### SUMMARY OF THE INVENTION

An object of one embodiment of the present invention is to provide a semiconductor device that operates at high speed. Another object of one embodiment of the present invention is to provide a semiconductor device that can be scaled down or highly integrated. Another object of one embodiment of the present invention is to provide a semiconductor device with excellent electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device. Another object of one embodiment of the present invention is to provide a method for fabricating a semiconductor device that operates at high speed. Another object of one embodiment of the present invention is to provide a method for fabricating a semiconductor device that can be scaled down or highly integrated. Another object of one embodiment of the present invention is to provide a method for fabricating a semiconductor device with excellent electrical characteristics. Another object of one embodiment of the present invention is to provide a method for fabricating a semiconductor device with a small variation in electrical characteristics of transistors. Another object of one embodiment of the present invention is to provide a method for fabricating a highly reliable semiconductor device. Another object of one embodiment of the present invention is to provide a method for fabricating a semiconductor device with a high on-state current. Another object of one embodiment of the present invention is to provide a method for fabricating a semiconductor device with low power consumption. Another object of one embodiment of the present invention is to provide a method for fabricating a semiconductor device with high productivity. Another object of one embodiment of the present invention is to provide a method for fabricating a novel semiconductor device.

Another object of one embodiment of the present invention is to provide a memory device that can be scaled down or highly integrated. Another object of one embodiment of the present invention is to provide a memory device having a high memory capacity. Another object of one embodiment of the present invention is to provide a memory device that operates at high speed. Another object of one embodiment of the present invention is to provide a memory device with low power consumption. Another object of one embodiment of the present invention is to provide a novel memory device.

Note that the description of these objects does not preclude the presence of other objects. One embodiment of the present invention does not necessarily achieve all of these objects. Other objects can be derived from the description of the specification, the drawings, and the claims.

One embodiment of the present invention is a method for fabricating a semiconductor device, in which a first coating film over a first insulator and a second coating film over the first coating film are formed; a first layer is formed by partly removing the second coating film; a second layer is formed by partly removing the first coating film using the first layer as a mask; heat treatment is performed; a first oxide semiconductor is formed to cover a top surface of the first insulator, a side surface of the second layer, and a side surface and a top surface of the first layer; a second oxide semiconductor is formed in contact with the side surface of the second layer by processing the first oxide semiconductor by anisotropic etching; the first layer is removed; and a side surface of the second oxide semiconductor covered with the second layer is exposed by removing the second layer.

In the above embodiment, it is preferable that the first coating film be an organic resin and that the second coating film contain silicon, oxygen, and carbon.

In the above embodiment, it is preferable that the first insulator be partly removed when the first layer is removed.

In the above embodiment, the heat treatment is preferably performed at higher than or equal to 200° C. and lower than or equal to 400° C.

In the above embodiment, the second layer is preferably removed by microwave treatment.

In the above embodiment, it is preferable that the first oxide semiconductor be formed through a step of forming a third oxide semiconductor, a step of forming a fourth oxide semiconductor over the third oxide semiconductor, and a step of forming a fifth oxide semiconductor over the fourth oxide semiconductor, that the third oxide semiconductor and the fifth oxide semiconductor be formed by an ALD method using an oxidizer and a precursor containing indium, and that the fourth oxide semiconductor be formed by a sputtering method using a sputtering target containing zinc.

Another embodiment of the present invention is a method for fabricating a semiconductor device, in which a second insulator is formed over a first insulator; a first coating film over the second insulator and a second coating film over the first coating film are formed; a first layer is formed by partly removing the second coating film; a second layer is formed by partly removing the first coating film using the first layer as a mask; heat treatment is performed; a first oxide semiconductor is formed to cover a top surface of the second insulator, a side surface of the second layer, and a side surface and a top surface of the first layer; a second oxide semiconductor is formed in contact with the side surface of the second layer by processing the first oxide semiconductor by anisotropic etching; the first layer and a region of the second insulator overlapping with neither the second layer nor the second oxide semiconductor are removed; a side surface of the second oxide semiconductor covered with the second layer is exposed by removing the second layer; a first conductor is formed to cover a top surface of the first insulator and a side surface of the second oxide semiconductor; a third insulator is formed over the first conductor; an opening portion is formed in the third insulator by partly removing the third insulator; a region of the first conductor overlapping with the opening portion is removed; a fourth insulator is formed over the third insulator and in the opening portion in the third insulator to cover a side surface of the second oxide semiconductor in the opening portion; and a second conductor is formed over the fourth insulator.

In the above embodiment, it is preferable that the first coating film be an organic resin and that the second coating film contain silicon, oxygen, and carbon.

In the above embodiment, the heat treatment is preferably performed at higher than or equal to 200° C. and lower than or equal to 400° C.

In the above embodiment, the second layer is preferably removed by microwave treatment.

According to one embodiment of the present invention, a semiconductor device that operates at high speed can be provided. According to one embodiment of the present invention, a semiconductor device that can be scaled down or highly integrated can be provided. According to one embodiment of the present invention, a semiconductor device with excellent electrical characteristics can be provided. According to one embodiment of the present invention, a semiconductor device with a small variation in electrical characteristics of transistors can be provided. According to one embodiment of the present invention, a highly reliable semiconductor device can be provided. According to one embodiment of the present invention, a semiconductor device with a high on-state current can be provided. According to one embodiment of the present invention, a semiconductor device with low power consumption can be provided. According to one embodiment of the present invention, a novel semiconductor device can be provided. According to one embodiment of the present invention, a method for fabricating a semiconductor device that operates at high speed can be provided. According to one embodiment of the present invention, a method for fabricating a semiconductor device that can be scaled down or highly integrated can be provided. According to one embodiment of the present invention, a method for fabricating a semiconductor device with excellent electrical characteristics can be provided. According to one embodiment of the present invention, a method for fabricating a semiconductor device with a small variation in electrical characteristics of transistors can be provided. According to one embodiment of the present invention, a method for fabricating a highly reliable semiconductor device can be provided. According to one embodiment of the present invention, a method for fabricating a semiconductor device with a high on-state current can be provided. According to one embodiment of the present invention, a method for fabricating a semiconductor device with low power consumption can be provided. According to one embodiment of the present invention, a method for fabricating a semiconductor device with high productivity can be provided. According to one embodiment of the present invention, a method for fabricating a novel semiconductor device can be provided.

According to one embodiment of the present invention, a memory device that can be scaled down or highly integrated can be provided. According to one embodiment of the present invention, a memory device having a high memory capacity can be provided. According to one embodiment of the present invention, a memory device that operates at high speed can be provided. According to one embodiment of the present invention, a memory device with low power consumption can be provided. According to one embodiment of the present invention, a novel memory device can be provided.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a plan view illustrating an example of a semiconductor device, and FIGS. 1B to 1D are cross-sectional views illustrating the example of the semiconductor device;

FIGS. 2A to 2C are cross-sectional views illustrating examples of a semiconductor device;

FIGS. 3A to 3C are cross-sectional views illustrating examples of a semiconductor device;

FIGS. 4A and 4B are plan views illustrating examples of part of a semiconductor device;

FIG. 5A is a plan view illustrating an example of a semiconductor device, and FIGS. 5B to 5D are cross-sectional views illustrating the example of the semiconductor device;

FIG. 6A is a plan view illustrating an example of a semiconductor device, and FIGS. 6B to 6D are cross-sectional views illustrating the example of the semiconductor device;

FIGS. 7A to 7C are cross-sectional views illustrating examples of a semiconductor device;

FIGS. 8A to 8D are cross-sectional views illustrating an example of a method for forming an oxide semiconductor;

FIGS. 9A to 9D are cross-sectional views illustrating examples of an oxide semiconductor;

FIGS. 10A to 10C are cross-sectional views illustrating examples of part of a semiconductor device;

FIGS. 11A to 11C are cross-sectional views illustrating examples of a semiconductor device;

FIG. 12A is a plan view illustrating an example of a semiconductor device, and FIGS. 12B to 12D are cross-sectional views illustrating the example of the semiconductor device;

FIG. 13A is a plan view illustrating an example of a method for fabricating a semiconductor device, and FIGS. 13B to 13D are cross-sectional views illustrating the example of the method for fabricating the semiconductor device;

FIG. 14A is a plan view illustrating an example of a method for fabricating a semiconductor device, and FIGS. 14B to 14D are cross-sectional views illustrating the example of the method for fabricating the semiconductor device;

FIG. 15A is a plan view illustrating an example of a method for fabricating a semiconductor device, and FIGS. 15B to 15D are cross-sectional views illustrating the example of the method for fabricating the semiconductor device;

FIG. 16A is a plan view illustrating an example of a method for fabricating a semiconductor device, and FIGS. 16B to 16D are cross-sectional views illustrating the example of the method for fabricating the semiconductor device;

FIG. 17A is a plan view illustrating an example of a method for fabricating a semiconductor device, and FIG. 17B is a cross-sectional view illustrating the example of the method for fabricating the semiconductor device;

FIG. 18A is a plan view illustrating an example of a method for fabricating a semiconductor device, and FIGS. 18B to 18D are cross-sectional views illustrating the example of the method for fabricating the semiconductor device;

FIG. 19A is a plan view illustrating an example of a method for fabricating a semiconductor device, and FIGS. 19B to 19D are cross-sectional views illustrating the example of the method for fabricating the semiconductor device;

FIG. 20A is a plan view illustrating an example of a method for fabricating a semiconductor device, and FIGS. 20B to 20D are cross-sectional views illustrating the example of the method for fabricating the semiconductor device;

FIG. 21A is a plan view illustrating an example of a method for fabricating a semiconductor device, and FIGS. 21B to 21D are cross-sectional views illustrating the example of the method for fabricating the semiconductor device;

FIG. 22A is a plan view illustrating an example of a method for fabricating a semiconductor device, and FIGS. 22B to 22D are cross-sectional views illustrating the example of the method for fabricating the semiconductor device;

FIG. 23A is a plan view illustrating an example of a method for fabricating a semiconductor device, and FIGS. 23B to 23D are cross-sectional views illustrating the example of the method for fabricating the semiconductor device;

FIG. 24A is a plan view illustrating an example of a method for fabricating a semiconductor device, and FIGS. 24B to 24D are cross-sectional views illustrating the example of the method for fabricating the semiconductor device;

FIG. 25A is a plan view illustrating an example of a method for fabricating a semiconductor device, and FIGS. 25B to 25D are cross-sectional views illustrating the example of the method for fabricating the semiconductor device;

FIG. 26A is a plan view illustrating an example of a method for fabricating a semiconductor device, and FIGS. 26B to 26D are cross-sectional views illustrating the example of the method for fabricating the semiconductor device;

FIG. 27A is a plan view illustrating an example of a method for fabricating a semiconductor device, and FIGS. 27B to 27D are cross-sectional views illustrating the example of the method for fabricating the semiconductor device;

FIG. 28A is a plan view illustrating an example of a method for fabricating a semiconductor device, and FIGS. 28B to 28D are cross-sectional views illustrating the example of the method for fabricating the semiconductor device;

FIG. 29 is a cross-sectional view illustrating an example of a semiconductor device;

FIGS. 30A to 30C are cross-sectional views illustrating an example of a semiconductor device;

FIGS. 31A and 31B are cross-sectional views illustrating examples of a semiconductor device;

FIG. 32 is a block diagram illustrating a structure example of a semiconductor device;

FIGS. 33A to 33H illustrate circuit structure examples of memory cells;

FIGS. 34A and 34B are perspective views illustrating structure examples of a semiconductor device;

FIG. 35 is a block diagram illustrating a CPU;

FIG. 36 is a block diagram illustrating a CPU;

FIGS. 37A and 37B are perspective views of a semiconductor device;

FIGS. 38A and 38B are perspective views of semiconductor devices;

FIGS. 39A and 39B show hierarchies of memory devices used for a semiconductor device;

FIGS. 40A and 40B illustrate examples of electronic devices, and FIGS. 40C to 40E illustrate an example of a large computer;

FIG. 41 illustrates an example of space equipment; and

FIG. 42 illustrates an example of a storage system that can be used in a data center.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Especially in a plan view (also referred to as a top view), a perspective view, or the like, some components might not be illustrated for easy understanding of the invention. In addition, some hidden lines might not be shown.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

Note that the terms “film” and “layer” can be used interchangeably depending on the case or the circumstances. For example, the term “conductive layer” can be replaced with the term “conductive film”. For another example, the term “insulating film” can be replaced with the term “insulating layer”. The term “conductor” can be replaced with the term “conductive layer” or “conductive film” depending on the case or the circumstances. The term “insulator” can be replaced with the term “insulating layer” or “insulating film” depending on the case or the circumstances.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 950 is also included. The term “substantially perpendicular” indicates that the angle formed between two straight lines is greater than or equal to 700 and less than or equal to 110°.

Examples of an opening include a groove and a slit. A region where the opening is formed may be referred to as an opening portion.

In the drawings used in this specification and the like, a sidewall of an insulator in an opening portion is perpendicular or substantially perpendicular to a substrate surface or a formation surface, but the sidewall may have a tapered shape.

In this specification and the like, a tapered shape refers to a shape such that at least part of a side surface of a component is inclined with respect to a substrate surface or a formation surface. For example, a tapered shape preferably includes a region where the angle between the inclined side surface and the substrate surface or the formation surface (hereinafter, such an angle is referred to as a taper angle in some cases) is less than 90°. Note that the side surface of the component and the substrate surface are not necessarily completely flat and may be substantially flat with a slight curvature or with slight unevenness.

In this specification and the like, the expression “level or substantially level with” indicates a structure having the same level from a reference surface (e.g., a flat surface such as a substrate surface) in a cross-sectional view. For example, in a manufacturing process of a memory device, planarization treatment (typically, CMP treatment) is performed, whereby the surface(s) of a single layer or a plurality of layers may be exposed. In that case, the surfaces on which the CMP treatment is performed are at the same level from a reference surface. Note that a plurality of layers may be on different levels depending on a treatment apparatus, a treatment method, or a material of the treated surfaces, used for the CMP treatment. This case is also included in the scope of “level or substantially level with” in this specification and the like. For example, the expression “level or substantially level with” also includes the case where two layers (here, a first layer and a second layer) have different levels with respect to a reference surface and the difference in the top-surface level between the first and second layers is less than or equal to 20 nm.

In this specification and the like, the expression “a side end portion is aligned or substantially aligned with another side end portion” indicates that at least outlines of stacked layers partly overlap with each other in a plan view. For example, the case of patterning or partly patterning an upper layer and a lower layer with the use of the same mask pattern is included. The expression “a side end portion is aligned or substantially aligned with another side end portion” also includes the case where the outlines do not completely overlap with each other; for instance, the outline of the upper layer may be positioned inward or outward from the outline of the lower layer.

### Embodiment 1

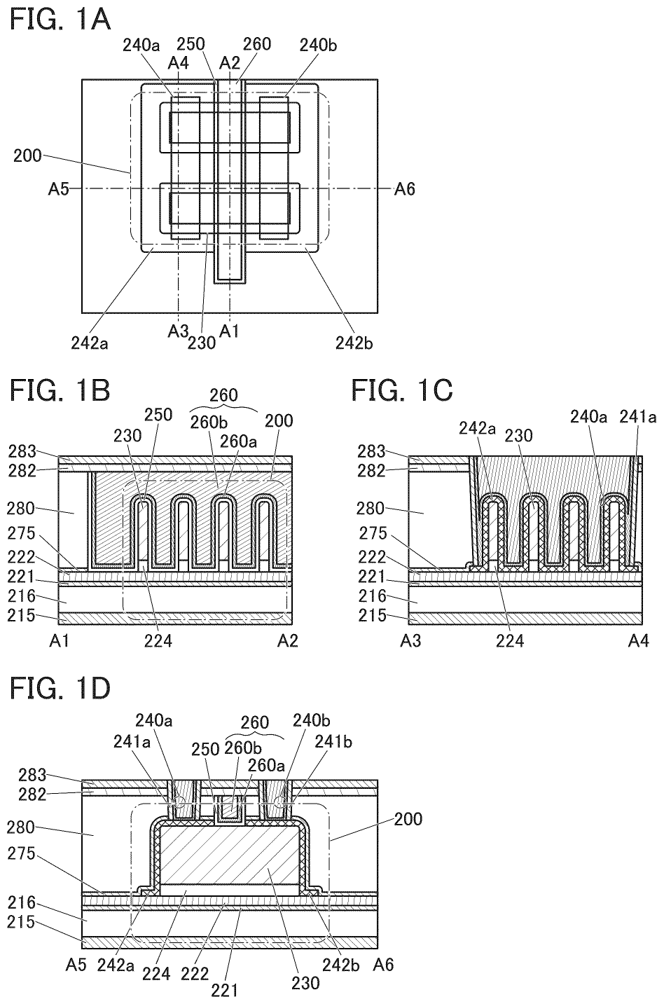

In this embodiment, a semiconductor device including an oxide semiconductor layer and a method for fabricating the semiconductor device will be described with reference to FIGS. 1A to 1D to FIGS. 31A and 31B.

### Structure Example 1 of Semiconductor Device

Structure examples of a semiconductor device will be described with reference to FIGS. 1A to 1D to FIGS. 11A to 11C. FIGS. 1A to 1D are a plan view and cross-sectional views of a semiconductor device including a transistor 200 over a substrate (not illustrated).

FIG. 1A is the plan view of the semiconductor device. FIGS. 1B to 1D are the cross-sectional views of the semiconductor device. FIG. 1B is a cross-sectional view taken along the dashed-dotted line A1-A2 in FIG. 1A, which corresponds to a cross-sectional view of the transistor 200 in the channel width direction. FIG. 1C is a cross-sectional view taken along the dashed-dotted line A3-A4 in FIG. 1A, which corresponds to a cross-sectional view of the transistor 200 in the channel width direction. FIG. 1D is a cross-sectional view taken along the dashed-dotted line A5-A6 in FIG. 1A, which corresponds to a cross-sectional view of the transistor 200 in the channel length direction. The dashed-dotted line A5-A6 is orthogonal to the dashed-dotted line A1-A2 and the dashed-dotted line A3-A4, and the dashed-dotted line A1-A2 is parallel to the dashed-dotted line A3-A4. Note that for simplification of the drawing, some components are not illustrated and other components are illustrated in a see-through manner in the plan view of FIG. 1A.

The semiconductor device of this embodiment includes an insulator 216 over the substrate (not illustrated), an insulator 221 over the insulator 216, an insulator 222 over the insulator 221, an insulator 224 over the insulator 222, an oxide semiconductor 230 over the insulator 224, a conductor 242a and a conductor 242b over the oxide semiconductor 230 and the insulator 224, an insulator 250 over the oxide semiconductor 230, and a conductor 260 (a conductor 260a and a conductor 260b) over the insulator 250. Hereinafter, the conductor 242a and the conductor 242b are sometimes collectively referred to as a conductor 242.

An insulator 275 is provided over the conductor 242, and an insulator 280 is provided over the insulator 275. The insulator 250 and the conductor 260 are provided in an opening formed in the insulator 280 and the insulator 275. The opening reaches the oxide semiconductor 230, and the insulator 250 is in contact with the oxide semiconductor 230 in the opening. An insulator 282 is provided over the insulator 280 and the conductor 260. An insulator 283 is provided over the insulator 282. An insulator 215 is provided under the insulator 216.

An insulator 241a is provided in contact with an inner wall of an opening in the insulator 280 and the like, and a conductor 240a is provided in contact with the side surface of the insulator 241a. The bottom surface of the conductor 240a is in contact with the top surface of the conductor 242a. An insulator 241b is provided in contact with an inner wall of an opening in the insulator 280 and the like, and a conductor 240b is provided in contact with the side surface of the insulator 241b. The bottom surface of the conductor 240b is in contact with the top surface of the conductor 242b. Hereinafter, the conductor 240a and the conductor 240b are sometimes collectively referred to as a conductor 240. In addition, the insulator 241a and the insulator 241b are sometimes collectively referred to as an insulator 241.

The oxide semiconductor 230 includes a region functioning as a channel formation region of the transistor 200. The conductor 260 includes a region functioning as a first gate electrode (an upper gate electrode) of the transistor 200. The insulator 250 includes a region functioning as a first gate insulator of the transistor 200.

The conductor 242a includes a region functioning as one of a source electrode and a drain electrode of the transistor 200. The conductor 240a functions as a plug connected to the conductor 242a. The conductor 242b includes a region functioning as the other of the source electrode and the drain electrode of the transistor 200. The conductor 240b functions as a plug connected to the conductor 242b.

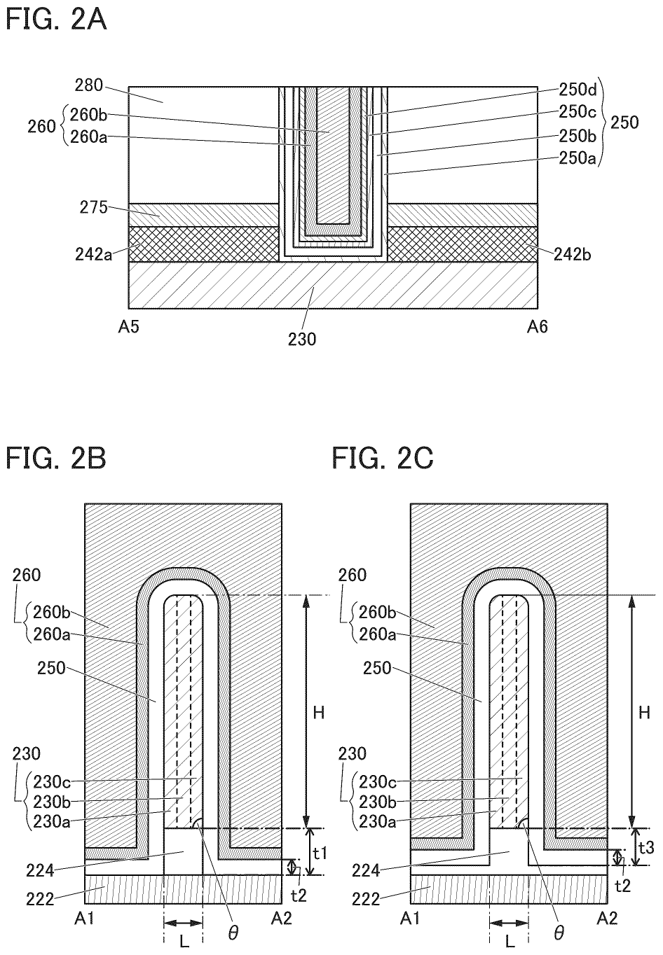

FIG. 2A is an enlarged view of the conductor 260 in FIG. 1D and its vicinity. FIG. 2A illustrates an example in which the insulator 250 includes an insulator 250a, an insulator 250b, an insulator 250c, and an insulator 250d. The details of the insulator 250a, the insulator 250b, the insulator 250c, and the insulator 250d will be described later.

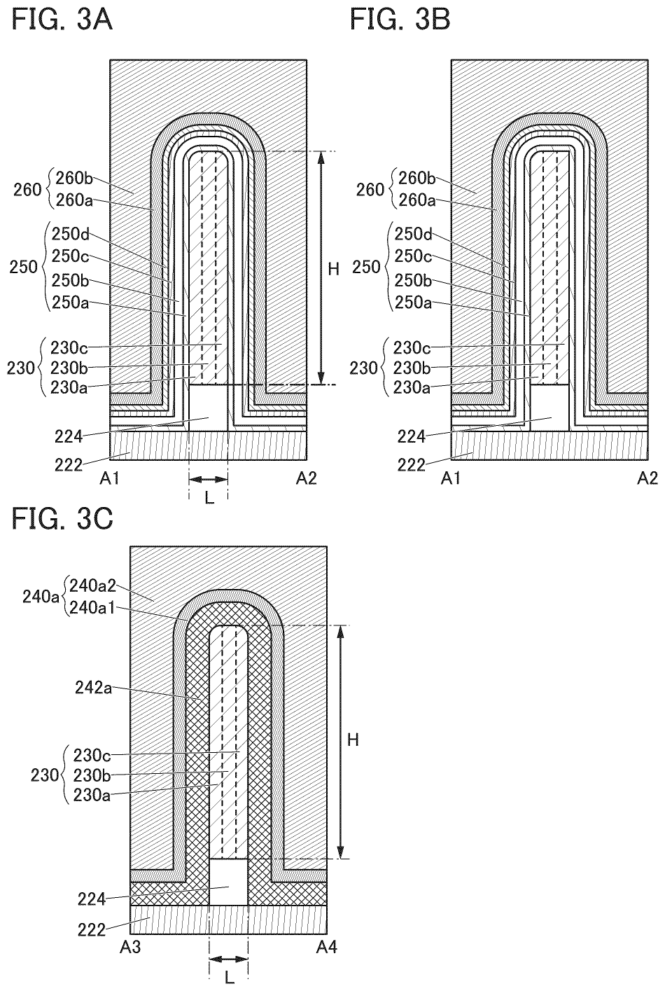

FIG. 2B and FIG. 3A are enlarged views of the oxide semiconductor 230 in FIG. 1B and its vicinity. FIG. 2B and FIG. 3A illustrate an example in which the oxide semiconductor 230 includes an oxide semiconductor 230a, an oxide semiconductor 230b, and an oxide semiconductor 230c. FIG. 3A also illustrates an example in which the insulator 250 includes the insulator 250a, the insulator 250b, the insulator 250c, and the insulator 250d.

FIG. 3C is an enlarged view of the oxide semiconductor 230 in FIG. 1C and its vicinity. FIG. 3C illustrates an example in which the oxide semiconductor 230 includes the oxide semiconductor 230a, the oxide semiconductor 230b, and the oxide semiconductor 230c. FIG. 3C also illustrates an example in which the conductor 240a includes a conductor 240al and a conductor 240a2. The conductor 260, the conductor 240a, the conductor 240b, the conductor 242a, the conductor 242b, and the like each preferably have a stacked-layer structure. The details of the stacked-layer structures of the conductors will be described later.

The oxide semiconductor 230 is formed on the top surface of the insulator 224. As illustrated in FIG. 2B and FIGS. 3A and 3C, the oxide semiconductor 230 has a shape with a high aspect ratio in a cross-sectional view in the channel width direction. Thus, the oxide semiconductor 230 can be regarded as having a fin shape.

Note that the aspect ratio of the oxide semiconductor 230 in a cross-sectional view in the channel width direction refers to the ratio of a length H (also referred to as a height H) of the oxide semiconductor 230 in a direction perpendicular to the formation surface of the oxide semiconductor 230 (e.g., the insulator 224) to a length L (also referred to as a width L) of the oxide semiconductor 230 in the A1-A2 direction. The aspect ratio of the oxide semiconductor 230 is preferably as high as possible unless the oxide semiconductor 230 collapses in the fabrication process of the transistor 200. The height H of the oxide semiconductor 230 is greater than at least the width L of the oxide semiconductor 230. The height H of the oxide semiconductor 230 is greater than 1 time and less than or equal to 400 times, preferably greater than or equal to 2 times and less than or equal to 100 times, further preferably greater than or equal to 5 times and less than or equal to 40 times, still further preferably greater than or equal to 10 times and less than or equal to 20 times the width L of the oxide semiconductor 230. For example, the height H may be greater than or equal to 2 times and less than or equal to 10 times the width L. The width L is, for example, greater than or equal to 5 nm and less than or equal to 100 nm, preferably greater than or equal to 5 nm and less than or equal to 50 nm, further preferably greater than or equal to 10 nm and less than or equal to 30 nm. The height H is, for example, greater than or equal to 50 nm and less than or equal to 2000 nm, preferably greater than or equal to 100 nm and less than or equal to 1000 nm. For another example, the height H may be greater than or equal to 50 nm and less than or equal to 100 nm.

As illustrated in FIG. 2B, it is preferable that the side surface of the oxide semiconductor 230 be perpendicular or substantially perpendicular to the top surface of the insulator 224 in a cross-sectional view in the channel width direction. The angle formed by the side surface of the oxide semiconductor 230 and the top surface of the insulator 224 is referred to as an angle θ. For example, the angle θ is preferably greater than or equal to 80° and less than or equal to 100°, further preferably greater than or equal to 85° and less than or equal to 95°.

The insulator 250, the conductor 260, and the conductor 242 are provided to cover the oxide semiconductor 230 having such a high aspect ratio. The insulator 250 and the conductor 260 are provided in the transistor 200 such that part of each of the insulator 250 and the conductor 260 is folded in half to sandwich the oxide semiconductor 230, as illustrated in FIG. 1B, FIG. 2B, and FIG. 3A. Thus, in a cross-sectional view in the channel width direction, the oxide semiconductor 230 and the conductor 260 face each other with the insulator 250 therebetween in the upper portion, the side surface on the A1 side, and the side surface on the A2 side of the oxide semiconductor 230. That is, the upper portion, the side surface on the A1 side, and the side surface on the A2 side of the oxide semiconductor 230 function as a channel formation region. Accordingly, the channel width of the transistor 200 is greater than that in the case where the oxide semiconductor 230 has a flat-plate shape by the side surface on the A1 side and the side surface on the A2 side of the oxide semiconductor 230.

The transistor 200 having such a large channel width can have a high on-state current, high mutual conductance, excellent frequency characteristics, and the like. Thus, a semiconductor device that operates at high speed can be provided. In addition, the operating speed of a memory device including the semiconductor device can be increased. In the above structure, providing the oxide semiconductor 230 enables the channel width to be increased without an increase in the area occupied by the transistor 200. Accordingly, scaling down or high integration of the semiconductor device can be achieved. Moreover, the memory capacity of the memory device including the semiconductor device can be increased. With the above structure, the area where the conductor 260 and the oxide semiconductor 230 face each other is increased, so that the transistor 200 can be normally off by control of the threshold value.

The upper portion of the oxide semiconductor 230 preferably has a curved shape as illustrated in FIG. 2B, FIG. 3A, and the like. Such a curved shape can prevent formation of a defect such as a void in the insulator 250 and the conductor 242 in the vicinity of the upper portion of the oxide semiconductor 230. Although the upper portion of the oxide semiconductor 230 has a symmetrical structure in which both the A1 side (A3 side) and the A2 side (A4 side) of the upper portion of the oxide semiconductor 230 have a curved shape in FIG. 2B, FIG. 3A, and the like, the present invention is not limited thereto. For example, the upper portion of the oxide semiconductor 230 sometimes has an asymmetrical structure in which one of the A1 side (A3 side) and the A2 side (A4 side) of the upper portion of the oxide semiconductor 230 has a curved shape. The structure example illustrated in FIG. 3B differs from that in FIG. 3A mainly in that one of the A1 side and the A2 side (here, the A1 side) of the upper portion of the oxide semiconductor 230 has a curved shape.

In one embodiment of the present invention, the oxide semiconductor 230 is formed to have a sidewall shape on the side surface of a pillar. This enables formation of the oxide semiconductor having a high aspect ratio.

After the formation of the oxide semiconductor 230, the pillar used for forming the oxide semiconductor 230 is removed. The pillar can be removed by dry etching, ashing, plasma treatment, wet etching, or the like.

In the treatment for removing the pillar, the etching selectivity with respect to the oxide semiconductor 230 is preferably high. High etching selectivity here refers to a state where the etching rate of the pillar is higher than that of the oxide semiconductor 230 in the etching treatment for removing the pillar. Adequately high selectivity can inhibit the oxide semiconductor 230 from partly or entirely disappearing in the removal of the pillar.

The treatment for removing the pillar preferably causes minimal damage to the oxide semiconductor 230. For example, dry etching sometimes causes plasma damage to the oxide semiconductor 230. In addition, in the removal of the pillar, the amount of a reaction product generated by etching and deposited on the surface of the oxide semiconductor 230 is preferably small. Damage to the surface of the oxide semiconductor 230, deposition of a reaction product on the surface of the oxide semiconductor 230, and the like might degrade the characteristics and reliability of a semiconductor element such as a transistor that includes the oxide semiconductor 230.

In view of the above, the pillar is preferably removed with a small influence on the oxide semiconductor 230 through a simple step.

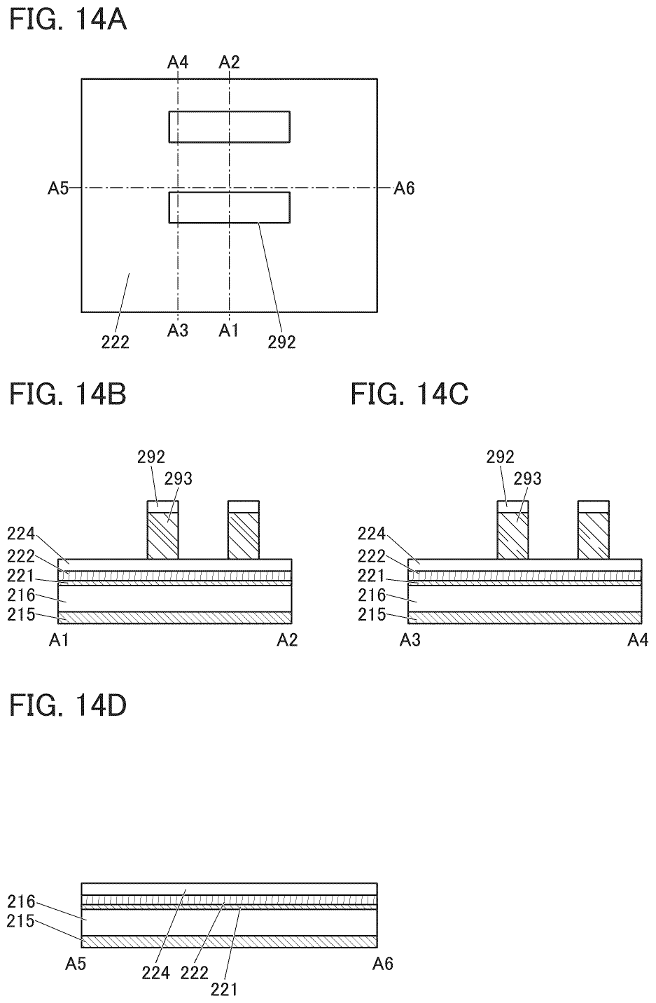

In one embodiment of the present invention, a stack of a layer 293 and a layer 292 over the layer 293 described later with reference to FIGS. 14B and 14C and the like is used as the pillar, so that damage to the oxide semiconductor 230 in the step of removing the pillar can be reduced.

The layer 293 is a layer containing carbon, for example. A non-photosensitive organic resin can be used for the layer 293. In one embodiment of the present invention, spin-on carbon (SOC) is preferably used for the layer 293.

The layer 292 is a layer containing silicon and carbon, for example. For another example, the layer 292 is a layer containing silicon and oxygen. A layer including a polymer containing silicon and oxygen can be used as the layer 292. The layer 292 preferably contains carbon in addition to silicon and oxygen. In one embodiment of the present invention, spin-on glass (SOG) is preferably used for the layer 292. A non-photosensitive organic resin can be used for the layer 292.

The layer 292 can function as a mask at the time of processing the layer 293. The formation of the layer 292 over the layer 293 facilitates the formation of the layer 293 with a fine pattern.

The layer 293 is a layer containing carbon, and an organic resin or the like can be used for the layer 293. A layer formed using an organic resin or the like is more likely to be damaged by plasma treatment or the like than an inorganic insulating layer in some cases. Thus, the oxide semiconductor 230 is preferably formed by a method that causes minimal damage. For example, the oxide semiconductor 230 is preferably formed by an ALD method. In the case where the oxide semiconductor 230 has a stacked-layer structure, it is preferable that at least one layer, preferably a layer in contact with the pillar (the layer 293 and the layer 292), be formed by an ALD method.

An ALD method offers excellent coverage. Thus, a film can be suitably formed on the sidewall of the pillar having a high aspect ratio.

When the oxide semiconductor 230 is formed in contact with the side surfaces of a plurality of pillars to have a sidewall shape, a plurality of fin-shaped regions can be formed concurrently in the oxide semiconductor 230 illustrated in FIG. 1A. When the plurality of fin-shaped regions are formed in this manner, the distances between the fin-shaped regions can be independently set in accordance with the sizes and shapes of the pillars. This can reduce the distances between the fin-shaped regions, leading to a reduction in the area occupied by the transistor 200 and high integration of the semiconductor device.

Since the oxide semiconductor 230 is formed in contact with the pillar to have a sidewall shape, the top surface shape of the oxide semiconductor 230 is an enclosing shape with no endpoints (which can also be referred to as a frame shape, a ring shape, a doughnut shape, or a closed-curve shape) as illustrated in FIG. 1A. The oxide semiconductor 230 can also be regarded as having an opening in the center portion. Although the top surface shape of the oxide semiconductor 230 is a line-symmetrical shape with respect to the line A1-A2 in FIG. 1A, the present invention is not limited thereto. For example, the top surface shape of the oxide semiconductor 230 may be an asymmetrical shape.

In the structure illustrated in FIG. 1A, two pillars are arranged in the A1-A2 direction and the enclosing-shaped oxide semiconductor 230 is formed in contact with the side surface of each of the pillars. As illustrated in FIG. 1A, the oxide semiconductor 230 preferably overlaps with the conductor 260 at two or more points in a top view. That is, there are two or more regions where the oxide semiconductor 230 and the conductor 260 overlap with each other. With such a structure, the plurality of fin-shaped regions are formed in the oxide semiconductor 230 in a cross-sectional view in the channel width direction as illustrated in FIG. 1B. The plurality of fin-shaped regions each function as a channel formation region. That is, the transistor 200 functions as a multi-channel transistor. Thus, the transistor 200 can have a larger channel width.

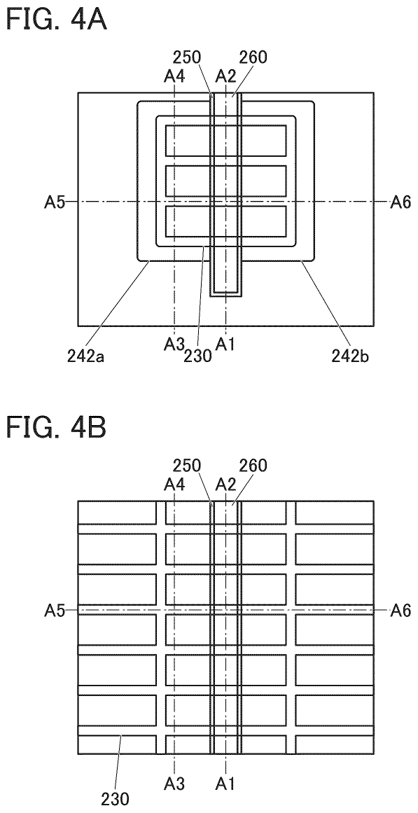

Although the structure in which the two enclosing-shaped oxide semiconductors 230 are provided is described above, the present invention is not limited thereto. For example, one or three or more enclosing-shaped oxide semiconductors 230 may be provided. Alternatively, the enclosing-shaped oxide semiconductors 230 may be bonded to each other to form the oxide semiconductor 230 having a plurality of openings. For example, as illustrated in FIG. 4A, the oxide semiconductor 230 can have a shape in which three openings are arranged in the A1-A2 direction in a top view. In that case, three pillars are formed to be adjacent to each other at a short distance, and the oxide semiconductor 230 is formed between the pillars. For another example, as illustrated in FIG. 4B, the oxide semiconductor 230 can have a lattice shape in a top view. In that case, a lattice-shaped trench is formed in the pillar, and the oxide semiconductor 230 is formed to fill the trench. Note that the number of oxide semiconductors 230 is not limited to two and can be one or three or more. As described above, the oxide semiconductor 230 preferably has a plurality of portions extending in the channel width direction (A1-A2 direction) and a plurality of portions extending in the channel length direction (A5-A6 direction). This can inhibit the oxide semiconductor 230 from collapsing during the fabrication process of the transistor even when the oxide semiconductor 230 has a high aspect ratio.

In the semiconductor device illustrated in FIGS. 1A to 1D, the top surface shape of the insulator 224 is similar to that of the oxide semiconductor 230, and the insulator 224 overlaps with the oxide semiconductor 230 in a top view. The bottom surface of the insulator 224 is in contact with the insulator 222, the side surface of the insulator 224 is in contact with the insulator 250 and the conductor 242a, and the top surface of the insulator 224 is in contact with the bottom surface of the oxide semiconductor 230.

As illustrated in FIG. 2B, a thickness t2 of the insulator 250 in the opening in the insulator 280 and the insulator 275 is preferably smaller than a thickness t1 of the insulator 224. With such a structure, the level of the bottom surface of the conductor 260 (the conductor 260a) positioned in the opening can be lower than the level of the bottom surface of the oxide semiconductor 230 by a difference between the thickness t1 and the thickness t2 (t1−t2). A change in the thickness t1 of the insulator 224 can change the level difference between the bottom surface of the conductor 260 and the bottom surface of the oxide semiconductor 230.

When the level of the bottom surface of the conductor 260 is lower than the level of the bottom surface of the oxide semiconductor 230, a gate electric field can be adequately applied to the oxide semiconductor 230 from its upper end portion to its lower end portion. In other words, in the opening in the insulator 280 and the like, the entire oxide semiconductor 230 can be electrically surrounded by the electric field of the conductor 260 to function as a channel formation region. Such a structure can prevent the lower end portion of the oxide semiconductor 230 from functioning as a parasitic channel, thereby reducing leakage current between the source electrode and the drain electrode. In addition, poor characteristics of the transistor due to the parasitic channel, such as normally-on characteristics, can be inhibited. That is, the transistor 200 can have excellent electrical characteristics.

When a region from the upper end portion to the lower end portion of the oxide semiconductor 230 functions as a channel formation region as described above, the channel width can be increased. Thus, the transistor 200 can have a high on-state current, high mutual conductance, excellent frequency characteristics, and the like.

In this specification and the like, a transistor structure in which a channel formation region is electrically surrounded by the electric field of a gate electrode as in the above structure is referred to as a surrounded channel (S-channel) structure. In the S-channel structure, a gate electrode is provided to cover at least two surfaces (specifically, two surfaces, three surfaces, four surfaces, or the like) of a channel. With the use of the S-channel structure, a transistor with high resistance to a short-channel effect, i.e., a transistor in which a short-channel effect is unlikely to occur, can be obtained.

Since the S-channel structure is a structure with the electrically surrounded channel formation region, the S-channel structure is, in a sense, equivalent to a gate all around (GAA) structure or a lateral gate all around (LGAA) structure. When the transistor 200 has any of the S-channel structure, the GAA structure, and the LGAA structure, the channel formation region formed at the interface between the oxide semiconductor 230 and the gate insulator or in the vicinity thereof can correspond to the whole bulk of the oxide semiconductor 230. Consequently, the density of current flowing through the transistor can be improved, so that the on-state current or the field-effect mobility of the transistor can be increased. In one embodiment of the present invention, the oxide semiconductor 230 has a CAAC structure and a fin shape. In the CAAC structure, the a-b plane is parallel or substantially parallel to the channel length direction. With this structure, a path of current flowing between the source and the drain of the transistor can be parallel to the a-b plane of the CAAC structure. In other words, the oxide semiconductor having the CAAC structure and the fin shape has a conduction path equivalent to that of a two-dimensional semiconductor material. With the use of such an oxide semiconductor for a semiconductor layer of a transistor, a device having two-dimensional conduction can be fabricated.

Although FIGS. 1B to 1D, FIG. 2B, FIG. 3A, and the like illustrate an example in which the top surface shape of the insulator 224 is similar to that of the oxide semiconductor 230, the insulator 224 may have a projection whose top surface shape is similar to that of the oxide semiconductor 230 as illustrated in FIG. 2C. FIG. 2C illustrates a modification example of FIG. 2B and differs from FIG. 2B in the shape of the insulator 224. In the above case, the thickness t2 of the insulator 250 in the opening in the insulator 280 and the insulator 275 is preferably less than a height t3 of the projection of the insulator 224. With such a structure, the level of the bottom surface of the conductor 260 (the conductor 260a) positioned in the opening can be lower than the level of the bottom surface of the oxide semiconductor 230 by a difference between the height t3 and the thickness t2 (t3−t2).

In etching treatment for the insulator 224, the etching rate of the insulator 224 is preferably higher than that of the insulator 222. When the etching rate of the insulator 224 is adequately higher than that of the insulator 222 (i.e., the etching rate of the insulator 222 is adequately lower than that of the insulator 224), the insulator 222 is processed not to have a top surface shape similar to that of the oxide semiconductor 230. Note that a projection with a small step due to overetching of the insulator 224 is sometimes formed in the insulator 222. The projection has a top surface shape similar to that of the oxide semiconductor 230.

In one embodiment of the present invention, the pillar used for processing the oxide semiconductor 230 is preferably removed after the processing of the oxide semiconductor 230. In the etching treatment for removing the pillar, part of the insulator 224 can be processed while the pillar is removed.

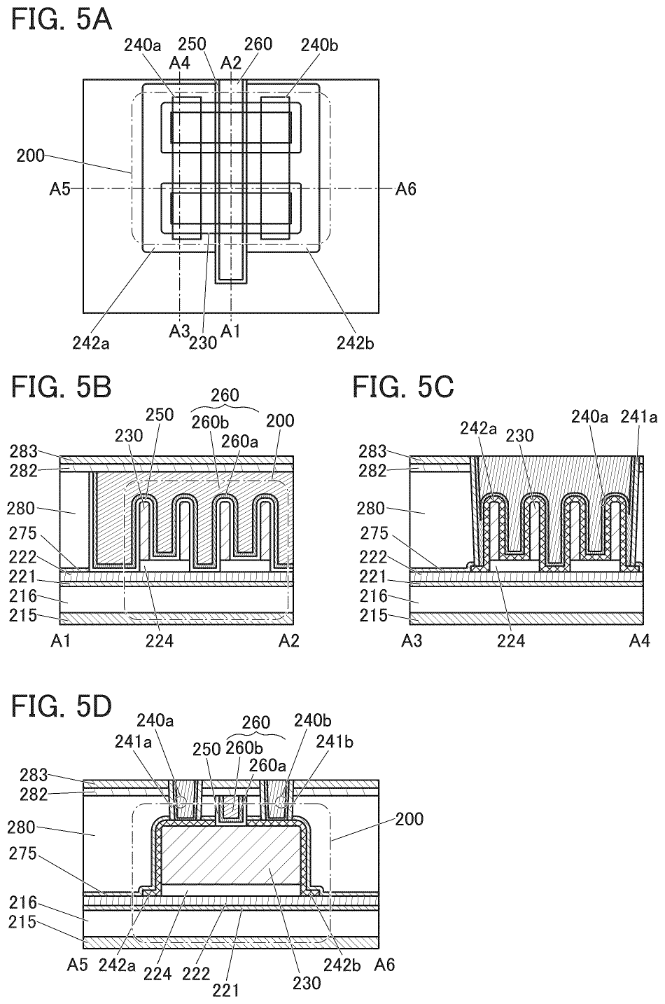

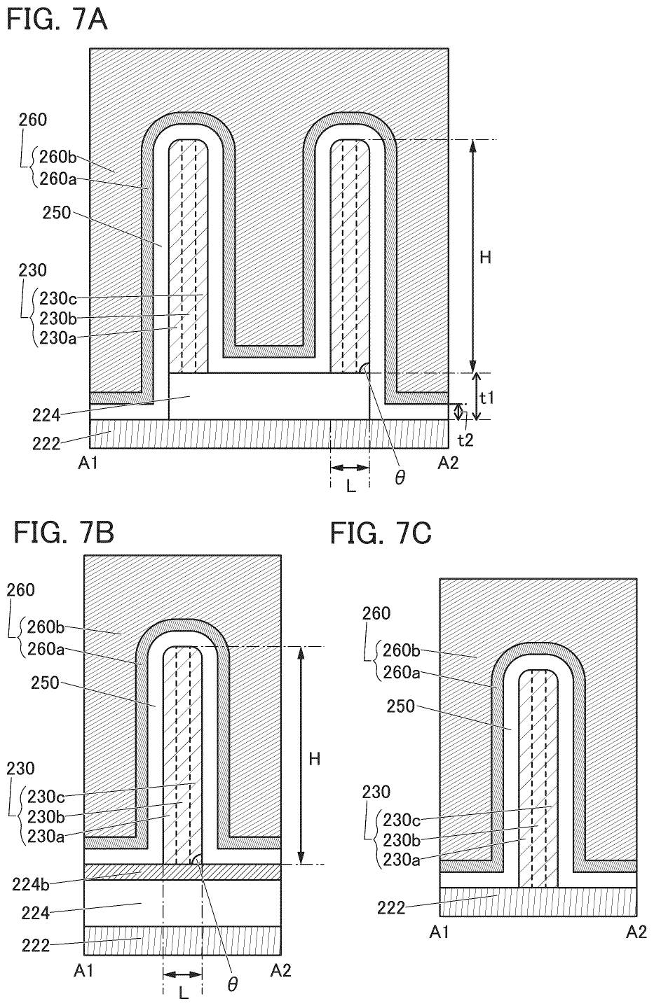

The shape of the insulator 224 may be different from that of the oxide semiconductor 230. FIGS. 5A to 5D illustrate a structure example of the semiconductor device that is different from the structure example in FIGS. 1A to 1D in the shape of the insulator 224. FIG. 7A is an enlarged view of the oxide semiconductor 230 in FIG. 5B and its vicinity. In FIGS. 5A to 5D, the oxide semiconductor 230 has an enclosing shape and has an opening in the center portion in a top view, whereas the insulator 224 does not have an opening in the center portion and has a plate shape (also referred to as an island shape). In the structure illustrated in FIGS. 5A to 5D, the outer circumferential shape of the oxide semiconductor 230 is substantially the same as the top surface shape of the insulator 224. The insulator 250 includes a region in contact with the top surface of the insulator 224.

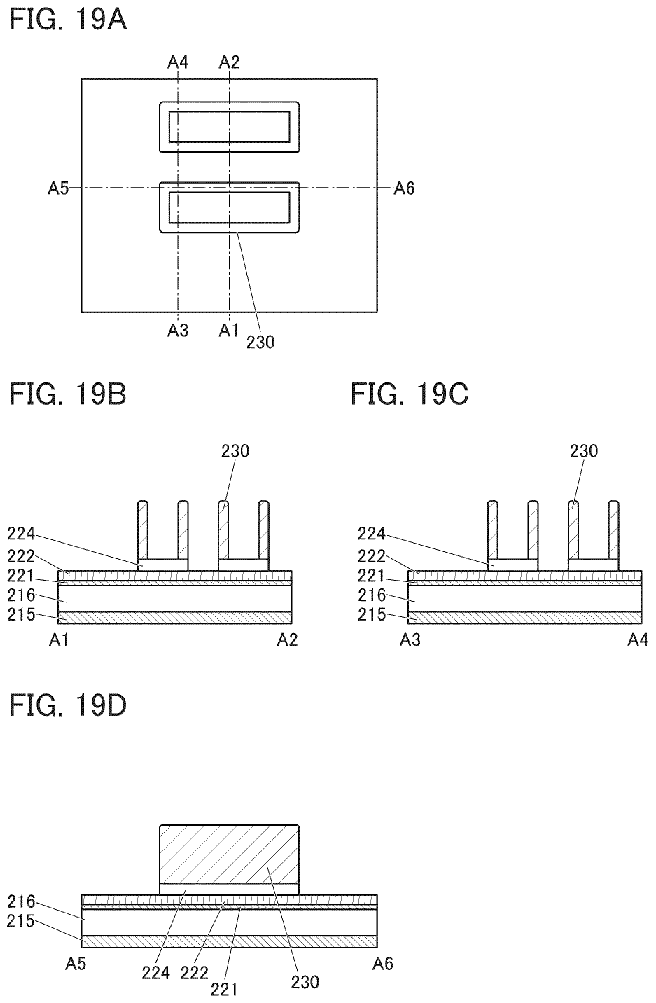

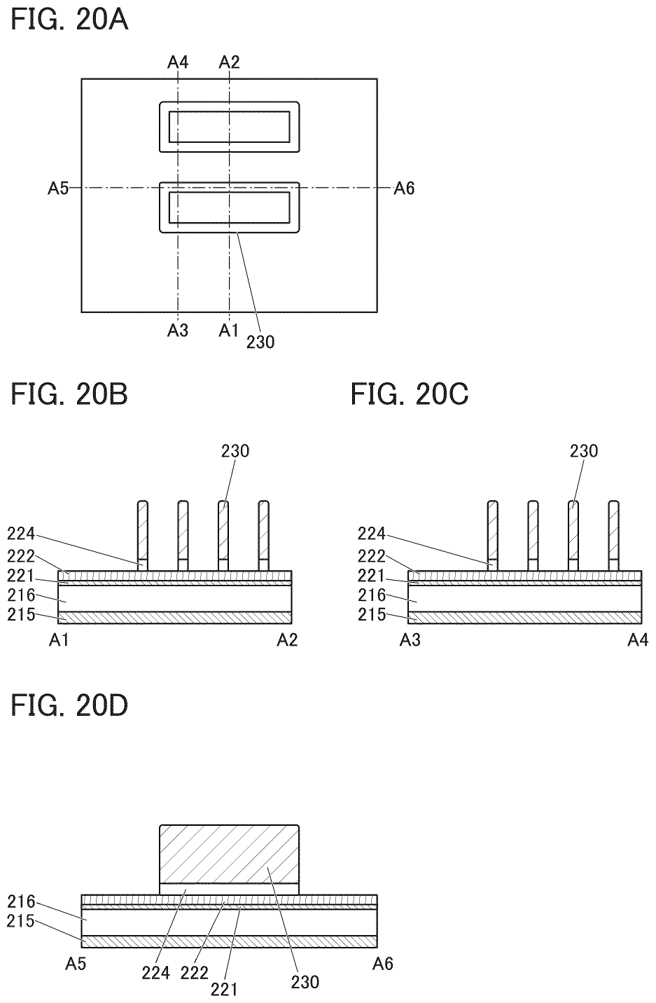

The structure illustrated in FIGS. 5A to 5D is formed by not performing a formation step described later with reference to FIGS. 20A to 20D after a formation step illustrated in FIGS. 19A to 19D. The structure illustrated in FIGS. 5A to 5D can be formed through a smaller number of steps. A reduction in the number of steps sometimes improves the yield and reliability of the semiconductor device.

Meanwhile, in the structure illustrated in FIGS. 5A to 5D, a gate electric field is applied more easily to the lower end portion of the outer side surface than to that of the inner side surface of the enclosing-shaped oxide semiconductor 230. That is, a gate electric field is applied to the outer side surface and the inner side surface of the enclosing-shaped oxide semiconductor 230 in different manners. Thus, the lower end portion of the oxide semiconductor 230 might have a region to which a gate electric field is not adequately applied. Since a gate electric field is applied to the lower end portions of both the outer side surface and the inner side surface of the enclosing-shaped oxide semiconductor 230 more easily in the structure illustrated in FIGS. 1A to 1D than in the structure illustrated in FIGS. 5A to 5D, the structure illustrated in FIGS. 1A to 1D probably offers a higher on-state current than the structure illustrated in FIGS. 5A to 5D.

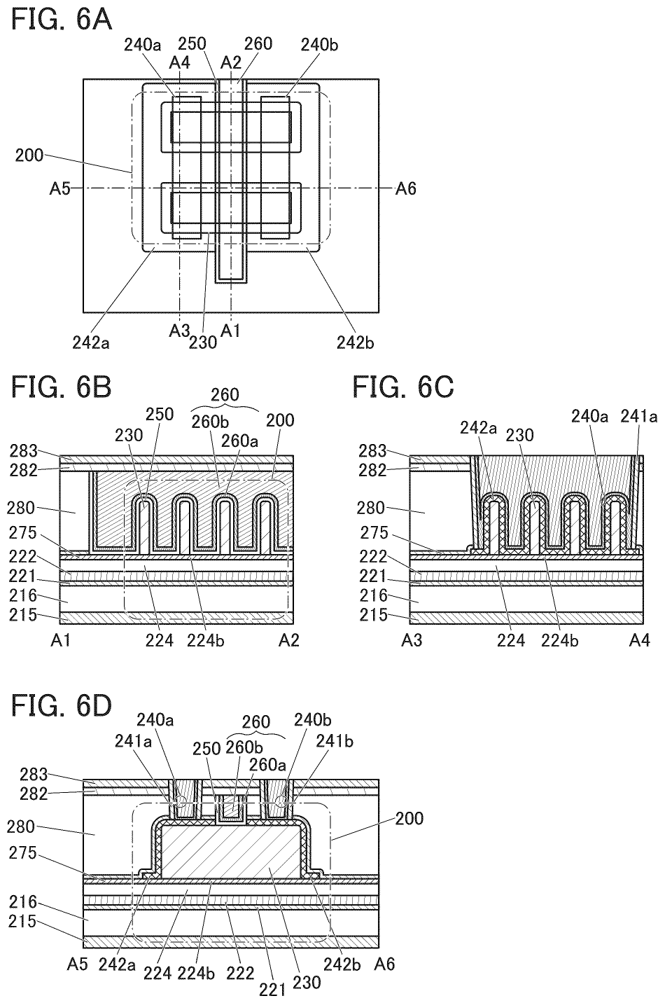

The semiconductor device of one embodiment of the present invention can have a structure illustrated in FIGS. 6A to 6D in which the insulator under the oxide semiconductor 230 has neither a projection nor a top surface shape similar to that of the oxide semiconductor 230.

The semiconductor device illustrated in FIGS. 6A to 6D differs from that in FIGS. 1A to 1D mainly in including an insulator 224b under the oxide semiconductor 230.

The etching rate of the insulator 224b is preferably adequately low in the etching treatment for processing the oxide semiconductor 230 and the etching treatment for removing the pillar. Thus, the insulator 224b and the insulator 224 are processed not to have top surface shapes similar to that of the oxide semiconductor 230. FIGS. 6A to 6D correspond to FIGS. 1A to 1D; thus, refer to the above description for the detailed structure. FIG. 7B is an enlarged view of the oxide semiconductor 230 in FIG. 6B and its vicinity.

In the case where the etching rate of the insulator 222 is adequately low in the etching treatment for processing the oxide semiconductor 230 and the etching treatment for removing the pillar as in the case of the insulator 224b, the semiconductor device may have a structure in which the insulator 224 and the insulator 224b are omitted as illustrated in FIG. 7C. FIG. 7C illustrates a modification example of FIG. 7B and differs from FIG. 7B in including neither the insulator 224 nor the insulator 224b.

### [Oxide Semiconductor Layer]

Here, an oxide semiconductor layer that can be used for the oxide semiconductor 230 will be described. The oxide semiconductor layer includes a metal oxide.

When a metal oxide is used for a semiconductor layer of a transistor, a lattice defect in the metal oxide might cause generation, capture, or the like of a carrier. Thus, when a metal oxide with a large number of lattice defects is used for a semiconductor layer of a transistor, the electrical characteristics of the transistor might be unstable. Therefore, a metal oxide used for a semiconductor layer of a transistor preferably has a small number of lattice defects. Examples of the lattice defect include point defects such as an atomic vacancy and an exotic atom, linear defects such as transition, plane defects such as a crystal grain boundary, and volume defects such as a cavity.

By using a metal oxide having crystallinity for an oxide semiconductor layer, the density of defect states in the oxide semiconductor layer can be reduced. Examples of the structure of a metal oxide having crystallinity include a c-axis aligned crystalline (CAAC) structure, a polycrystalline structure, and a nanocrystalline (nc) structure.

The metal oxide included in the oxide semiconductor layer of one embodiment of the present invention includes a plurality of microcrystals. A clear crystal grain boundary (grain boundary) is not observed between the plurality of microcrystals. It is preferable that the metal oxide included in the oxide semiconductor layer of one embodiment of the present invention include a plurality of microcrystals oriented and have a crystal structure in which the plurality of microcrystals are connected without a clear crystal grain boundary when observed from the orientation direction.

The oxide semiconductor layer of one embodiment of the present invention includes a metal oxide having a crystal structure different from a single crystal structure and a polycrystalline structure. It is particularly preferable that the oxide semiconductor layer of one embodiment of the present invention include a metal oxide having a CAAC structure.

The CAAC structure is a crystal structure in which a plurality of microcrystals (typically, a plurality of microcrystals each having a hexagonal crystal structure) have c-axis alignment and are connected on the a-b plane without a clear crystal grain boundary. In cross-sectional observation of the oxide semiconductor layer having the CAAC structure with use of a high-resolution transmission electron microscope (TEM) image, metal atoms are observed to be arranged in a layered manner in a crystal part. Thus, the oxide semiconductor layer having the CAAC structure can be regarded as having a structure including the layered crystal parts. The metal atoms arranged in a layered manner can be observed as bright spots in the cross-sectional TEM image of the oxide semiconductor layer. The bright spots are arranged in a direction parallel to the formation surface of the oxide semiconductor layer, for example.

The CAAC structure sometimes refers to a structure in which metal atoms are arranged in a layered manner in a direction parallel or substantially parallel to a formation surface and the layers in which the metal atoms are arranged are stacked in a direction perpendicular or substantially perpendicular to the formation surface in each of a plurality of microcrystals. The crystal structure of the microcrystals is not limited to a hexagonal crystal structure as long as the microcrystals have such a structure. For example, some of the plurality of microcrystals may have a crystal structure other than a hexagonal crystal structure (e.g., a cubic crystal structure).

The CAAC structure is formed such that the c-axis is perpendicular or substantially perpendicular to a formation surface, for example. In the CAAC structure, metal atoms are arranged in a layered manner in a direction parallel or substantially parallel to the formation surface. In a region having the CAAC structure, an angle formed by the c-axis and the formation surface is preferably within 900±200 (greater than or equal to 700 and less than or equal to 110°), further preferably within 900±150 (greater than or equal to 750 and less than or equal to 105°), still further preferably within 900±100 (greater than or equal to 800 and less than or equal to 100°), yet still further preferably within 900±5° (greater than or equal to 850 and less than or equal to 95°).

A polycrystalline structure includes a crystal grain boundary (grain boundary). When an oxide semiconductor layer having the polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. Meanwhile, in the CAAC structure, a crystal grain boundary is not clearly observed in the a-b plane; thus, a highly reliable semiconductor device can be achieved. Since the CAAC structure has a small number of crystal grain boundaries, an energy barrier for carrier conduction in a channel of a transistor is low, and on-state current is expected to be increased. Furthermore, an increase in electric resistance of a semiconductor layer of a transistor including the oxide semiconductor layer can be inhibited or initial characteristics (especially on-state current) of the transistor can be improved; thus, a transistor suitable for high-speed driving can be expected.

For the channel formation region of a transistor, a metal oxide that increases the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

The crystallinity of the oxide semiconductor layer can be analyzed by X-ray diffraction (XRD), TEM, or electron diffraction (ED), for example. Alternatively, these methods may be combined as appropriate for the analysis.

When the oxide semiconductor layer having the CAAC structure is subjected to electron diffraction, spots indicating c-axis alignment (bright spots) are observed in the electron diffraction pattern. The c-axes of the CAAC structure are preferably aligned in a direction parallel to the normal vector of the formation surface of the oxide semiconductor layer or the normal vector of a surface of the oxide semiconductor layer.

A fast Fourier transform (FFT) pattern obtained by FFT processing on a TEM image reflects reciprocal lattice space information like an electron diffraction pattern.

When the cross-sectional TEM image of the oxide semiconductor layer having the CAAC structure is obtained and each region in the cross-sectional TEM image is subjected to FFT processing to form an FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region where an angle formed by the crystal axis direction of each region calculated from the FFT pattern and the formation surface is preferably greater than or equal to 70° and less than or equal to 110° (within 90°±20°), further preferably greater than or equal to 75° and less than or equal to 105° (within 90°±15°), still further preferably greater than or equal to 80° and less than or equal to 100° (within 90°±10°), yet still further preferably greater than or equal to 85° and less than or equal to 95° (within 90°±5°) can be regarded as having the CAAC structure.

When the oxide semiconductor layer having the CAAC structure is observed from the direction perpendicular to the formation surface using the TEM image, a triangular or hexagonal atomic arrangement and crystallinity are observed in the a-b plane. In a Voronoi diagram formed by analysis of the TEM image of the oxide semiconductor layer having the CAAC structure observed from the direction perpendicular to the formation surface, pentagonal, hexagonal, and heptagonal Voronoi regions are mainly observed, typically a hexagonal Voronoi region is observed. For example, the hexagonal Voronoi region accounts for higher than or equal to 30% and lower than 100% of the Voronoi regions observed in the Voronoi diagram.

A method for forming a Voronoi diagram is described. First, in TEM image analysis, FFT processing is performed, only information within a certain range is left by filtering, and then reverse FFT is performed to obtain an FFT filtering image. Lattice points are extracted from the obtained FFT filtering image, and perpendicular bisectors of line segments each connecting adjacent lattice points are formed. A point at which three perpendicular bisectors intersect with each other is referred to as a Voronoi point, and a polygonal region surrounded by lines connecting the Voronoi points is referred to as a Voronoi region. In the above manner, a Voronoi diagram can be formed.

As the TEM observation range for forming a Voronoi diagram, a rectangular region that is 50 nm wide and 50 nm long is observed, for example. Note that the observation range is not limited to this.

In addition, when distribution of hexagonal lattice orientations is analyzed using lattice points extracted by analysis of a plan-view TEM image, at a boundary between two structures with different hexagonal lattice orientations, the difference in hexagonal lattice orientation is small, the boundary is blurred, and the two structures are connected to be tangled with each other. That is, no clear boundary portion is observed in the CAAC structure.

As the hexagonal lattice orientation, the orientation of a hexagon formed by six lattice points closest to each other can be calculated.

Note that there is no limitation on the crystallinity of a semiconductor material contained in the oxide semiconductor layer. The oxide semiconductor layer sometimes contains one or more of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including a crystal region). When the oxide semiconductor layer has crystallinity, degradation of the transistor characteristics can be inhibited in some cases.

The metal oxide of one embodiment of the present invention preferably contains at least indium (In) or zinc (Zn), particularly preferably contains indium as its main component. Here, the metal oxide contains indium as its main component, and can further contain an element M. The metal oxide preferably contains two or three selected from indium, the element M, and zinc, and particularly preferably contains indium and zinc as its main components. Here, the metal oxide contains indium and zinc as its main components, and can further contain the element M. The element M is a metal element or metalloid element that has a high bonding energy with oxygen, such as a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, further preferably one or more selected from gallium, tin, yttrium, and aluminum, still further preferably one or more selected from gallium and tin. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

A main component in a metal oxide refers to, for example, a metal element having a proportion of 0.1 atomic % or higher or 1 atomic % or higher with respect to all metal elements contained in the metal oxide.

In the cross section of the oxide semiconductor layer observed using the TEM image, metal atoms arranged in a layered manner in a direction parallel or substantially parallel to the formation surface are observed. In a TEM image, metal atoms are observed as bright spots. For example, in a metal oxide containing indium, indium atoms arranged in a layered manner are observed. For another example, in a metal oxide containing indium and zinc, indium atoms and zinc atoms arranged in a layered manner are observed.

As the metal oxide of one embodiment of the present invention, for example, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga-A1 oxide), an indium gallium tin oxide (In—Ga—Sn oxide, also referred to as IGTO), a gallium zinc oxide (Ga—Zn oxide, also referred to as GZO), an aluminum zinc oxide (A1-Zn oxide, also referred to as AZO), an indium aluminum zinc oxide (In-A1-Zn oxide, also referred to as IAZO), an indium tin zinc oxide (In—Sn—Zn oxide, also referred to as ITZO (registered trademark)), an indium titanium zinc oxide (In—Ti—Zn oxide), an indium gallium zinc oxide (In—Ga—Zn oxide, also referred to as IGZO), an indium gallium tin zinc oxide (In—Ga—Sn—Zn oxide, also referred to as IGZTO), or an indium gallium aluminum zinc oxide (In—Ga-A1-Zn oxide, also referred to as IGAZO or IAGZO) can be used. Alternatively, an indium tin oxide containing silicon (also referred to as ITSO), a gallium tin oxide (Ga—Sn oxide), an aluminum tin oxide (A1-Sn oxide), or the like can be used. As the metal oxide of one embodiment of the present invention, an indium oxide can be used. Alternatively, as the metal oxide of one embodiment of the present invention, a gallium oxide, a zinc oxide, or the like can be used.

By increasing the proportion of the number of indium atoms in the total number of atoms of all the metal elements contained in the metal oxide, a high on-state current and excellent frequency characteristics of the transistor can be achieved.

By increasing the proportion of the number of zinc atoms in the total number of atoms of all the metal elements contained in the metal oxide, the metal oxide has high crystallinity, so that diffusion of impurities in the metal oxide can be inhibited. Consequently, changes in the electrical characteristics of the transistor are reduced and the transistor can have high reliability.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor are reduced and the transistor can have high reliability.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, fluorine, chlorine, bromine, and hydrogen.

### [Formation Method of Oxide Semiconductor Layer]

The oxide semiconductor layer of one embodiment of the present invention can be formed by forming metal oxides using two kinds of film formation methods.

In the formation of the oxide semiconductor layer of one embodiment of the present invention, a metal oxide having the CAAC structure is formed. Here, the use of a sputtering method as a film formation method enables a metal oxide with high crystallinity to be formed. Alternatively, a film formation method such as a pulsed laser deposition (PLD) method may be used.

In the case where a metal oxide is formed by the above-described film formation method (hereinafter, a first film formation method), a mixed layer is sometimes formed at the interface between the metal oxide and a formation surface over which the metal oxide is formed. There is a concern that the mixed layer may hinder crystallization of the metal oxide. A metal oxide is formed in advance as a first layer over the formation surface by a film formation method (hereinafter, a second film formation method) that causes less damage than a sputtering method, a PLD method, or the like described as the first film formation method, and then a metal oxide is formed as a second layer by the first film formation method, whereby the formation of a mixed layer at the interface between the oxide semiconductor layer and the formation surface can be inhibited. Moreover, entry of impurities contained in the formation surface into the second layer can be inhibited. Accordingly, the crystallinity of the second layer can be further increased.

An atomic layer deposition (ALD) method and a chemical vapor deposition (CVD) method are suitable as the second film formation method because they enable damage to a formation surface to be reduced as compared with a sputtering method. Examples of the second film formation method include a molecular beam epitaxy (MBE) method and a wet process. Examples of the CVD method include a plasma enhanced CVD (PECVD) method, a thermal CVD method, a photo CVD method, and a metal organic CVD (MOCVD) method. The MBE method is a film formation method in which a thin film having a crystal structure reflecting a crystal system of a substrate is grown, and is one of film formation methods that cause less damage to a formation surface. The wet process is one of film formation methods that cause less damage to a formation surface. An example of the wet process is a spray coating method.

Furthermore, a third layer can be formed over the second layer. The third layer can be formed by the second film formation method, for example.

After the oxide semiconductor layer is formed, heat treatment is preferably performed.

In the method for forming the oxide semiconductor layer of one embodiment of the present invention, the crystallinity of the oxide semiconductor layers (the first layer and the third layer) above and below the second layer can be increased by using the second layer having high crystallinity (i.e., CAAC) as a nucleus or a seed. This can increase the crystallinity of the whole oxide semiconductor layer. In other words, the second layer serves as a nucleus or a seed to cause solid-phase growths of the metal oxides in the oxide semiconductor layers above and below the second layer, so that the oxide semiconductor layer with high crystallinity can be formed. An oxide semiconductor layer formed by such a film formation method, specifically, an oxide semiconductor layer having the CAAC structure, can be referred to as an axial growth CAAC (AG CAAC).

With the use of the method for forming the oxide semiconductor layer of one embodiment of the present invention, the first layer and the third layer can have high crystallinity even when they are not formed by a method that facilitates formation of a metal oxide with high crystallinity. The heat treatment has an assist function of increasing the crystallinity of the first layer and the third layer.

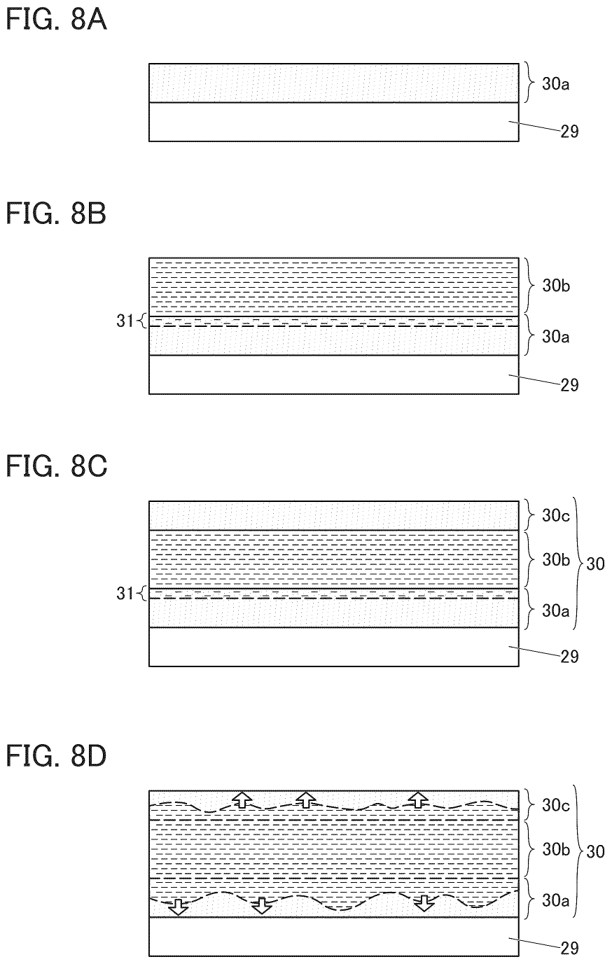

An example of a method for forming an oxide semiconductor 30 will be described below with reference to FIGS. 8A to 8D.

First, a layer 29 is formed. The layer 29 corresponds to an insulating film or a conductive film included in the semiconductor device. As the layer 29, for example, an insulating film such as a silicon oxide film, a silicon oxynitride film, a silicon nitride film, a silicon nitride oxide film, an aluminum oxide film, or a hafnium oxide film can be used. For another example, a conductive film functioning as an electrode of the semiconductor device can be used as the layer 29. The layer 29 does not need to have crystallinity. In other words, the layer 29 may have an amorphous structure. In the case where the layer 29 has crystallinity, the layer 29 may have a crystal structure with low lattice matching with the metal oxide included in the oxide semiconductor 30.

Next, an oxide semiconductor 30a is formed over the layer 29 (FIG. 8A).

In the formation method of one embodiment of the present invention, an oxide semiconductor 30b is formed by a sputtering method as described later. In the case where a metal oxide film is formed by a sputtering method, a mixed layer of a component of the metal oxide film to be formed and a component contained in the layer serving as the formation surface may be formed (i.e., alloying may occur) because of sputtered particles ejected from a target or the like or energy or the like applied to the substrate side by sputtered particles or the like, for example. The alloying might hinder crystallization of the oxide semiconductor layer above the mixed layer. In the case where the alloying occurs, it is difficult to increase the crystallinity of the alloyed region even when heat treatment described later is performed. When an oxide semiconductor layer including the alloyed region is used for a transistor, the initial characteristics or reliability of the transistor may be adversely affected.

In view of the above, before the formation of the oxide semiconductor 30b, the oxide semiconductor 30a is formed in advance by a film formation method that causes less damage to the formation surface. This can inhibit alloying of the component contained in the oxide semiconductor 30 with the component contained in the layer 29, enabling the alloyed region to be thin or thin enough not to be observed. Here, the oxide semiconductor 30a is formed by an ALD method.

Examples of the ALD method include a thermal ALD method, in which a precursor and a reactant react with each other only by a thermal energy, and a plasma-enhanced ALD (PEALD) method, in which a reactant excited by plasma is used.

Unlike in a film formation method in which particles ejected from a target or the like are deposited, a film is formed by reaction at a surface of an object to be processed in an ALD method. An ALD method enables one atomic layer to be formed at a time, and has various advantages enabling formation of an extremely thin film, formation of a film on a component with a high aspect ratio or a surface with a large step, formation of a film with few defects such as pinholes, formation of a film with excellent coverage, low-temperature film formation, and the like. By forming the oxide semiconductor 30a and an after-mentioned oxide semiconductor 30c by an ALD method, the oxide semiconductor layer can have good coverage. Thus, the oxide semiconductor layer can suitably cover a step, an opening portion, or the like with a high aspect ratio.

A PEALD method utilizing plasma is preferable because film formation at lower temperatures is possible in some cases. Note that a precursor used in the ALD method sometimes contains an element such as carbon or chlorine. Thus, a film formed by the ALD method may contain an element such as carbon or chlorine in a larger quantity than a film formed by another film formation method.

Here, a method for forming an In-M-Zn oxide as the oxide semiconductor 30a by an ALD method is described.

First, a source gas that contains a precursor containing indium is introduced into a chamber so that the precursor is adsorbed on the surface of the layer 29. Then, an oxidizer is introduced as a reactant into the chamber to react with the adsorbed precursor, and components other than indium are released while indium is being adsorbed on the substrate, whereby a layer in which indium and oxygen are bonded to each other is formed.

Subsequently, a source gas that contains a precursor containing the element M is introduced into the chamber, so that the precursor is adsorbed on the layer in which indium and oxygen are bonded to each other. Then, an oxidizer is introduced as a reactant into the chamber to react with the adsorbed precursor, and components other than the element M are released while the element M is being adsorbed on the substrate, whereby a layer in which the element M and oxygen are bonded to each other is formed.

Subsequently, a source gas that contains a precursor containing zinc is introduced into the chamber, so that the precursor is adsorbed on the layer in which the element M and oxygen are bonded to each other. Then, an oxidizer is introduced as a reactant into the chamber to react with the adsorbed precursor, and components other than zinc are released while zinc is being adsorbed on the substrate, whereby a layer in which zinc and oxygen are bonded to each other is formed.

By repeating the above steps, an In-M-Zn oxide can be formed as the oxide semiconductor 30a over the layer 29 by an ALD method.

The substrate heating temperature is preferably a temperature corresponding to the decomposition temperature of the precursor. Here, in the case of a thermal ALD method in which triethylindium is used as the precursor containing indium, triethylgallium is used as a precursor containing gallium, and diethylzinc is used as the precursor containing zinc, the substrate heating temperature is higher than or equal to 100° C. and lower than or equal to 350° C., preferably higher than or equal to 150° C. and lower than or equal to 300° C., for example.

It is preferable that after the precursor is adsorbed in the above manner, introduction of the source gas containing the precursor be stopped and the chamber be purged so that an excess precursor, a reaction product, and the like are removed from the chamber. Moreover, it is preferable that after the adsorbed precursor reacts with the oxidizer in the above manner, introduction of the oxidizer be stopped and the chamber be purged so that an excess reactant, a reaction product, and the like are removed from the chamber.

In the description of this specification and the like, in the case of using ozone (O₃), oxygen (O₂), and water (H₂O) as a reactant or an oxidizer, they include not only those in gas or molecular states but also those in plasma, radical, and ion states, unless otherwise specified.

When the oxide semiconductor 30a is formed by an ALD method, an oxide semiconductor layer having a microcrystalline structure or an amorphous structure that has lower crystallinity than the CAAC structure may be formed.

Next, as the oxide semiconductor 30b, an In-M-Zn oxide is formed over the oxide semiconductor 30a by a sputtering method (FIG. 8B). The oxide semiconductor 30b preferably has a composition suitable for forming the CAAC structure.

When the oxide semiconductor 30b is formed by a sputtering method, a mixed layer 31 is formed on the surface of the oxide semiconductor 30a or in the vicinity of the surface. A fine crystal region is sometimes formed in the mixed layer 31 by, for example, sputtered particles or energy or the like applied to the substrate side by sputtered particles or the like at the time of forming the oxide semiconductor 30b. In the subsequent heat treatment step, the mixed layer 31 or the fine crystal region formed in the mixed layer 31 serves as a nucleus, and at least part of the oxide semiconductor 30a is crystallized in some cases.

Examples of the sputtering method include an RF sputtering method using a high-frequency power source for a sputtering power source, a DC sputtering method using a DC power source, and a pulsed DC sputtering method in which voltage applied to an electrode is changed in a pulsed manner. The DC sputtering method can be suitably used for forming a metal conductive film, and its high film formation rate can increase productivity. The pulsed DC sputtering method can be suitably used for forming a metal conductive film and a semiconductor film. The RF sputtering method can be suitably used for forming an insulating film. A film of a compound such as an oxide, a nitride, or a carbide can be formed by a reactive sputtering method using a reactive gas. The metal oxide film used as the oxide semiconductor layer of one embodiment of the present invention can be formed by any of the above methods selected as appropriate in accordance with, for example, the conductivity of a target used in a sputtering method.

As a target used in a sputtering method, an In-M-Zn oxide can be used. In the case where a metal oxide is formed by a sputtering method, oxygen or a mixed gas of oxygen and a noble gas can be used as a sputtering gas. In addition, an increase in the proportion of oxygen in the sputtering gas can increase the amount of excess oxygen contained in the oxide film to be formed.

A higher proportion of the flow rate of an oxygen gas to the flow rate of the whole film formation gas (also referred to as oxygen flow rate ratio) used at the time of forming the metal oxide enables the formed metal oxide to have higher crystallinity in some cases.

When the metal oxide is formed by a sputtering method and the proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess oxide semiconductor layer in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient metal oxide is formed. A transistor including an oxygen-deficient metal oxide in a channel formation region can have relatively high field-effect mobility.

In the case where the metal oxide is formed by a sputtering method, the composition of the formed metal oxide may be different from the composition of the sputtering target. In particular, the zinc content of the formed metal oxide may be reduced to approximately 50% of that of the sputtering target.

In the formation of the oxide semiconductor 30b by a sputtering method, substrate heating is preferably performed. In forming a metal oxide, the substrate temperature (stage temperature) at the time of forming the metal oxide is increased, whereby a metal oxide with high crystallinity can be formed in some cases. In the formation of the oxide semiconductor 30b by a sputtering method, the substrate heating temperature is preferably higher than or equal to 100° C. and lower than or equal to 400° C., further preferably higher than or equal to 200° C. and lower than or equal to 300° C., for example.

Here, a formation model of the CAAC structure by a sputtering method will be described. First, microcrystals are formed during film formation by sputtering. The microcrystals are sometimes formed by energy or the like applied to the substrate side from sputtered particles (sometimes referred to as atomic particles), gas particles, or the like. Planar or pellet-like sputtered particles (sometimes referred to as nanoclusters) ejected from a sputtering target and deposited on a formation surface may become the microcrystals. Subsequently, the sputtered particles are adsorbed on the end portions of the microcrystals, and the microcrystals grow in a lateral direction (a direction substantially parallel to the formation surface). When the microcrystals grow in the lateral direction, the neighboring microcrystals are connected to each other so that no end portions of the microcrystals are observed. When there are no end portions of the microcrystals, the sputtered particles are adsorbed on the microcrystals, and the microcrystals grow in a vertical direction (a direction substantially perpendicular to the formation surface). The sputtered particles are adsorbed on the end portions of the microcrystals that have grown in the vertical direction, and the microcrystals grow in the lateral direction. The lateral growth and the vertical growth of the microcrystals are repeated in this manner, so that the CAAC structure is formed. That is, the CAAC structure is formed through the growth of microcrystals included in an oxide semiconductor and used as a nucleus or a seed.

Note that the CAAC structure is unlikely to be formed in an oxide semiconductor into which an impurity such as silicon, carbon, or water enters. Thus, the oxide semiconductor 30b is preferably formed by a film formation method that hardly causes entry of such an impurity. A sputtering method that uses a sputtering target in which the impurity concentration is reduced and a film formation gas in which the amount of impurity is reduced is suitable for forming the oxide semiconductor 30b because an oxide semiconductor with a low impurity concentration can be formed by such a sputtering method.

Next, the oxide semiconductor 30c is formed over the oxide semiconductor 30b (FIG. 8C). Here, the oxide semiconductor 30c is formed by an ALD method. For the formation of the oxide semiconductor 30c by an ALD method, refer to the method for forming the oxide semiconductor 30a.

When the oxide semiconductor 30c having lower crystallinity than the CAAC structure is formed by an ALD method over the oxide semiconductor 30b having the CAAC structure, the oxide semiconductor 30c may epitaxially grow with the oxide semiconductor 30b as a nucleus. Thus, at the time of forming the oxide semiconductor 30c, the oxide semiconductor 30c may include a region having the CAAC structure. The region having the CAAC structure is preferably formed throughout the oxide semiconductor 30c.

The oxide semiconductor 30c can be used for a layer in contact with a gate insulating layer of a transistor, for example. Increasing the crystallinity of the layer in contact with the gate insulating layer can increase the carrier mobility in an on state of the transistor.

Moreover, the formation of the oxide semiconductor 30c by an ALD method causes less damage to the oxide semiconductor 30b, so that the entire oxide semiconductor 30 can have high crystallinity.

When the oxide semiconductor 30a and the oxide semiconductor 30c are formed by an ALD method that offers good coverage, the entire oxide semiconductor layer can have high coverage. Moreover, the oxide semiconductor 30b with high crystallinity is formed by a sputtering method and is subjected to epitaxial growth or the like, so that the crystallinity of the upper and lower oxide semiconductor layers (the oxide semiconductor 30a and the oxide semiconductor 30c) is increased. Thus, the whole layer of the oxide semiconductor 30 can have high crystallinity. Accordingly, the oxide semiconductor 30 can have both high coverage and high crystallinity.

Next, a heat treatment step may be performed.

The heat treatment temperature is higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature is set to 400° C.±25° C. (higher than or equal to 375° C. and lower than or equal to 425° C.). The treatment time is shorter than or equal to 10 hours, longer than or equal to 1 minute and shorter than or equal to 5 hours, or longer than or equal to 1 minute and shorter than or equal to 2 hours. In the case of using a rapid thermal anneal (RTA) apparatus, the treatment time is longer than or equal to 1 second and shorter than or equal to 5 minutes, for example. By the heat treatment, the oxide semiconductor 30c (in other words, crystal molecules formed by an ALD method) is expected to repair the atomic-level space between crystal parts of the CAAC structure of the oxide semiconductor 30b.

The heating apparatus used for the heat treatment is not limited to a particular apparatus, and may be an apparatus for heating an object to be processed by heat conduction or heat radiation from a heating element such as a resistance heating element. For example, an electric furnace, or an RTA apparatus such as a lamp rapid thermal anneal (LRTA) apparatus or a gas rapid thermal anneal (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high-pressure sodium lamp, or a high-pressure mercury lamp. A GRTA apparatus is an apparatus for heat treatment using a high-temperature gas.

By the heat treatment step, the crystallinity of the region having the CAAC structure in the oxide semiconductor 30c is increased in some cases. In the case where the region is formed only below the oxide semiconductor 30c after film formation by an ALD method, the region may be extended upward by the heat treatment step (FIG. 8D). That is, by the heat treatment, the region having the CAAC structure is sometimes formed in the whole layer of the oxide semiconductor 30c.

By the heat treatment step, the oxide semiconductor 30b is further repaired by the oxide semiconductor 30c (in other words, crystal molecules formed by an ALD method) that fills the atomic-level space between crystal parts of the CAAC structure of the oxide semiconductor 30b in some cases.

At least part of the oxide semiconductor 30a preferably has the CAAC structure by the heat treatment step (FIG. 8D). The CAAC structure is expected to be easily generated when the mixed layer 31 formed in the oxide semiconductor 30a in the formation of the oxide semiconductor 30b becomes a nucleus or a seed. The oxide semiconductor 30a preferably has a large CAAC region, and the CAAC region preferably extends to the vicinity of the layer 29.

Since the CAAC region extends from the upper portion to the lower portion of the oxide semiconductor 30a, the CAAC region can extend to the vicinity of the layer 29, regardless of the material and crystallinity of the layer 29. For example, even when the layer 29 has an amorphous structure, the oxide semiconductor 30a having high crystallinity can be formed. Thus, the method for forming the oxide semiconductor layer of one embodiment of the present invention is particularly suitable for the case where a layer serving as the formation surface has an amorphous structure.

After the formation of the oxide semiconductor 30c, microwave treatment may be performed.

Here, the microwave treatment refers to, for example, treatment using an apparatus including a power source for generating high-density plasma using microwaves. In this specification and the like, a microwave refers to an electromagnetic wave having a frequency higher than or equal to 300 MHz and lower than or equal to 300 GHz. The microwave treatment can also be referred to as microwave excitation high-density plasma treatment.

The impurity concentration in the oxide semiconductor 30 is preferably reduced by performing microwave treatment in an oxygen-containing atmosphere. Examples of the impurity especially include hydrogen and carbon. Although the microwave treatment in an oxygen-containing atmosphere is performed on the metal oxide in the above example, one embodiment of the present invention is not limited thereto. For example, the microwave treatment in an oxygen-containing atmosphere may be performed on an insulating film, more specifically a silicon oxide film, which is positioned in the vicinity of the metal oxide. Furthermore, the crystallinity of the oxide semiconductor layer is sometimes increased by heat in the microwave treatment.

The microwave treatment is preferably performed under reduced pressure, and the pressure is preferably higher than or equal to 10 Pa and lower than or equal to 1000 Pa, further preferably higher than or equal to 300 Pa and lower than or equal to 700 Pa. It is preferable to perform the microwave treatment with the substrate heated. The substrate temperature can be higher than or equal to room temperature (e.g., 25° C.) and lower than or equal to 750° C., preferably higher than or equal to 100° C. and lower than or equal to 500° C., further preferably higher than or equal to 200° C. and lower than or equal to 500° C., still further preferably higher than or equal to 300° C. and lower than or equal to 500° C., yet still further preferably higher than or equal to 400° C. and lower than or equal to 500° C. The substrate temperature can be higher than or equal to 400° C. and lower than or equal to 450° C., for example.

The microwave treatment may be followed successively by heat treatment without exposure to the air. The heat treatment temperature is, for example, preferably higher than or equal to 100° C. and lower than or equal to 750° C., further preferably higher than or equal to 300° C. and lower than or equal to 500° C., still further preferably higher than or equal to 400° C. and lower than or equal to 450° C.

The microwave treatment can be performed using an oxygen gas and an argon gas, for example. The microwave treatment in an oxygen-containing atmosphere converts an oxygen gas into plasma using a high-frequency wave such as a microwave or RF, and applies the oxygen plasma to the oxide semiconductor layer. By the effects of plasma, a microwave, and the like, a defect that is an oxygen vacancy into which hydrogen enters (hereinafter, sometimes referred to as V_{O}H) in the oxide semiconductor layer can be divided into an oxygen vacancy and hydrogen, and hydrogen which is an impurity can be removed from the oxide semiconductor layer. In this manner, V_{O}H contained in the oxide semiconductor layer can be reduced. At this time, carbon bonded to oxygen, hydrogen, or the like can also be removed in some cases. Performing the microwave treatment in such a manner can reduce impurities such as carbon and hydrogen. In addition, oxygen radicals generated by the oxygen plasma can be supplied to oxygen vacancies formed in the oxide semiconductor layer, thereby further reducing oxygen vacancies in the oxide semiconductor layer.

Oxygen implanted into the oxide semiconductor layer has a variety of forms such as an oxygen atom, an oxygen molecule, an oxygen ion, and an oxygen radical (also referred to as O radical which is an atom, a molecule, or an ion having an unpaired electron). The oxygen implanted into the oxide semiconductor layer has one or more of the above forms; an oxygen radical is particularly preferable.

In the above manner, impurities in the oxide semiconductor layer can be reduced. Crystal growth of the oxide semiconductor layer with a low impurity concentration can further make crystallinity higher.

Note that one or both of the heat treatment and the microwave treatment may be performed directly on the oxide semiconductor layer or performed on an insulating film or the like formed over the oxide semiconductor layer.

The oxide semiconductor layer having the CAAC structure formed by the two kinds of film formation methods sometimes has one or more of a higher dielectric constant, higher film density, and higher film hardness than the oxide semiconductor layer having the CAAC structure formed by one kind of film formation method.

With the use of the oxide semiconductor layer having the CAAC structure formed by the two kinds of film formation methods for a channel formation region of a transistor, the transistor can have excellent characteristics (e.g., a high on-state current, high field-effect mobility, a low S value, excellent frequency characteristics (also referred to as f characteristics), or high reliability).

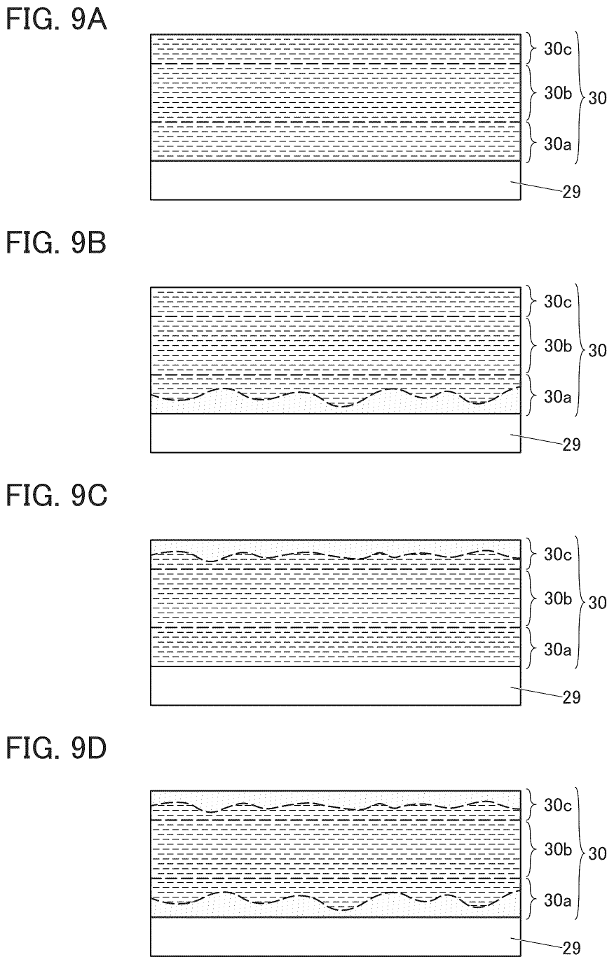

The region having the CAAC structure preferably spreads in the whole oxide semiconductor 30 including the oxide semiconductor 30a and the oxide semiconductor 30c. FIG. 9A illustrates a state where the oxide semiconductor 30a, the oxide semiconductor 30b, and the oxide semiconductor 30c are each crystallized. Crystals in the region having the CAAC structure in the oxide semiconductor 30a are connected to crystals in the region having the CAAC structure in the oxide semiconductor 30b. Crystals in the region having the CAAC structure in the oxide semiconductor 30c are connected to the crystals in the region having the CAAC structure in the oxide semiconductor 30b. The oxide semiconductor 30 may be expressed as one layer where the interfaces are not clearly observed. The oxide semiconductor 30 may be expressed as a single layer.

In cross-sectional observation with a high-resolution TEM, for example, the regions having the CAAC structure in the oxide semiconductor 30a, the oxide semiconductor 30b, and the oxide semiconductor 30c can be observed as bright spots arranged in parallel with the formation surface. The c-axis of the CAAC structure included in each of the oxide semiconductor 30a, the oxide semiconductor 30b, and the oxide semiconductor 30c is preferably substantially parallel to the normal direction of the formation surface of the oxide semiconductor layer.

Part of the oxide semiconductor 30a or part of the oxide semiconductor 30c is not crystallized in some cases. An example in FIG. 9B illustrates a state where the vicinity of the interface between the oxide semiconductor 30a and the layer 29 is not crystallized. FIG. 9C illustrates a state where the vicinity of the surface of the oxide semiconductor 30c is not crystallized. FIG. 9D illustrates a state where the vicinity of the interface between the oxide semiconductor 30a and the layer 29 and the vicinity of the surface of the oxide semiconductor 30c are not crystallized.

The whole oxide semiconductor layer of one embodiment of the present invention has high crystallinity. Thus, in the oxide semiconductor 30, the boundaries between the stacked films of the oxide semiconductor 30a, the oxide semiconductor 30b, and the oxide semiconductor 30c are not observed in some cases. In particular, after heat treatment, the boundaries between the stacked films are difficult to observe in some cases. Whether the boundaries between the stacked films are present can be checked with a cross-sectional TEM or a cross-sectional STEM, for example.

It is preferable that crystals included in the oxide semiconductor 30b and crystals included in the oxide semiconductor 30a or 30c have a small lattice mismatch. Thus, the oxide semiconductor 30a or 30c can form crystals reflecting the orientation of crystals included in the oxide semiconductor 30b. In that case, for example, in high-resolution TEM cross-sectional observation of the oxide semiconductor 30, bright spots arranged in a layered manner in a direction parallel to the formation surface are observed in the oxide semiconductor 30a or 30c.

There is no particular limitation on the crystal structure of the oxide semiconductor 30a or 30c as long as crystals included in the oxide semiconductor 30b and crystals included in the oxide semiconductor 30a or 30c have a small lattice mismatch. The crystal structure of the oxide semiconductor 30a or 30c may be any of a cubic crystal structure, a tetragonal crystal structure, an orthorhombic crystal structure, a hexagonal crystal structure, a monoclinic crystal structure, and a trigonal crystal structure.

Treatment for increasing the crystallinity of the oxide semiconductor layer is preferably performed during or after the formation of the oxide semiconductor layer. Examples of the treatment for increasing the crystallinity of the oxide semiconductor layer include heat treatment, plasma treatment, microwave treatment, and light (e.g., ultraviolet light) irradiation treatment. Some of these treatments may be performed concurrently or sequentially. For example, heat treatment and microwave treatment can be performed concurrently. Alternatively, microwave treatment can be performed after heat treatment.

It is further preferable that the treatment for increasing the crystallinity of the oxide semiconductor layer be performed a plurality of times during the formation of the oxide semiconductor layer. For example, in the case where the oxide semiconductor layer is formed by an atomic layer deposition method (hereinafter, also referred to as an ALD method), microwave treatment is preferably performed every time an atomic layer is formed. Alternatively, the treatment for increasing crystallinity is preferably performed every time the oxide semiconductor layer with a thickness in a predetermined range is formed, in which case the productivity can be increased. Specifically, the oxide semiconductor layer is preferably formed in the following manner: a first oxide semiconductor layer with a thickness greater than or equal to 1 nm and less than or equal to 10 nm is formed, first microwave treatment is performed, a second oxide semiconductor layer with a thickness greater than or equal to 1 nm and less than or equal to 10 nm is formed, and then second microwave treatment is performed. Note that methods for forming the first oxide semiconductor layer and the second oxide semiconductor layer are not particularly limited, and are each an ALD method or a sputtering method. It is particularly preferable to form the first oxide semiconductor layer by an ALD method, in which case entry (also referred to as mixing) of an element of a layer on which the first oxide semiconductor layer is formed into the first and second oxide semiconductor layers can be prevented. Forming the first oxide semiconductor layer by an ALD method is particularly preferable in the case where the element contained in the layer on which the first oxide semiconductor layer is formed hinders crystallization of an oxide semiconductor (e.g., the case where silicon, carbon, or the like is contained in the layer). The first oxide semiconductor layer and the second oxide semiconductor layer may have different compositions. Although the stacked-layer structure of the first oxide semiconductor layer and the second oxide semiconductor layer is exemplified here, one embodiment of the present invention is not limited thereto. Treatment similar to the above treatment can be performed on the oxide semiconductor layer having a single-layer structure or a stacked-layer structure of three or more layers.

The treatment for increasing the crystallinity of the oxide semiconductor layer may be performed after the formation of the oxide semiconductor layer. Specifically, after the formation of the oxide semiconductor layer, the treatment may be performed directly on the oxide semiconductor layer, or may be performed on the oxide semiconductor layer through another film such as an insulating film formed over the oxide semiconductor layer. For example, microwave treatment may be performed on the oxide semiconductor layer after the formation of the oxide semiconductor layer; alternatively, an insulating film (e.g., a silicon nitride film, a silicon oxide film, or an aluminum oxide film) may be formed after the formation of the oxide semiconductor layer, and then one or more of heat treatment, plasma treatment, and microwave treatment may be performed on the oxide semiconductor layer through the insulating film.

Note that the treatment for increasing the crystallinity of the oxide semiconductor layer can also serve as treatment for removing impurities contained in the oxide semiconductor layer. For example, carbon, hydrogen, nitrogen, and the like contained in the oxide semiconductor layer can be suitably removed. Alternatively, by performing the treatment for increasing the crystallinity of the oxide semiconductor layer in an oxygen gas atmosphere, oxygen vacancies in the oxide semiconductor layer can be reduced.

During the treatment for increasing the crystallinity of the oxide semiconductor layer, the substrate temperature is preferably higher than or equal to room temperature (e.g., 25° C.), higher than or equal to 100° C. and lower than or equal to 600° C., or higher than or equal to 300° C. and lower than or equal to 450° C. The heat treatment temperature is preferably higher than or equal to 100° C. and lower than or equal to 700° C., or higher than or equal to 300° C. and lower than or equal to 450° C.

The oxide semiconductor layer of one embodiment of the present invention can be used as a semiconductor layer of a transistor.

In the case where the oxide semiconductor 30 is used for a semiconductor layer of a transistor, the thickness of the oxide semiconductor 30 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm. In a transistor used for a scaled-down semiconductor device, the thickness of the oxide semiconductor 30 is preferably greater than or equal to 1 nm and less than or equal to 20 nm, further preferably greater than or equal to 3 nm and less than or equal to 15 nm, yet further preferably greater than or equal to 5 nm and less than or equal to 12 nm.

The thickness of the oxide semiconductor 30b is preferably less than or equal to 200 nm, for example. In the case where the oxide semiconductor 30b is in a form of layer, the thickness of the oxide semiconductor 30b is, for example, preferably greater than or equal to 1 nm and less than or equal to 200 nm, further preferably greater than or equal to 1 nm and less than or equal to 100 nm, yet further preferably greater than or equal to 2 nm and less than or equal to 100 nm.

Alternatively, when the oxide semiconductor 30b can function as a crystal nucleus, the oxide semiconductor 30b is not in a form of layer and may be an aggregate of island-shaped regions. For example, such island-shaped regions included in the oxide semiconductor 30b are discretely located.

The thicknesses of the oxide semiconductor 30a and the oxide semiconductor 30c are each preferably greater than or equal to 1 nm and less than or equal to 50 nm, further preferably greater than or equal to 1 nm and less than or equal to 30 nm, still further preferably greater than or equal to 1 nm and less than or equal to 20 nm, yet still further preferably greater than or equal to 2 nm and less than or equal to 20 nm, for example.

The thickness of the region formed by alloying of the component contained in the oxide semiconductor 30 and the component contained in the layer 29 is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 8A and 8B illustrate an example in which an alloyed region is not formed between the layer 29 and the oxide semiconductor 30a.

Note that the thickness of the alloyed region can sometimes be calculated by performing secondary ion mass spectrometry (SIMS) or composition line analysis by energy dispersive X-ray spectroscopy (EDX) on the region and its vicinity.

For example, EDX line analysis is performed on the region and its vicinity with the direction perpendicular to the formation surface of the oxide semiconductor 30a as the depth direction. Next, in profiles of quantitative values of elements in the depth direction obtained by the analysis, the depth at which the quantitative value of a metal that is the main component of the oxide semiconductor 30a and is not the main component of a layer (here, the layer 29) serving as a formation surface (the metal is In when the oxide semiconductor 30a contains In) becomes half is defined as a depth (position) of the interface between the region and the oxide semiconductor 30a. Furthermore, the depth at which the quantitative value of an element (e.g., Si) that is the main component of the layer serving as the formation surface and that is not the main component of the oxide semiconductor 30a becomes half is defined as a depth (position) of the interface between the region and the layer serving as the formation surface. In the above manner, the thickness of the alloyed region can be calculated.

For example, in the case where SIMS analysis of the oxide semiconductor 30 formed over the layer 29 that is formed using a silicon oxide layer is performed, the depth at which the silicon concentration is 50% of the maximum value of the silicon concentration of the layer 29 is defined as an interface, and the distance between the interface and the depth at which the silicon concentration decreases to 1.0×10²¹ atoms/cm³, preferably 5.0×10²⁰ atoms/cm³, further preferably 1.0×10²¹ atoms/cm³ is defined as a thickness t_s. The thickness t_s is preferably less than or equal to 3 nm, further preferably less than or equal to 2 nm.

When the thickness of the alloyed region is reduced, the CAAC structure can be formed in the vicinity of the formation surface. Here, the vicinity of the formation surface refers to, for example, a region ranging from the formation surface of the oxide semiconductor 30 to greater than 0 nm and less than or equal to 3 nm, preferably greater than 0 nm and less than or equal to 2 nm, further preferably greater than or equal to 1 nm and less than or equal to 2 nm in a direction substantially perpendicular to the formation surface of the oxide semiconductor 30.

The oxide semiconductor 30a includes a region positioned in a range of 0 nm to 3 nm, both inclusive, from the top surface of the layer 29, for example. The oxide semiconductor 30c is positioned in a range of 0 nm to 3 nm, both inclusive, from the top surface of the oxide semiconductor 30. The oxide semiconductor 30a, the oxide semiconductor 30b, and the oxide semiconductor 30c have substantially the same thicknesses, for example. Alternatively, the oxide semiconductor 30a, the oxide semiconductor 30b, and the oxide semiconductor 30c may have different thicknesses.

Although the structure in which the oxide semiconductor 30 has a three-layer structure of the oxide semiconductors 30a to 30c is described above, the present invention is not limited thereto. The oxide semiconductor 30 may have either a two-layer structure or a stacked-layer structure of four or more layers.

In the case where the oxide semiconductor 30 has a two-layer structure, the oxide semiconductor 30a and the oxide semiconductor 30b can be stacked in this order. This can inhibit alloying of the component contained in the oxide semiconductor 30 with the component contained in the layer 29, enabling the alloyed region to be thin or thin enough not to be observed.

Alternatively, in the case where the oxide semiconductor 30 has a five-layer structure, a first oxide semiconductor, a second oxide semiconductor, a third oxide semiconductor, a fourth oxide semiconductor, and a fifth oxide semiconductor can be stacked in this order to form the oxide semiconductor 30. For example, the first oxide semiconductor, the third oxide semiconductor, and the fifth oxide semiconductor are formed preferably by the second film formation method, further preferably by an ALD method. The second oxide semiconductor and the fourth oxide semiconductor are formed preferably by the first film formation method, further preferably by a sputtering method. With such a structure, crystal growth is promoted from one or both of the second oxide semiconductor and the fourth oxide semiconductor, so that the crystallinity of the third oxide semiconductor can be increased, even when the third oxide semiconductor has a composition in which the CAAC structure is unlikely to be formed.

In the case where the oxide semiconductor 30 has a stacked-layer structure of two or more layers, typically a stacked-layer structure of two to five layers, the layers are preferably formed successively without exposure to the air. For example, the layers are formed successively using a multi-chamber film formation apparatus. In that case, the oxide semiconductor 30 can be formed while entry of impurities into the layers is being inhibited.

### [C-Axis Alignment Proportion]

The oxide semiconductor layer of one embodiment of the present invention has the CAAC structure. The crystallinity degree of the oxide semiconductor layer of one embodiment of the present invention can be evaluated with the use of crystal orientation, for example.

The CAAC structure in the oxide semiconductor layer can be evaluated from a map showing crystal orientation in some cases. In a region having the CAAC structure, for example, a state where crystals have c-axis alignment is observed.

The map showing crystal orientation can be obtained by, for example, obtaining a cross-sectional TEM image, performing FFT processing on each region in the cross-sectional TEM image to form an FFT pattern, and calculating the crystal axis direction in each region. Specifically, for example, two spots with high intensity are observed in the FFT pattern of the region including a layered crystal part. The crystal axis direction in the region can be obtained from the angle of a line segment connecting the two spots. The FFT pattern reflects reciprocal lattice space information like an electron diffraction pattern.

By calculating the proportion of regions having c-axis alignment from the map showing crystal orientation, the c-axis alignment proportion can be calculated.

In the oxide semiconductor layer of one embodiment of the present invention, the c-axis alignment proportion can be calculated with use of, for example, cross-sectional or plan-view TEM observation of the oxide semiconductor layer and the above map showing crystal orientation. The region where the FFT is performed (also referred to as an FFT window) can be a circle with a diameter of 1.0 nm, for example. Note that the region where the FFT is performed is not limited to a circle.

In the case where analysis is performed using a cross-sectional TEM image, the cross-sectional TEM image observation range is, for example, a region having a width of 100 nm in the horizontal direction with the direction perpendicular to the formation surface regarded as the vertical direction. Note that the observation range is not limited to this.

When the proportion of regions where the orientation is deviated from the c-axis by less than or equal to 200 is calculated as the c-axis alignment proportion in the oxide semiconductor layer of one embodiment of the present invention, for example, the c-axis alignment proportion is preferably higher than or equal to 50%, further preferably higher than or equal to 60%, still further preferably higher than or equal to 70%, yet further preferably higher than or equal to 80%, yet still further preferably higher than or equal to 90%, yet still further preferably higher than or equal to 95%.

The c-axis alignment proportions of a region formed as the oxide semiconductor 30a, a region formed as the oxide semiconductor 30b, and a region formed as the oxide semiconductor 30c are Rc1, Rc2, and Rc3, respectively. Here, the c-axis alignment proportion is calculated as the proportion of regions where the orientation is deviated from the c-axis by less than or equal to 20°, for example. Rc2 is preferably higher than or equal to 50%, further preferably higher than or equal to 60%, still further preferably higher than or equal to 70%, yet further preferably higher than or equal to 80%, yet still further preferably higher than or equal to 90%, yet still further preferably higher than or equal to 95%. Furthermore, Rc3 is preferably higher than or equal to 50%, further preferably higher than or equal to 60%, still further preferably higher than or equal to 70%, yet further preferably higher than or equal to 80%, yet still further preferably higher than or equal to 90%, yet still further preferably higher than or equal to 95%. Rc3/Rc1 is preferably greater than one. Furthermore, Rc2/Rc1 is preferably greater than one.

### [Composition of Oxide Semiconductor Layer]

The oxide semiconductor 30a preferably has a composition different from that of the oxide semiconductor 30b. The oxide semiconductor 30c preferably has a composition different from that of the oxide semiconductor 30b. The oxide semiconductor 30a can have the same composition as the oxide semiconductor 30c. Alternatively, the oxide semiconductor 30a and the oxide semiconductor 30c can have different compositions.

The oxide semiconductor 30b preferably has a composition suitable for forming the CAAC structure. The oxide semiconductor 30b preferably contains zinc, for example. The oxide semiconductor 30b containing zinc can be a metal oxide having high crystallinity. The oxide semiconductor 30b preferably contains the element M in addition to zinc. When the oxide semiconductor 30b contains the element M, formation of oxygen vacancies in the metal oxide can be inhibited, for example. For the oxide semiconductor 30b, a metal oxide with an atomic ratio of In:M:Zn=1:1:1 or in the neighborhood thereof, a metal oxide with an atomic ratio of In:M:Zn=1:1:1.2 or in the neighborhood thereof, an atomic ratio of In:M:Zn=1:1:0.5 or in the neighborhood thereof, a metal oxide with an atomic ratio of In:M:Zn=1:1:2 or in the neighborhood thereof, a metal oxide with an atomic ratio of In:M:Zn=4:2:3 or in the neighborhood thereof, a metal oxide with an atomic ratio of In:M:Zn=1:3:2 or in the neighborhood thereof, or a metal oxide with an atomic ratio of In:M:Zn=1:3:4 or in the neighborhood thereof is specifically used. Note that the neighborhood of the atomic ratio includes ±30% of an intended atomic ratio. It is preferable to use one or more of gallium, tin, yttrium, and aluminum as the element M.

The oxide semiconductor 30b may have a structure not containing the element M. For example, an In—Zn oxide may be used. Specifically, an In—Zn oxide with an atomic ratio of In:Zn=1:1 or in the neighborhood thereof, an atomic ratio of In:Zn=2:1 or in the neighborhood thereof, or an atomic ratio of In:Zn=4:1 or in the neighborhood thereof can be used. Alternatively, an indium oxide may be used. A structure containing a slight amount of the element M may be employed. For example, a metal oxide with an atomic ratio of In:Ga:Zn=4:0.1:1 or in the neighborhood thereof or an atomic ratio of In:Ga:Zn=2:0.1:1 or in the neighborhood thereof can be used. For another example, a metal oxide with an atomic ratio of In:Sn:Zn=4:0.1:1 or in the neighborhood thereof or an atomic ratio of In:Sn:Zn=2:0.1:1 or in the neighborhood thereof can be used.

The oxide semiconductor 30a and the oxide semiconductor 30c can be metal oxides with a high proportion of In. It is particularly preferable that each of the oxide semiconductor 30a and the oxide semiconductor 30c be a metal oxide having a higher proportion of In than the oxide semiconductor 30b. The oxide semiconductor 30a and the oxide semiconductor 30c can each be formed by an ALD method, for example. It is particularly preferable to use a metal oxide in which the proportion of In is higher than that of the element M. With the use of a metal oxide having a high proportion of In, the on-state current can be increased and the frequency characteristics can be enhanced in a transistor including an oxide semiconductor layer.

An oxide semiconductor with a high In content tends to be polycrystallized. The use of a metal oxide having a polycrystalline structure for a transistor adversely affects the initial characteristics or reliability of the transistor. In the oxide semiconductor layer of one embodiment of the present invention, the crystal orientation of the oxide semiconductor 30b can be reflected in the oxide semiconductor 30a and the oxide semiconductor 30c each having a high In content. Thus, polycrystallization can be inhibited even in the case where a metal oxide with a high In content is used as each of the oxide semiconductor 30a and the oxide semiconductor 30c.

Alternatively, the oxide semiconductor 30a and the oxide semiconductor 30c may each have a structure not containing the element M. For example, an In—Zn oxide may be used. Specifically, an In—Zn oxide with an atomic ratio of In:Zn=1:1 or in the neighborhood thereof, an atomic ratio of In:Zn=2:1 or in the neighborhood thereof, or an atomic ratio of In:Zn=4:1 or in the neighborhood thereof can be used. Alternatively, an indium oxide may be used. A structure containing a slight amount of the element M may be employed for the oxide semiconductor 30a and the oxide semiconductor 30c. Specifically, a metal oxide with an atomic ratio of In:Ga:Zn=4:0.1:1 or in the neighborhood thereof, an atomic ratio of In:Ga:Zn=2:0.1:1 or in the neighborhood thereof, an atomic ratio of In:Sn:Zn=4:0.1:1 or in the neighborhood thereof, or an atomic ratio of In:Sn:Zn=2:0.1:1 or in the neighborhood thereof can be used.

A metal oxide with a high proportion of Ga can be used as each of the oxide semiconductor 30a and the oxide semiconductor 30c. For example, as each of the oxide semiconductor 30a and the oxide semiconductor 30c, a metal oxide having a higher proportion of Ga than the oxide semiconductor 30b can be used. For example, as each of the oxide semiconductor 30a and the oxide semiconductor 30c, it is preferable to use a metal oxide with an atomic ratio of In:Ga:Zn=1:1:1 or in the neighborhood thereof, a metal oxide with an atomic ratio of In:Ga:Zn=1:3:2 or in the neighborhood thereof, or a metal oxide with an atomic ratio of In:Ga:Zn=1:3:4 or in the neighborhood thereof. When the proportion of Ga is increased, the band gap of each of the oxide semiconductor 30a and the oxide semiconductor 30c can be larger than that of the oxide semiconductor 30b in some cases. Thus, the oxide semiconductor 30b is sandwiched between the oxide semiconductor 30a and the oxide semiconductor 30c each having a wide band gap, so that the oxide semiconductor 30b can mainly function as a current path (channel). Furthermore, trap states at the interfaces with the oxide semiconductor 30b and the vicinity thereof can be reduced. Accordingly, a buried-channel transistor where a channel is away from the interface with an insulating layer can be achieved, whereby the field-effect mobility can be increased. Furthermore, the influence of interface states that may be formed on the back channel side is reduced, so that light deterioration (e.g., light negative bias deterioration) of the transistor can be inhibited and the reliability of the transistor can be increased.

Alternatively, one of the oxide semiconductor 30a and the oxide semiconductor 30c can be a metal oxide with a higher proportion of In than the oxide semiconductor 30b, and the other can be a metal oxide with a higher proportion of Ga than the oxide semiconductor 30b.

The oxide semiconductor 30a, the oxide semiconductor 30b, and the oxide semiconductor 30c may each include a stack of layers having the above compositions. For example, the oxide semiconductor 30c may have a structure in which a metal oxide with a high proportion of Ga is stacked over a metal oxide with a high proportion of In.

A metal oxide having the same composition as the oxide semiconductor 30b may be used as each of the oxide semiconductor 30a and the oxide semiconductor 30c. By using the same composition, the oxide semiconductors each easily have the CAAC structure after heat treatment in some cases.

In the oxide semiconductor layer of one embodiment of the present invention, even in the case where a composition in which the CAAC structure is unlikely to be formed in the formation of a single layer is used for the oxide semiconductor 30a and the oxide semiconductor 30c, crystal growth occurs with the oxide semiconductor 30b as a nucleus, so that the whole oxide semiconductor layer including the oxide semiconductor 30a and the oxide semiconductor 30c can have the CAAC structure. Alternatively, the CAAC structure can be formed in a region that includes the oxide semiconductor 30b and at least part of each of the oxide semiconductor 30a and the oxide semiconductor 30c.

Analysis of the composition of the metal oxide used as the oxide semiconductor 30 can be performed by EDX, X-ray photoelectron spectroscopy (XPS), inductively coupled plasma-mass spectrometry (ICP-MS), or inductively coupled plasma-atomic emission spectrometry (ICP-AES). Alternatively, these methods may be combined as appropriate for the analysis. As for an element whose content is low, the actual content may be different from the content obtained by analysis because of the influence of the analysis accuracy. In the case where the content of the element M is low, for example, the content of the element M obtained by analysis may be lower than the actual content.

### [Impurities in Oxide Semiconductor]

The influence of impurities in the oxide semiconductor will be described. The impurities contained in the oxide semiconductor can be quantified by XPS, SIMS, EDX, ICP-MS, ICP-AES, or the like.

It is preferable that a channel formation region of a transistor including an oxide semiconductor in a semiconductor layer contain less oxygen vacancies or have a lower concentration of impurities such as hydrogen, nitrogen, and a metal element than a source region and a drain region. When oxygen vacancies (V_{O}) and impurities are in a channel formation region of an oxide semiconductor, electrical characteristics of the transistor may easily vary and the reliability thereof may worsen. In some cases, hydrogen in the vicinity of oxygen vacancies forms V_{O}H and generates an electron serving as a carrier. Thus, if the channel formation region in the oxide semiconductor includes oxygen vacancies, the transistor tends to have normally-on characteristics. Therefore, V_{O}H in the channel formation region is also preferably reduced. Thus, the channel formation region of the transistor is a high-resistance region having a low carrier concentration. Accordingly, the channel formation region of the transistor can be regarded as an i-type (intrinsic) or substantially i-type region.

In order to obtain stable electrical characteristics of the transistor, reducing the impurity concentration in the oxide semiconductor is effective. Examples of the impurity include hydrogen, carbon, and nitrogen. Note that an impurity in an oxide semiconductor refers to, for example, elements other than the main components of the oxide semiconductor. For example, an element with a concentration of lower than 1 atomic % or lower than 0.1 atomic % is an impurity.

When an oxide semiconductor contains silicon or carbon, which is a Group 14 element, defect states are formed in the oxide semiconductor. Thus, the carbon concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³. The silicon concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This may make the electrical characteristics of the transistor unstable. Thus, the nitrogen concentration in the channel formation region in the oxide semiconductor, which is measured by SIMS, is lower than or equal to 1×10²′ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region in the oxide semiconductor is preferably reduced as much as possible. Specifically, the hydrogen concentration in the channel formation region in the oxide semiconductor, which is measured by SIMS, is lower than 1×10²¹ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region in the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

### [Structure Example of Transistor]

The average thickness of the oxide semiconductor 30 in the channel formation region is preferably less than or equal to 30 nm, further preferably less than or equal to 15 nm, still further preferably less than or equal to 10 nm.

The oxide semiconductor 30a is an oxide semiconductor layer formed on the formation surface. The thickness of the oxide semiconductor 30a is preferably greater than or equal to 0.5 nm and less than or equal to 3 nm.

In cross-sectional observation of the oxide semiconductor 230 in the semiconductor device of one embodiment of the present invention, a state can sometimes be observed where metal atoms included in a metal oxide are arranged in a layered manner in a region having the CAAC structure. In that case, the metal atoms are arranged in a direction perpendicular or substantially perpendicular to the substrate surface, for example.

The metal atoms arranged in a layered manner in the region having the CAAC structure can be observed as bright spots in the cross-sectional TEM image of the oxide semiconductor layer. Thus, when a cross section of the oxide semiconductor 230 in the semiconductor device of one embodiment of the present invention is observed, a state can sometimes be observed where bright spots are arranged in a direction perpendicular or substantially perpendicular to the substrate surface.

The oxide semiconductor 30 that is the AG CAAC can be used as the oxide semiconductor 230 of the transistor 200. As illustrated in FIG. 2B and FIG. 3A, for example, the oxide semiconductor 230 can include the oxide semiconductor 230a, the oxide semiconductor 230b in contact with the oxide semiconductor 230a, and the oxide semiconductor 230c in contact with the oxide semiconductor 230b. Here, the oxide semiconductor 230a corresponds to the oxide semiconductor 30a, the oxide semiconductor 230b corresponds to the oxide semiconductor 30b, and the oxide semiconductor 230c corresponds to the oxide semiconductor 30c.

The above-described pillar (the stack of the layer 293 and the layer 292) corresponds to the layer 29. That is, the formation surface of the oxide semiconductor 230 is the pillar, and the pillar is removed in the transistor 200. In the fabrication process, one side surface of the oxide semiconductor 230a is in contact with the pillar, and the other side surface thereof is in contact with the oxide semiconductor 230b. After the pillar is removed, the one side surface of the oxide semiconductor 230a is in contact with the insulator 250. One side surface of the oxide semiconductor 230b is in contact with the oxide semiconductor 230a, and the other side surface thereof is in contact with the oxide semiconductor 230c. One side surface of the oxide semiconductor 230c is in contact with the oxide semiconductor 230b, and the other side surface thereof is in contact with the insulator 250. Note that the side surface of the pillar is perpendicular or substantially perpendicular to the substrate surface (also referred to as the surface of the insulator 222); thus, the side surface of the oxide semiconductor 230 (the oxide semiconductors 230a to 230c) is also perpendicular or substantially perpendicular to the substrate surface.

As described above, a state where metal atoms are arranged in a layered manner in a direction parallel or substantially parallel to the formation surface is observed in a cross-sectional TEM image of the oxide semiconductor 230 (the oxide semiconductors 230a to 230c). In other words, a state where the metal atoms are arranged in a layered manner in a direction perpendicular or substantially perpendicular to the substrate surface is observed in the cross-sectional TEM image of the oxide semiconductor 230 (the oxide semiconductors 230a to 230c). The c-axis of the AG CAAC can be regarded as being substantially parallel to the normal direction of the side surface of the oxide semiconductor 230.

With the use of the oxide semiconductor 230 that is the AG CAAC in the channel formation region of the transistor 200 in this manner, the transistor can have a high on-state current, high field-effect mobility, a low S value, excellent frequency characteristics, and high reliability.

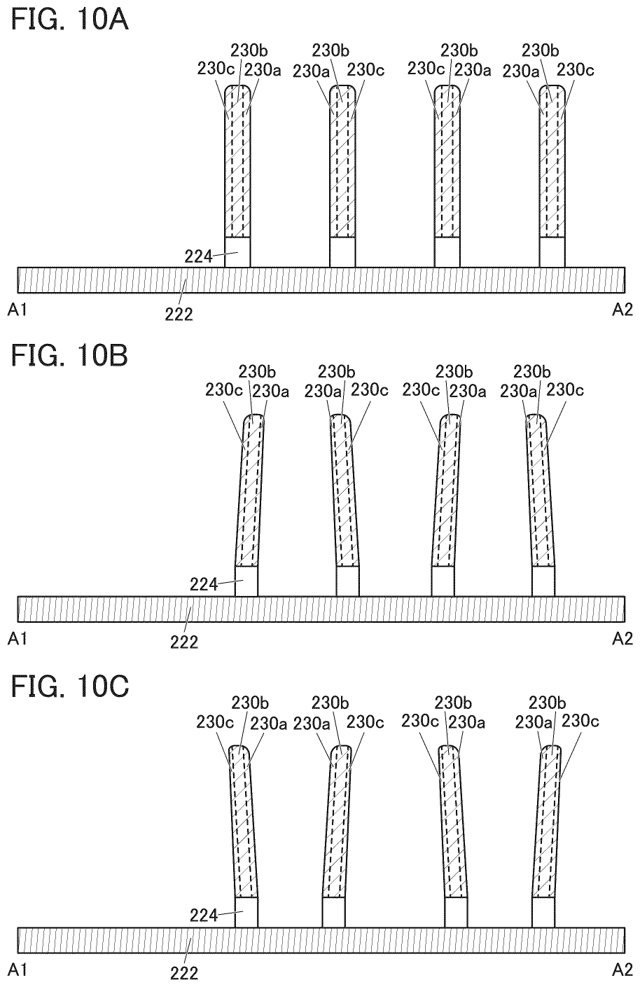

In the case where the oxide semiconductor 230 has a three-layer structure of the oxide semiconductors 230a to 230c as described above, the oxide semiconductor 230a is the closest to a region where the pillar has been formed, followed in order by the oxide semiconductor 230b and the oxide semiconductor 230c. Thus, as illustrated in FIG. 10A, the oxide semiconductor 230c, the oxide semiconductor 230b, the oxide semiconductor 230a, the oxide semiconductor 230a, the oxide semiconductor 230b, and the oxide semiconductor 230c are symmetrically arranged in this order in a cross-sectional view in the channel width direction. That is, in order that the oxide semiconductor 230 can have a symmetrical structure in a cross-sectional view, the oxide semiconductor 230a and the oxide semiconductor 230c preferably have substantially the same compositions. In addition, the oxide semiconductor 230a and the oxide semiconductor 230c preferably have substantially the same thicknesses. In the case where the angle θ in FIG. 2B is greater than or equal to 80° and less than 90°, i.e., the side surface of the oxide semiconductor 230 is slightly inclined, the oxide semiconductors 230 are inclined symmetrically in pairs as illustrated in FIG. 10B. In the case where the oxide semiconductor 230 is formed to be inclined, the upper portion of the oxide semiconductor 230 might be thinner than the lower portion of the oxide semiconductor 230 as illustrated in FIG. 10B. FIG. 10C illustrates an example in which the angle θ is greater than 90°.

In the oxide semiconductor 230, a channel formation region and source and drain regions of the transistor 200 are formed. The channel formation region is sandwiched between the source and drain regions. At least part of the channel formation region overlaps with the conductor 260. The source region overlaps with the conductor 242a, and the drain region overlaps with the conductor 242b. Note that the source region and the drain region can be interchanged with each other.

The channel formation region has a smaller amount of oxygen vacancies or a lower impurity concentration than the source and drain regions, and thus has a low carrier concentration and a high resistance. Thus, the channel formation region can be regarded as an i-type (intrinsic) or substantially i-type region.

The source and drain regions have a large amount of oxygen vacancies or a high concentration of impurities such as hydrogen, nitrogen, and a metal element, and thus are low-resistance regions with a high carrier concentration. In other words, the source and drain regions are n-type regions (low-resistance regions) having a higher carrier concentration than the channel formation region.

Note that the carrier concentration in the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration of the oxide semiconductor 230, the impurity concentration in the oxide semiconductor 230 is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration may be referred to as a highly purified intrinsic or substantially highly purified intrinsic oxide semiconductor (or metal oxide).

In order to obtain stable electrical characteristics of the transistor 200, reducing the impurity concentration in the channel formation region of the oxide semiconductor 230 is effective. In order to reduce the impurity concentration in the oxide semiconductor 230, the impurity concentration in a film adjacent to the oxide semiconductor 230 is preferably reduced. Examples of the impurity include hydrogen, nitrogen, an alkali metal, an alkaline earth metal, iron, nickel, and silicon. Note that the impurity in the oxide semiconductor 230 refers to, for example, elements other than the main components of the oxide semiconductor 230. For example, an element with a concentration of lower than 0.1 atomic % is regarded as an impurity.

In the oxide semiconductor 230, the boundaries between the regions are difficult to clearly observe in some cases. The concentration of a metal element and an impurity element such as hydrogen or nitrogen, which is detected in each region, may be gradually changed not only between the regions but also in each region. That is, the region closer to the channel formation region may have a lower concentration of a metal element and an impurity element such as hydrogen or nitrogen.

If impurities and oxygen vacancies exist in a channel formation region in an oxide semiconductor, a transistor including the oxide semiconductor might have variable electrical characteristics and poor reliability. In some cases, hydrogen in the vicinity of an oxygen vacancy forms a defect that is an oxygen vacancy into which hydrogen enters (hereinafter, sometimes referred to as V_{O}H), which generates an electron serving as a carrier. Therefore, when the channel formation region in the oxide semiconductor includes oxygen vacancies, the transistor tends to have normally-on characteristics (the channel is generated even when no voltage is applied to a gate electrode and current flows through the transistor). Thus, impurities, oxygen vacancies, and V_{O}H are preferably reduced as much as possible in the channel formation region in the oxide semiconductor. In other words, the channel formation region in the oxide semiconductor is preferably an i-type (intrinsic) or substantially i-type region with a low carrier concentration.

By contrast, when an insulator containing oxygen that is released by heating (hereinafter, sometimes referred to as excess oxygen) is provided in the vicinity of the oxide semiconductor and heat treatment is performed, oxygen can be supplied from the insulator to the oxide semiconductor so as to reduce oxygen vacancies and V_{O}H. Note that too much oxygen supplied to the source region or the drain region might cause a decrease in the on-state current or the field-effect mobility of the transistor 200. Furthermore, a variation in the amount of oxygen supplied to the source region or the drain region in the substrate plane leads to variations in characteristics of the semiconductor device including the transistor. When oxygen supplied from the insulator to the oxide semiconductor is diffused into a conductor such as the gate electrode, the source electrode, or the drain electrode, the conductor might be oxidized and the conductivity might be impaired, for example, so that the electrical characteristics and reliability of the transistor might be adversely affected.

Therefore, the oxide semiconductor preferably includes an i-type or substantially i-type channel formation region with a low carrier concentration and n-type source and drain regions with a high carrier concentration. That is, the amounts of oxygen vacancies and V_{O}H in the channel formation region in the oxide semiconductor are preferably reduced. Excessive supply of oxygen to the source and drain regions and excessive reduction in the amount of V_{O}H in the source and drain regions are preferably inhibited. Furthermore, a reduction in the conductivity of the conductor 260, the conductor 242a, the conductor 242b, and the like is preferably inhibited. For example, oxidation of the conductor 260, the conductor 242a, the conductor 242b, and the like is preferably inhibited. Note that hydrogen in an oxide semiconductor can form V_{O}H; thus, the hydrogen concentration needs to be reduced in order to reduce the amount of V_{O}H.

The semiconductor device of this embodiment has a structure in which the hydrogen concentration in the channel formation region is reduced, oxidation of the conductor 242a, the conductor 242b, and the conductor 260 is inhibited, and a reduction in the hydrogen concentration in the source and drain regions is inhibited.

A material that releases little hydrogen is preferably used as a material surrounding the oxide semiconductor layer, e.g., a material used for the insulator in contact with the oxide semiconductor layer. Examples of the material that releases little hydrogen include silicon nitride, silicon nitride oxide, aluminum oxide, and hafnium oxide. The use of such a material can inhibit entry of hydrogen into the oxide semiconductor layer. In particular, the use of silicon nitride for at least one of the insulators in contact with the oxide semiconductor layer can improve the reliability of the transistor. Note that the material that releases little hydrogen sometimes has a function of capturing or fixing (also referred to as gettering) hydrogen in the insulator.

The insulator 250 in contact with the channel formation region in the oxide semiconductor 230 preferably has a function of capturing or fixing hydrogen. This can reduce the hydrogen concentration in the channel formation region in the oxide semiconductor 230. Thus, V_{O}H in the channel formation region can be reduced, so that the channel formation region can be an i-type or substantially i-type region.

As illustrated in FIG. 2A, the insulator 250 preferably has a stacked-layer structure including the insulator 250a in contact with the oxide semiconductor 230, the insulator 250b over the insulator 250a, the insulator 250c over the insulator 250b, and the insulator 250d over the insulator 250c. In that case, the insulator 250a and the insulator 250c preferably have a function of capturing or fixing hydrogen.

An example of the insulator having a function of capturing or fixing hydrogen is a metal oxide having an amorphous structure. For each of the insulator 250a and the insulator 250c, for example, a metal oxide, such as magnesium oxide or an oxide containing aluminum and/or hafnium, is preferably used. In such a metal oxide having an amorphous structure, an oxygen atom has a dangling bond with which hydrogen is captured or fixed in some cases. That is, the metal oxide having an amorphous structure has high capability of capturing or fixing hydrogen.

Moreover, a high dielectric constant (high-k) material is preferably used for each of the insulator 250a and the insulator 250c. An example of the high-k material is an oxide containing aluminum and/or hafnium. With the use of the high-k material for each of the insulator 250a and the insulator 250c, a gate potential applied during operation of the transistor can be reduced while the physical thickness of the gate insulator is being maintained. In addition, the equivalent oxide thickness (EOT) of the insulator functioning as the gate insulator can be reduced.

For each of the insulator 250a and the insulator 250c, an oxide containing aluminum and/or hafnium is preferably used, and an oxide containing aluminum and/or hafnium and having an amorphous structure is further preferably used.

In this embodiment, an aluminum oxide film is used as the insulator 250a. The aluminum oxide film preferably has an amorphous structure. When the insulator 250a is provided in contact with the oxide semiconductor 230, hydrogen contained in the oxide semiconductor 230 or the like can be captured and fixed more effectively.

In this embodiment, hafnium oxide is used for the insulator 250c. When the insulator 250c is provided between the insulator 250b and the insulator 250d, hydrogen contained in the insulator 250b or the like can be captured and fixed more effectively.

An insulator having thermal stability, such as silicon oxide or silicon oxynitride, is preferably used as the insulator 250b. In this specification and the like, an oxynitride refers to a material that contains more oxygen than nitrogen, and a nitride oxide refers to a material that contains more nitrogen than oxygen. For example, silicon oxynitride refers to a material that contains more oxygen than nitrogen, and silicon nitride oxide refers to a material that contains more nitrogen than oxygen.

A silicon oxide film used as the insulator 250b is preferably formed by a PEALD method.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to, for example, the insulator 250a, the insulator 250d, the insulator 250c, and the insulator 275.

In this specification and the like, a barrier insulator refers to an insulator having a barrier property. In this specification and the like, “having a barrier property” means having a property of hindering transmission of a target substance (also referred to as having a low permeability). For example, an insulator having a barrier property hardly allows a target substance to be diffused into the insulator. For another example, an insulator having a barrier property has a function of capturing or fixing (also referred to as gettering) a target substance in the insulator.

Examples of a barrier insulator against oxygen include an oxide containing aluminum and/or hafnium, magnesium oxide, gallium oxide, silicon nitride, and silicon nitride oxide. Examples of the oxide containing aluminum and/or hafnium include aluminum oxide, hafnium oxide, an oxide containing aluminum and hafnium (hafnium aluminate), and an oxide containing hafnium and silicon (hafnium silicate). For example, each of the insulator 250a, the insulator 250c, the insulator 250d, and the insulator 275 preferably has a single-layer structure or a stacked-layer structure of the barrier insulator against oxygen.

The insulator 250a preferably has a barrier property against oxygen. The insulator 250a is preferably less permeable to oxygen than at least the insulator 280 is. The insulator 250a includes a region in contact with the side surface of the conductor 242a and a region in contact with the side surface of the conductor 242b. When the insulator 250a has a barrier property against oxygen, oxidation of the side surfaces of the conductor 242a and the conductor 242b and formation of oxide films on the side surfaces can be inhibited. Accordingly, a reduction in on-state current or field-effect mobility of the transistor 200 can be inhibited.

The insulator 250a is provided in contact with the top and side surfaces of the oxide semiconductor 230 and the top surface of the insulator 222. When the insulator 250a has a barrier property against oxygen, release of oxygen from the channel formation region in the oxide semiconductor 230 caused by heat treatment or the like can be inhibited. This can inhibit formation of oxygen vacancies in the oxide semiconductor 230.

By providing the insulator 250a, excessive supply of oxygen from the insulator 280 to the oxide semiconductor 230 can be inhibited and an appropriate amount of oxygen can be supplied to the oxide semiconductor 230. Thus, excessive oxidation of the source and drain regions can be inhibited, and a reduction in on-state current or field-effect mobility of the transistor 200 can be inhibited.

An oxide containing aluminum and/or hafnium has a barrier property against oxygen and thus can be suitably used for the insulator 250a.

The insulator 250d also preferably has a barrier property against oxygen. The insulator 250d is provided between the conductor 260 and the channel formation region in the oxide semiconductor 230 and between the insulator 280 and the conductor 260. Such a structure can inhibit oxygen contained in the channel formation region in the oxide semiconductor 230 from diffusing into the conductor 260 and thus can inhibit formation of oxygen vacancies in the channel formation region in the oxide semiconductor 230. Oxygen contained in the oxide semiconductor 230 and oxygen contained in the insulator 280 can be inhibited from diffusing into the conductor 260 and oxidizing the conductor 260. The insulator 250d is preferably less permeable to oxygen than at least the insulator 280 is. For example, a silicon nitride film is preferably used as the insulator 250d. In that case, the insulator 250d contains at least nitrogen and silicon.

The insulator 250d preferably has a barrier property against hydrogen. This can prevent diffusion of impurities contained in the conductor 260, such as hydrogen, into the oxide semiconductor 230.

The insulator 275 also preferably has a barrier property against oxygen. The insulator 275 is provided between the insulator 280 and each of the conductor 242a and the conductor 242b. The insulator 275 is provided in contact with the side surface of the conductor 242, the side surface of the oxide semiconductor 230, and the top surface of the insulator 222. This structure can inhibit diffusion of oxygen contained in the insulator 280 into the conductor 242. Accordingly, oxidation of the conductor 242 by oxygen contained in the insulator 280 can be inhibited, so that an increase in resistivity due to the oxidation can be inhibited. The insulator 275 is preferably less permeable to oxygen than at least the insulator 280 is. For example, silicon nitride is preferably used for the insulator 275. In that case, the insulator 275 contains at least nitrogen and silicon.

In order to inhibit a reduction in the hydrogen concentration in the source and drain regions in the oxide semiconductor 230, a barrier insulator against hydrogen is preferably provided in the vicinity of each of the source and drain regions. In the semiconductor device described in this embodiment, the barrier insulator against hydrogen corresponds to, for example, the insulator 275.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the above barrier insulator against hydrogen.

Providing the insulator 275 described above can reduce the amount of hydrogen diffused from the source and drain regions to the outside, so that a reduction in the hydrogen concentration in the source and drain regions can be inhibited. Thus, the source and drain regions can be n-type regions.

With the above structure, the i-type or substantially i-type channel formation region and the n-type source and drain regions can be formed; hence, a semiconductor device can have excellent electrical characteristics. The semiconductor device with the above structure can have excellent electrical characteristics even when being scaled down or highly integrated. Furthermore, scaling down of the transistor 200 can improve the high-frequency characteristics. Specifically, the cutoff frequency can be improved.

The insulators 250a to 250d function as part of the gate insulator. The insulators 250a to 250d are provided together with the conductor 260 in an opening formed in the insulator 280. The thickness of each of the insulators 250a to 250d is preferably small for scaling down of the transistor 200. The thickness of each of the insulators 250a to 250d is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Note that each of the insulators 250a to 250d at least partly includes a region with the above thickness.

The thickness of the silicon oxide film used as the insulator 250 is preferably greater than or equal to 0.7 nm and less than or equal to 3 nm.

In order that the insulators 250a to 250d can have small thicknesses as described above, an ALD method is preferably employed. Furthermore, in the case where the insulators 250a to 250d are provided in the opening in the insulator 280 and the like, an ALD method is preferably employed. Examples of the ALD method include a thermal ALD method, in which a precursor and a reactant react with each other only by a thermal energy, and a PEALD method, in which a reactant excited by plasma is used. A PEALD method utilizing plasma is preferable, in which case film formation at lower temperatures is possible in some cases.

An ALD method enables one atomic layer to be formed at a time, and has various advantages enabling formation of an extremely thin film, film formation on a component with a high aspect ratio, formation of a film with few defects such as pinholes, formation of a film with excellent coverage, low-temperature film formation, and the like. Thus, the insulator 250 can be formed with the above-described small thickness and high coverage on the side surface of the opening portion formed in the insulator 280, the side end portions of the conductor 242a and the conductor 242b, and the like.

Note that a precursor used in the ALD method sometimes contains carbon or the like. Thus, a film formed by the ALD method may contain impurities such as carbon in a larger amount than a film formed by another film formation method. Note that impurities can be quantified by secondary ion mass spectrometry (SIMS), X-ray photoelectron spectroscopy (XPS), or auger electron spectroscopy (AES).

Although the case where the insulator 250 has a four-layer structure of the insulators 250a to 250d is described above, the present invention is not limited to this structure. The insulator 250 can have a structure including at least one of the insulators 250a to 250d. When the insulator 250 is formed using one, two, or three layers selected from the insulators 250a to 250d, the fabrication process of the semiconductor device can be simplified and the productivity can be improved.

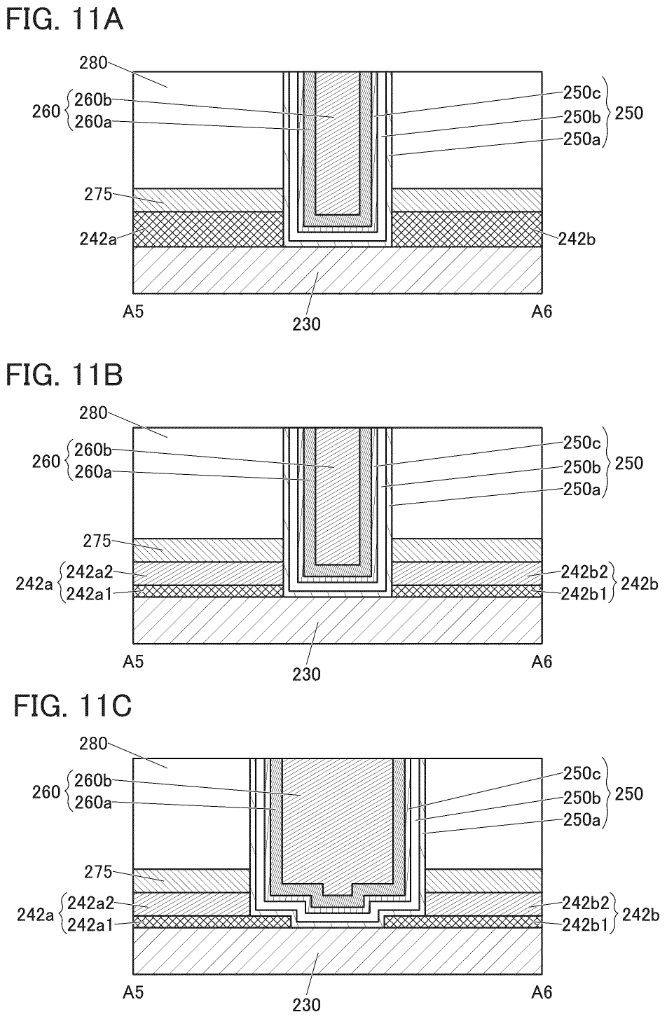

For example, as illustrated in FIG. 11A, the insulator 250 may have a three-layer structure. In that case, the insulator 250 preferably has a stacked-layer structure of the insulator 250a, the insulator 250b over the insulator 250a, and the insulator 250c over the insulator 250b. That is, the stacked-layer structure is obtained by removing the insulator 250d from the structure illustrated in FIG. 2A.

In forming the insulator 250, an ALD process is preferably performed twice or more. For example, the insulator 250 preferably has a stacked-layer structure of a plurality of insulating films, and two or more of the plurality of insulating films are preferably formed through an ALD process. By forming at least two or more insulating films through an ALD process, coverage and thickness uniformity of the insulator 250 can be improved. Moreover, by successively forming two or more different kinds of films, e.g., two or more insulating films, through an ALD process, the productivity can be increased.

In addition to the above structure, a structure is preferably employed in which entry of hydrogen into the transistor 200 and the like is inhibited. For example, an insulator having a function of inhibiting diffusion of hydrogen is preferably provided over and/or below the transistor 200 and the like. In the semiconductor device described in this embodiment, the insulator corresponds to, for example, the insulator 283, the insulator 282, the insulator 222, and the insulator 221. The insulator 215 provided below the transistor 200 may have a structure similar to the structure(s) of the insulator 282 and/or the insulator 283. In that case, the insulator 215 may have a stacked-layer structure of the insulator 282 and the insulator 283; the insulator 283 may be positioned over the insulator 282 or the insulator 282 may be positioned over the insulator 283.

At least one of the insulator 283, the insulator 282, the insulator 222, and the insulator 221 preferably functions as a barrier insulator that inhibits diffusion of impurities such as water and hydrogen from the substrate side or from above the transistor 200 and the like into the transistor 200 and the like. Thus, at least one of the insulator 283, the insulator 282, the insulator 222, and the insulator 221 preferably includes an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom, that is, an insulating material through which the above impurities are less likely to pass. Alternatively, at least one of the insulator 283, the insulator 282, the insulator 222, and the insulator 221 preferably includes an insulating material having a function of inhibiting diffusion of oxygen (e.g., at least one of an oxygen atom, an oxygen molecule, and the like), that is, an insulating material through which the oxygen is less likely to pass.

Each of the insulator 283, the insulator 282, the insulator 222, and the insulator 221 preferably includes an insulator having a function of inhibiting diffusion of oxygen and impurities such as water and hydrogen. Examples of the insulator include aluminum oxide, magnesium oxide, hafnium oxide, zirconium oxide, an oxide containing aluminum and hafnium (hafnium aluminate), an oxide containing hafnium and zirconium (a hafnium zirconium oxide), gallium oxide, silicon nitride, and silicon nitride oxide. For example, silicon nitride, which has a higher hydrogen barrier property, is preferably used for each of the insulator 283 and the insulator 221. For example, aluminum oxide, which has high capability of capturing or fixing hydrogen, is preferably used for the insulator 282. For example, hafnium oxide, which has high capability of capturing or fixing hydrogen and is a high dielectric constant (high-k) material, is preferably used for the insulator 222.

Note that at least one of the insulator 221 and the insulator 222 can have a stacked-layer structure of the above-described material and silicon oxide or silicon oxynitride. For example, the insulator 221 can have a stacked-layer structure of silicon nitride and silicon oxide. For example, the insulator 222 can be a stack of hafnium oxide and silicon oxide.

Such a structure can inhibit impurities such as water and hydrogen from diffusing into the transistor 200 or the like from an interlayer insulating film or the like positioned above the insulator 283. Furthermore, impurities such as water and hydrogen can be inhibited from diffusing into the transistor 200 or the like from an interlayer insulating film or the like positioned below the insulator 221. Moreover, hydrogen contained in the insulator 280, the insulator 250, and the like can be captured and fixed in the insulator 282 or the insulator 222. Providing the insulator 282 and the insulator 283 can inhibit oxygen contained in the insulator 280 and the like from diffusing above the transistor 200 or the like. Providing the insulator 222 and the insulator 221 can inhibit oxygen contained in the oxide semiconductor 230 and the like from diffusing below the transistor 200 or the like. With such a structure in which the transistor 200 is surrounded by the insulators having a function of inhibiting diffusion of oxygen and impurities such as water and hydrogen, excess oxygen and excess hydrogen can be inhibited from diffusing into the oxide semiconductor. This can improve the electrical characteristics and reliability of the semiconductor device.

Moreover, silicon nitride, which has a higher hydrogen barrier property, is preferably used for each of the insulator 275 and the insulator 250d, for example. Aluminum oxide, which has high capability of capturing or fixing hydrogen, is preferably used for the insulator 250a, for example. Hafnium oxide, which has high capability of capturing or fixing hydrogen, is preferably used for the insulator 250c, for example.

A conductive material that is unlikely to be oxidized or a conductive material having a function of inhibiting diffusion of oxygen is preferably used for the conductor 242a, the conductor 242b, and the conductor 260. Examples of the conductive material include a conductive material containing nitrogen and a conductive material containing oxygen. Thus, a decrease in conductivity of the conductor 242a, the conductor 242b, and the conductor 260 can be inhibited. In the case where a conductive material containing a metal and nitrogen is used for each of the conductor 242a, the conductor 242b, and the conductor 260, the conductor 242a, the conductor 242b, and the conductor 260 contain at least a metal and nitrogen.

The conductor 242a and the conductor 242b are provided apart from each other and in contact with the oxide semiconductor 230. As illustrated in FIG. 3C and the like, the conductor 242 is provided to cover the oxide semiconductor 230 having a high aspect ratio. As illustrated in FIG. 1C, the conductor 242a (the conductor 242b) is preferably in contact with two or more fin-shaped regions of the oxide semiconductor 230 in a cross-sectional view.

The conductor 242a is provided such that the conductor 242a is folded in half to sandwich the oxide semiconductor 230 in the vicinity of the source or the drain of the transistor 200 as illustrated in FIG. 3C. Thus, the conductor 242a is in contact with the oxide semiconductor 230 in the upper portion, the side surface on the A3 side, and the side surface on the A4 side of the oxide semiconductor 230 in a cross-sectional view in the channel width direction. Accordingly, the contact area between the conductor 242a and the oxide semiconductor 230 is larger than that in the case where the oxide semiconductor 230 has a flat-plate shape by the side surface on the A3 side and the side surface on the A4 side of the oxide semiconductor 230. The structure illustrated in FIG. 1C in which the conductor 242a is in contact with the plurality of fin-shaped regions of the oxide semiconductor 230 can further increase the contact area. Although FIG. 3C and FIG. 1C illustrate the conductor 242a and its vicinity, the same applies to the conductor 242b. That is, the contact area between the conductor 242b and the oxide semiconductor 230 increases like that between the conductor 242a and the oxide semiconductor 230.

The increase in the contact area between the conductor 242 and the oxide semiconductor 230 enables the transistor 200 to have a high on-state current, excellent frequency characteristics, and the like without an increase in the area occupied by the transistor 200. Thus, a semiconductor device that operates at high speed can be provided. In addition, the operating speed of a memory device including the semiconductor device can be increased. Accordingly, scaling down or high integration of the semiconductor device can be achieved. Moreover, the memory capacity of the memory device including the semiconductor device can be increased.

Since the conductor 242a and the conductor 242b are in contact with the oxide semiconductor 230, a conductive material that is unlikely to be oxidized or a conductive material having a function of inhibiting diffusion of oxygen is preferably used for the conductor 242a and the conductor 242b. This can inhibit a decrease in conductivity of the conductor 242a and the conductor 242b. Extraction of oxygen from the oxide semiconductor 230 is inhibited and accordingly formation of an excess amount of oxygen vacancies can be inhibited. A material that is likely to absorb (extract) hydrogen is preferably used for the conductor 242a and the conductor 242b, in which case the hydrogen concentration in the oxide semiconductor 230 can be reduced.

For the conductor 242, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. For another example, ruthenium, ruthenium oxide, ruthenium nitride, an oxide containing strontium and ruthenium, or an oxide containing lanthanum and nickel may be used. These materials are preferable because they are conductive materials that are not easily oxidized or materials that maintain the conductivity even after absorbing oxygen.

Note that hydrogen contained in the oxide semiconductor 230 or the like diffuses into the conductor 242a or the conductor 242b in some cases. In particular, when a nitride containing tantalum is used for the conductor 242a and the conductor 242b, hydrogen contained in the oxide semiconductor 230 or the like is likely to diffuse into the conductor 242a or the conductor 242b, and the diffused hydrogen is bonded to nitrogen contained in the conductor 242a or the conductor 242b in some cases. That is, hydrogen contained in the oxide semiconductor 230 or the like is sometimes absorbed by the conductor 242a or the conductor 242b.

In order to inhibit a decrease in the conductivity of the conductor 242a and the conductor 242b, an oxide having crystallinity, such as a CAAC-OS, can be used as the oxide semiconductor 230. Specifically, a metal oxide containing one or more selected from indium, zinc, gallium, aluminum, and tin is preferably used. The use of the CAAC-OS can inhibit the conductor 242a or the conductor 242b from extracting oxygen from the oxide semiconductor 230. In addition, a decrease in the conductivity of the conductor 242a and the conductor 242b can be inhibited.

As illustrated in FIG. 11B, the conductor 242a and the conductor 242b may each have a two-layer structure. The conductor 242a can be a stacked-layer film of a conductor 242al and a conductor 242a2 over the conductor 242al, and the conductor 242b can be a stacked-layer film of a conductor 242b1 and a conductor 242b2 over the conductor 242b1. At this time, for a layer (the conductor 242al and the conductor 242b1) in contact with the oxide semiconductor 230, the conductive material that is unlikely to be oxidized or the conductive material having a function of inhibiting diffusion of oxygen is preferably used. This can inhibit a decrease in the conductivity of the conductor 242a and the conductor 242b. Extraction of oxygen from the oxide semiconductor 230 is inhibited and accordingly formation of an excess amount of oxygen vacancies can be inhibited. For a layer (the conductor 242al and the conductor 242b1) in contact with the oxide semiconductor 230, a material that is likely to absorb (extract) hydrogen is preferably used, in which case the hydrogen concentration in the oxide semiconductor 230 can be reduced.

The conductor 242a2 and the conductor 242b2 preferably have higher conductivity than the conductor 242al and the conductor 242b1. For example, the conductor 242a2 and the conductor 242b2 preferably have a larger thickness than the conductor 242al and the conductor 242b1. As each of the conductor 242a2 and the conductor 242b2, a conductor that can be used as the conductor 260b described later can be used. The above-described structure can reduce the resistance of the conductor 242a2 and the conductor 242b2. As a result, the on-state current of the transistor 200 can be increased and the operating speed of the semiconductor device of this embodiment can be improved.

For example, tantalum nitride or titanium nitride can be used for each of the conductor 242a1 and the conductor 242b1, and tungsten can be used for each of the conductor 242a2 and the conductor 242b2.

As illustrated in FIG. 11C, the conductor 242al and the conductor 242b1 may respectively extend beyond the conductor 242a2 and the conductor 242b2 in a cross-sectional view of the transistor 200 in the channel length direction. The extending portions of the conductor 242al and the conductor 242b1 are covered with the insulator 250. The distance between the conductor 242a1 and the conductor 242b1 is shorter than the distance between the conductor 242a2 and the conductor 242b2. With such a structure, the distance between the source and the drain can be shortened, and the channel length can be accordingly shortened. This can improve the frequency characteristics of the transistor 200. In this manner, scaling down of the semiconductor device enables the semiconductor device to operate at higher speed.

As illustrated in FIGS. 1B and 1D, the conductor 260 is provided in the opening formed in the insulator 280 and the insulator 275. The conductor 260 is formed in the opening to cover the top surface of the insulator 222 and the top and side surfaces of the oxide semiconductor 230 with the insulator 250 therebetween. The top surface of the conductor 260 is level or substantially level with the uppermost portion of the insulator 250 and the top surface of the insulator 280.

Note that the sidewall of the opening in which the conductor 260 and the insulator 250 are formed may be perpendicular or substantially perpendicular to the top surface of the insulator 222 or may have a tapered shape. The tapered sidewall can improve the coverage with the insulator 250 and the like formed in the opening in the insulator 280, so that the number of defects such as voids can be reduced.

The conductor 260 functions as the first gate electrode of the transistor 200. Here, the conductor 260 is preferably provided to extend in the channel width direction as illustrated in FIGS. 1A and 1B. With such a structure, the conductor 260 functions as a wiring when a plurality of transistors are provided.

The conductor 260 is provided such that part of the conductor 260 is folded in half to sandwich the fin-shaped oxide semiconductor 230. Thus, as illustrated in FIG. 2B and FIG. 3A, the oxide semiconductor 230 and the conductor 260 face each other with the insulator 250 therebetween in the upper portion, the side surface on the A1 side, and the side surface on the A2 side of the oxide semiconductor 230 in a cross-sectional view in the channel width direction. That is, the upper portion, the side surface on the A1 side, and the side surface on the A2 side of the oxide semiconductor 230 function as a channel formation region. Accordingly, the channel width of the transistor 200 is greater than that in the case where the oxide semiconductor 230 has a flat-plate shape by the side surface on the A1 side and the side surface on the A2 side of the oxide semiconductor 230.

FIG. 1D and the like illustrate the conductor 260 having a two-layer structure. Here, the conductor 260 preferably includes the conductor 260a and the conductor 260b over the conductor 260a. For example, the conductor 260a is preferably provided to cover the bottom and side surfaces of the conductor 260b. In that case, a conductive material that is unlikely to be oxidized or a conductive material having a function of inhibiting diffusion of oxygen is preferably used for the conductor 260a.

The conductor 260a preferably includes a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, the conductor 260a preferably includes a conductive material having a function of inhibiting diffusion of oxygen (e.g., at least one of an oxygen atom and an oxygen molecule).

When the conductor 260a has a function of inhibiting diffusion of oxygen, the conductivity of the conductor 260b can be inhibited from being lowered because of oxidation of the conductor 260b due to oxygen contained in the insulator 280 and the like. As the conductive material having a function of inhibiting diffusion of oxygen, for example, titanium, titanium nitride, tantalum, tantalum nitride, ruthenium, or ruthenium oxide is preferably used.

A conductor having high conductivity is preferably used as the conductor 260b. For example, a conductive material containing tungsten, copper, or aluminum as its main component can be used for the conductor 260b. The conductor 260b may have a stacked-layer structure, for example, a stacked-layer structure of titanium or titanium nitride and the above conductive material.

In the transistor 200, the conductor 260 is formed in a self-aligned manner to fill the opening formed in the insulator 280 and the like. Here, the side surface of the insulator 280 in the opening is aligned or substantially aligned with the side surface of the conductor 242a and the side surface of the conductor 242b. Thus, the conductor 260 can be provided to overlap with a region between the conductor 242a and the conductor 242b without alignment.

The insulator 216 and the insulator 280 preferably have a lower dielectric constant than the insulator 222. In the case where a material with a low dielectric constant is used for interlayer films, parasitic capacitance generated between wirings can be reduced.

For example, each of the insulator 216 and the insulator 280 preferably includes one or more of silicon oxide, silicon oxynitride, silicon oxide to which fluorine is added, silicon oxide to which carbon is added, silicon oxide to which carbon and nitrogen are added, and porous silicon oxide.

Silicon oxide and silicon oxynitride are particularly preferable because of their thermal stability. In particular, materials such as silicon oxide, silicon oxynitride, and porous silicon oxide are preferably used, in which case a region containing oxygen released by heating can be easily formed.

The top surfaces of the insulator 216 and the insulator 280 may be planarized.

The concentration of impurities such as water and hydrogen in the insulator 280 is preferably reduced. For example, the insulator 280 preferably includes an oxide containing silicon, such as silicon oxide or silicon oxynitride.

Each of the conductor 240a and the conductor 240b is formed in an opening in the insulator 275, the insulator 280, the insulator 282, and the insulator 283. The bottom surface of the conductor 240a is in contact with the top surface of the conductor 242a, and the bottom surface of the conductor 240b is in contact with the top surface of the conductor 242b. The top surface of the conductor 240 is substantially level with the top surface of the insulator 283.

The conductor 240 is preferably formed using a conductive material containing tungsten, copper, or aluminum as its main component. The conductor 240 may have a stacked-layer structure in which a first conductor is provided in contact with the side surface of the insulator 241 and a second conductor is provided on the inner side. In that case, the second conductor can be formed using the above conductive material. The first conductor and the second conductor respectively correspond to the conductor 240al and the conductor 240a2 illustrated in FIG. 3C.

In the case where the conductor 240 has a stacked-layer structure, a conductive material having a function of inhibiting transmission of impurities such as water and hydrogen is preferably used for the first conductor in the vicinity of the insulator 283, the insulator 282, the insulator 280, and the insulator 275. For example, tantalum, tantalum nitride, titanium, titanium nitride, ruthenium, or ruthenium oxide is preferably used. The conductive material having a function of inhibiting transmission of impurities such as water and hydrogen can be used as a single layer or stacked layers. With such a structure, impurities such as water and hydrogen contained in the components above the insulator 283 can be inhibited from entering the oxide semiconductor 230 through the conductor 240a and the conductor 240b.

Each of the insulator 241a and the insulator 241b is formed in contact with the inner wall of the opening in the insulator 275, the insulator 280, the insulator 282, and the insulator 283. The inner side surface of the insulator 241a is in contact with the conductor 240a, and the inner side surface of the insulator 241b is in contact with the conductor 240b.

The insulator 241 is formed using the barrier insulating film that can be used as the insulator 275 or the like. As the insulator 241, for example, an insulator such as silicon nitride, aluminum oxide, or silicon nitride oxide is used. Providing the insulator 241 can inhibit entry of impurities such as water and hydrogen contained in the insulator 280 or the like into the oxide semiconductor 230 through the conductor 240a and the conductor 240b. Silicon nitride is particularly preferable because of its high blocking property against hydrogen. Moreover, oxygen contained in the insulator 280 can be prevented from being absorbed into the conductor 240a and the conductor 240b.

When the insulator 241 has a stacked-layer structure as illustrated in FIG. 1D, a first insulator in contact with the inner wall of the opening in the insulator 280 and the like and a second insulator located inward from the first insulator are preferably formed using a combination of a barrier insulating film against oxygen and a barrier insulating film against hydrogen.

For example, aluminum oxide formed by a thermal ALD method is used as the first insulator, and silicon nitride formed by a PEALD method is used as the second insulator. With this structure, oxidation of the conductor 240 can be inhibited, and hydrogen can be inhibited from entering the conductor 240.

Although the insulator 241 has a two-layer structure in the above, the present invention is not limited thereto. For example, the insulator 241 may have a single-layer structure or a stacked-layer structure of three or more layers. Although the conductor 240 has a two-layer structure in the above, the present invention is not limited thereto. For example, the conductor 240 may have a single-layer structure or a stacked-layer structure of three or more layers.

As illustrated in FIG. 3C, for example, the conductor 240a may cover the oxide semiconductor 230 and the conductor 242a that is folded in half to sandwich the oxide semiconductor 230. Thus, the conductor 240a is in contact with the conductor 242a in the upper portion, the side surface on the A3 side, and the side surface on the A4 side of the oxide semiconductor 230 in a cross-sectional view in the channel width direction. Accordingly, the contact area between the conductor 240a and the conductor 242a is larger than that in the case where the oxide semiconductor 230 has a flat-plate shape by the side surface on the A3 side and the side surface on the A4 side of the oxide semiconductor 230. The structure illustrated in FIG. 1C in which the plurality of fin-shaped regions of the oxide semiconductor 230 are covered with the conductor 240a can further increase the contact area between the conductor 240a and the conductor 242a. Although FIG. 3C and FIG. 1C illustrate the conductor 240a, the conductor 242a, and their vicinities, the same applies to the conductor 240b and the conductor 242b. That is, the contact area between the conductor 240b and the conductor 242b increases like that between the conductor 240a and the conductor 242a.

The increase in the contact area between the conductor 240 and the conductor 242 can reduce the contact resistance between the conductor 240 and the conductor 242. This enables the transistor 200 to have a high on-state current, excellent frequency characteristics, and the like without an increase in the area occupied by the transistor 200. Thus, a semiconductor device that operates at high speed can be provided. In addition, the operating speed of a memory device including the semiconductor device can be increased. Accordingly, scaling down or high integration of the semiconductor device can be achieved. Moreover, the memory capacity of the memory device including the semiconductor device can be increased.

Although the opening in which the conductor 240 and the insulator 241 are provided has a quadrangular shape in a top view as illustrated in FIG. 1A, the shape of the opening is not limited thereto. For example, the opening in a top view may have a circular shape, an almost circular shape such as an elliptical shape, a polygonal shape such as a quadrangular shape, or a polygonal shape such as a quadrangular shape with rounded corners. Although the opening is formed to overlap with the plurality of fin-shaped regions of the oxide semiconductor 230, the present invention is not limited thereto, and the opening is formed to overlap with at least the conductor 242a or the conductor 242b. When part of the conductor 240 overlaps with the oxide semiconductor 230, the alignment margin for the conductor 240 can be increased. The opening and the conductor 240 can also be provided in a region not overlapping with the oxide semiconductor 230.

Although the conductor 240a and the conductor 240b are provided symmetrically with respect to the conductor 260 in FIG. 1D, the present invention is not limited thereto. In a cross-sectional view in the channel length direction, a structure may be employed in which part of the conductor 240a overlaps with the oxide semiconductor 230 and the conductor 240b does not overlap with the oxide semiconductor 230. Alternatively, a structure may be employed in which the conductor 240a is provided in a position overlapping with the oxide semiconductor 230 and the conductor 240b is provided in a position not overlapping with the oxide semiconductor 230 in a cross-sectional view in the channel length direction.

### Modification Example 1 of Semiconductor Device

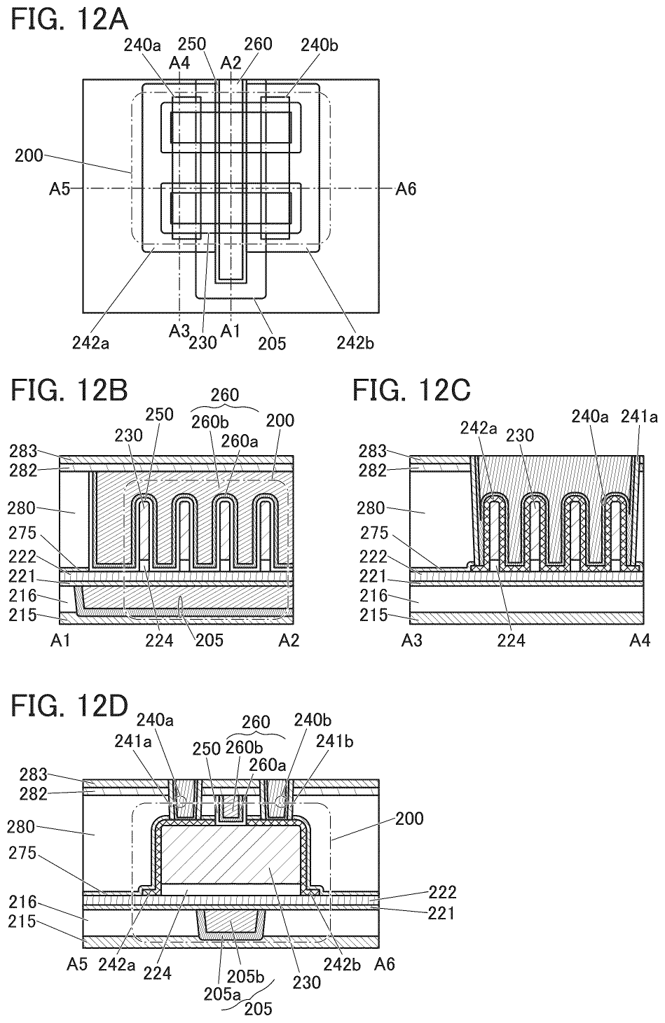

In the semiconductor device of this embodiment, a conductor 205 may be provided under the insulator 221 as illustrated in FIGS. 12A to 12D. The conductor 205 includes a region functioning as a second gate electrode (a lower gate electrode) of the transistor 200. Each of the insulator 224, the insulator 222, and the insulator 221 includes a region functioning as a second gate insulator of the transistor 200. FIGS. 12A to 12D correspond to FIGS. 1A to 1D; thus, refer to the above description for the detailed structure.

In the transistor 200, the conductor 205 is provided to overlap with the oxide semiconductor 230 and the conductor 260. Here, the conductor 205 is preferably provided to fill an opening formed in the insulator 216. As illustrated in FIGS. 12A and 12B, the conductor 205 is preferably provided to extend in the channel width direction. With such a structure, the conductor 205 functions as a wiring when a plurality of transistors are provided.

As illustrated in FIGS. 12B and 12D, the conductor 205 preferably includes a conductor 205a and a conductor 205b. The conductor 205a is provided in contact with the bottom surface and the sidewall of the opening portion. The conductor 205b is provided to fill a depression formed by the conductor 205a formed along the opening portion. The top surface of the conductor 205 is level or substantially level with the top surface of the insulator 216.

The conductor 205a preferably includes a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 205a preferably includes a conductive material having a function of inhibiting diffusion of oxygen (e.g., at least one of an oxygen atom and an oxygen molecule).

When the conductor 205a is formed using a conductive material having a function of inhibiting diffusion of hydrogen, impurities such as hydrogen contained in the conductor 205b can be prevented from diffusing into the oxide semiconductor 230 through the insulator 216 and the like. When a conductive material having a function of inhibiting diffusion of oxygen is used for the conductor 205a, a decrease in conductivity of the conductor 205b due to oxidation of the conductor 205b can be inhibited. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material. For example, the conductor 205a preferably contains titanium nitride.

A conductive material containing tungsten, copper, or aluminum as its main component is preferably used for the conductor 205b. For example, the conductor 205b preferably contains tungsten.

The conductor 205 can function as the second gate electrode. In that case, by changing a potential applied to the conductor 205 independently of a potential applied to the conductor 260, the threshold voltage (Vₜₕ) of the transistor 200 can be controlled. In particular, by applying a negative potential to the conductor 205, Vₜₕ of the transistor 200 can be higher, and its off-state current can be reduced. Thus, drain current at the time when a potential applied to the conductor 260 is 0 V can be lower in the case where a negative potential is applied to the conductor 205 than in the case where the negative potential is not applied to the conductor 205.

The electrical resistivity of the conductor 205 is designed in consideration of the potential applied to the conductor 205, and the thickness of the conductor 205 is determined in accordance with the electrical resistivity. The thickness of the insulator 216 is substantially equal to that of the conductor 205. The conductor 205 and the insulator 216 are preferably as thin as possible in the allowable range of the design of the conductor 205. The insulator 216 with a reduced thickness contains a smaller absolute amount of impurities such as hydrogen, inhibiting the diffusion of the impurities into the oxide semiconductor 230.

Although the stacked-layer structure of the conductor 205a and the conductor 205b is described above, the present invention is not limited to this structure. The conductor 205 may have a single-layer structure or a stacked-layer structure of three or more layers. For example, in the case where the conductor 205 has a three-layer structure, a conductor that contains the same material as the conductor 205a can be further provided over the conductor 205b of the above-described stacked-layer structure of the conductor 205a and the conductor 205b. In that case, the level of the top surface of the conductor 205b is lower than that of an uppermost portion of the conductor 205a, and the conductor may be formed to fill the depression formed by the conductor 205a and the conductor 205b.

### <Materials for Semiconductor Device>

Materials that can be used for the semiconductor device will be described below. Note that the layers included in the semiconductor device may each have a single-layer structure or a stacked-layer structure.

### <<Substrate>>

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example is a semiconductor substrate in which an insulator region is provided in the above semiconductor substrate, such as a silicon on insulator (SOI) substrate. Examples of the conductor substrate include a graphite substrate, a metal substrate, an alloy substrate, and a conductive resin substrate. Examples of the substrate include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided over the substrate include a capacitor, a resistor, a switching element, a light-emitting element, and a memory element.

### <<Insulator>>

Examples of the insulator 215, the insulator 216, the insulator 221, the insulator 222, the insulator 224, the insulator 224b, the insulator 250, the insulator 275, the insulator 280, the insulator 282, the insulator 283, and the like include an insulating oxide, an insulating nitride, an insulating oxynitride, an insulating nitride oxide, an insulating metal oxide, an insulating metal oxynitride, and an insulating metal nitride oxide.

As the insulators, a single layer or stacked layers of an insulator containing one or more of aluminum, magnesium, germanium, indium, gallium, zinc, yttrium, neodymium, tantalum, hafnium, zirconium, lanthanum, chromium, manganese, iron, cobalt, nickel, molybdenum, tungsten, cerium, calcium, strontium, tin, titanium, vanadium, barium, antimony, silicon, germanium, boron, and phosphorus can be used.

With scaling down and high integration of a transistor, for example, a problem such as generation of leakage current may arise because of a thin gate insulator. When a high-k material is used for the insulator functioning as a gate insulator, the voltage at the time of operation of the transistor can be reduced while the physical thickness is being maintained. By contrast, when a material with a low dielectric constant is used for the insulator functioning as an interlayer film, parasitic capacitance generated between wirings can be reduced. Thus, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

A transistor including a metal oxide can have stable electrical characteristics when surrounded by an insulator having a function of inhibiting transmission of oxygen and impurities such as hydrogen. The insulator having a function of inhibiting transmission of oxygen and impurities such as hydrogen can have, for example, a single-layer structure or a stacked-layer structure of an insulator containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as the insulator having a function of inhibiting transmission of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

The insulator functioning as a gate insulator preferably includes a region containing oxygen that is released by heating. For example, silicon oxide or silicon oxynitride that includes a region containing oxygen that is released by heating is provided in contact with the oxide semiconductor 230 to compensate for the oxygen vacancies in the oxide semiconductor 230.

### <<Conductor>>

For the conductors such as the conductor 240a, the conductor 240b, the conductor 242a, the conductor 242b, the conductor 260, and the conductor 205, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like. Examples of the conductors include tantalum nitride, titanium nitride, tungsten, a nitride containing titanium and aluminum, a nitride containing tantalum and aluminum, ruthenium oxide, ruthenium nitride, an oxide containing strontium and ruthenium, and an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high conductivity, typified by polycrystalline silicon containing an impurity element such as phosphorus, or silicide such as nickel silicide may be used.

In the case of using a conductor having a stacked-layer structure, for example, a stacked-layer structure combining a material containing any of the metal elements and a conductive material containing oxygen, a stacked-layer structure combining a material containing any of the metal elements and a conductive material containing nitrogen, or a stacked-layer structure combining a material containing any of the metal elements, a conductive material containing oxygen, and a conductive material containing nitrogen may be employed.

When an oxide is used for the channel formation region of the transistor, the conductor functioning as the gate electrode preferably has a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide in which the channel is formed. A conductive material containing any of the above metal elements and nitrogen may also be used. For example, a conductive material containing nitrogen, such as titanium nitride or tantalum nitride, may be used. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used. With the use of such a material, hydrogen contained in the metal oxide in which the channel is formed can be captured in some cases. Hydrogen entering from a surrounding insulator or the like can also be captured in some cases.

### Example 1 of Method for Fabricating Semiconductor Device

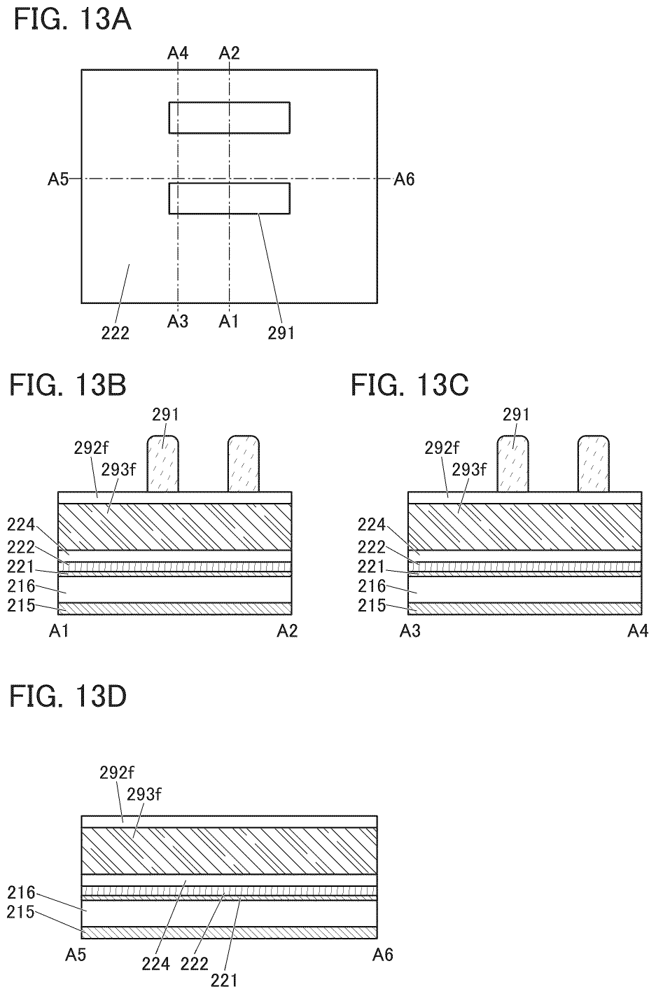

An example of a method for fabricating the semiconductor device of one embodiment of the present invention will be described with reference to FIGS. 13A to 13D to FIGS. 28A to 28D. Here, the case of fabricating the semiconductor device illustrated in FIGS. 1A to 1D will be described as an example.

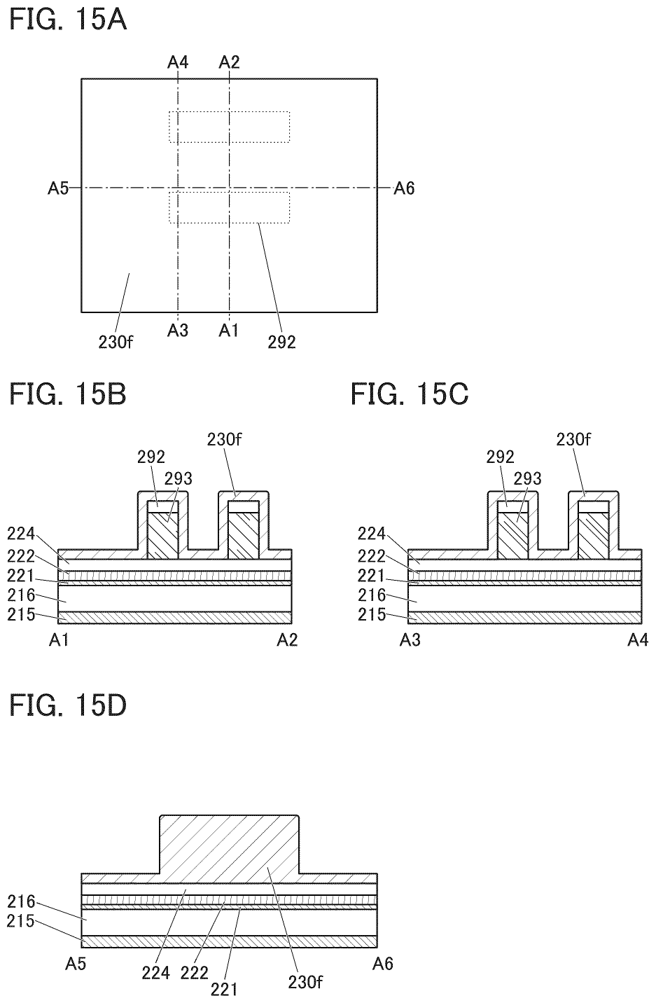

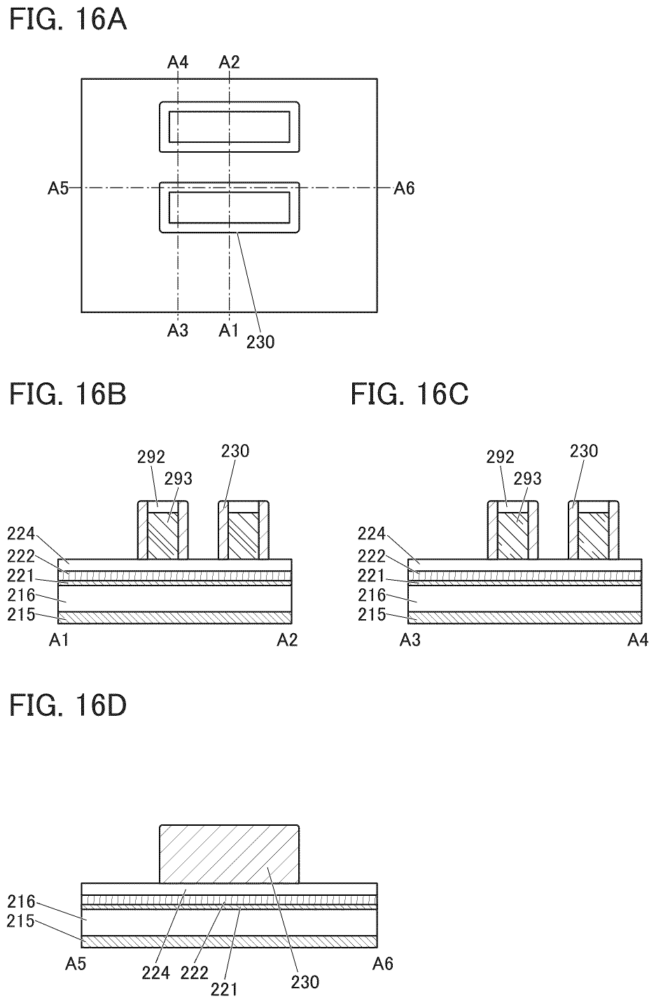

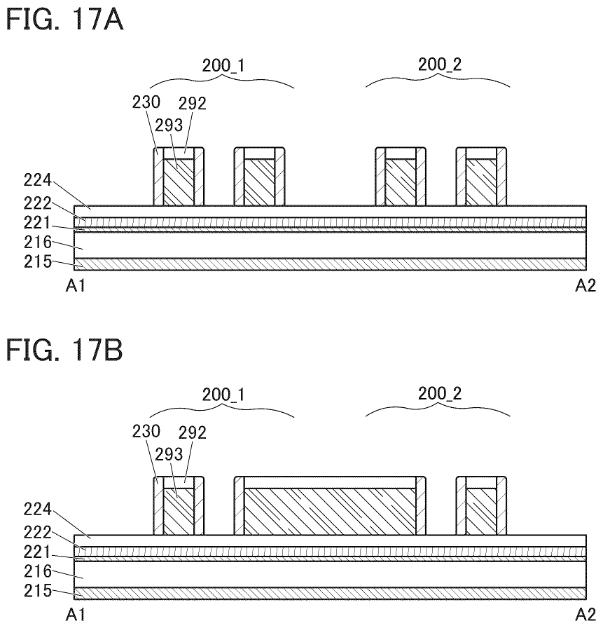

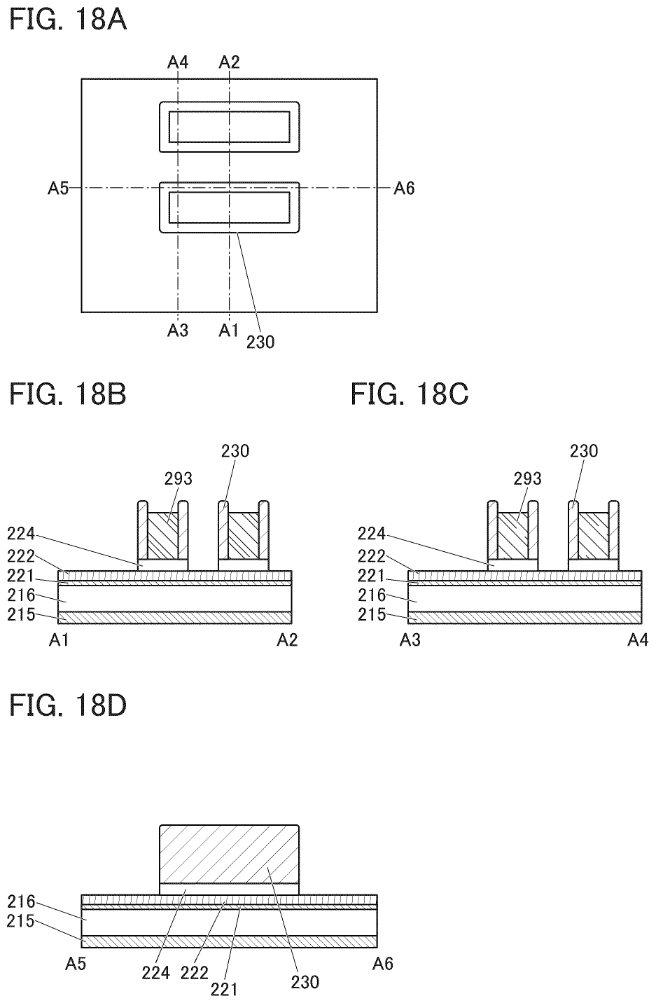

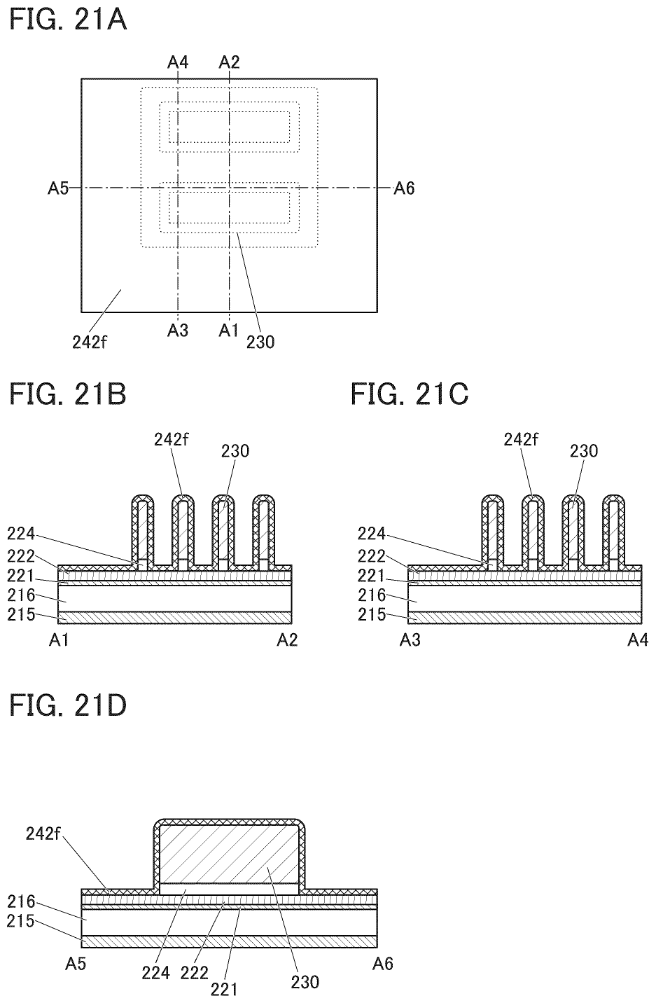

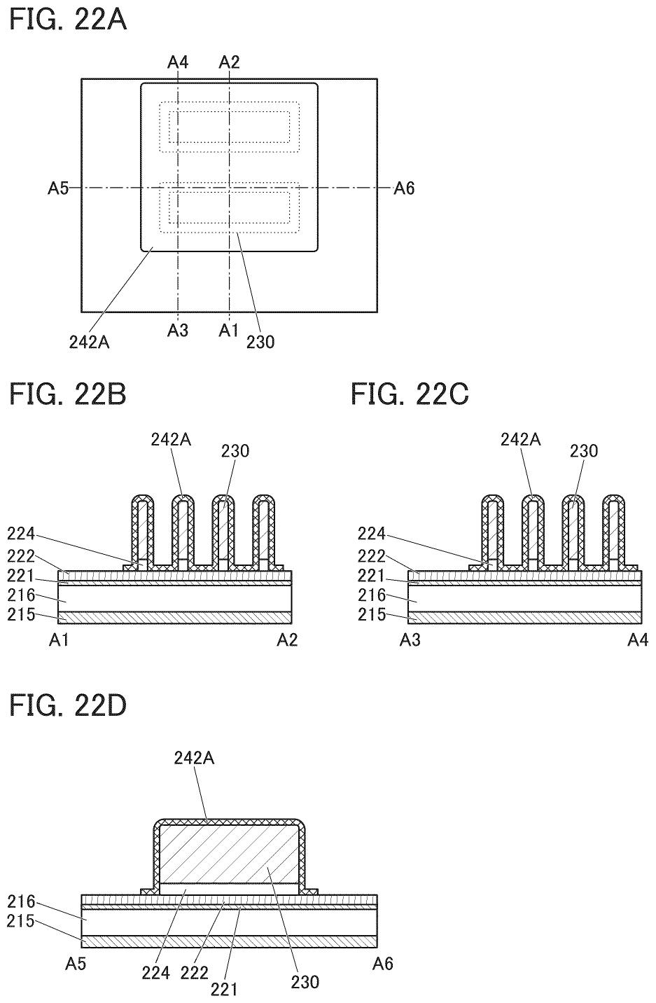

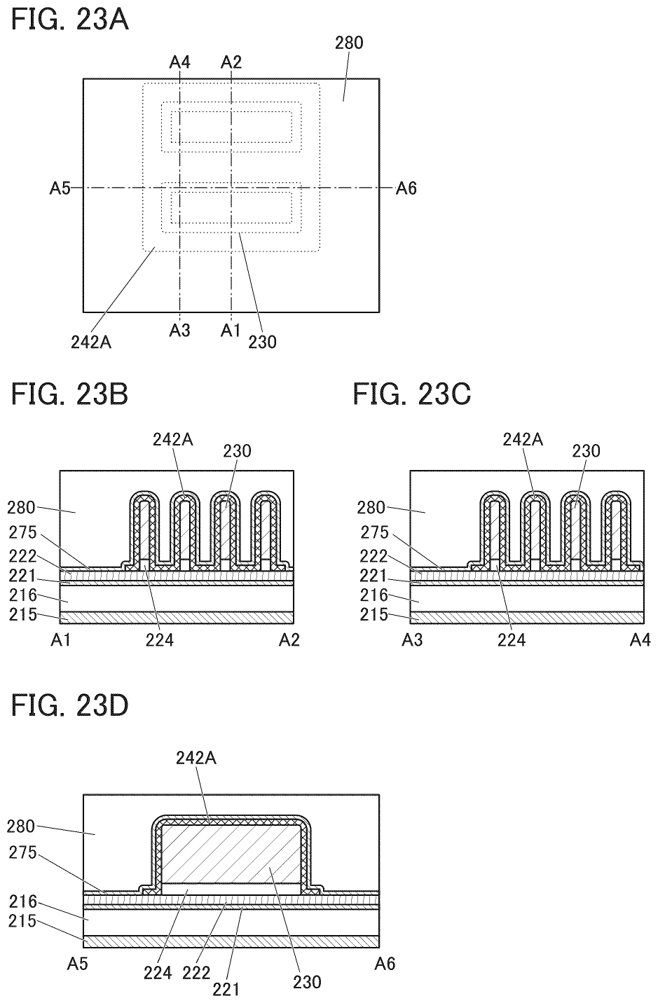

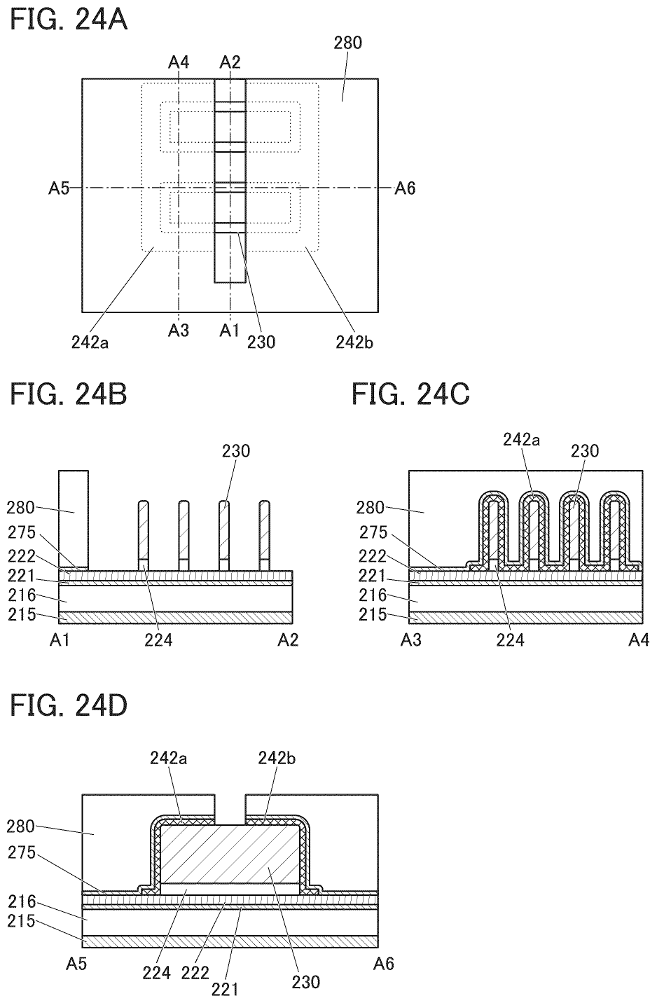

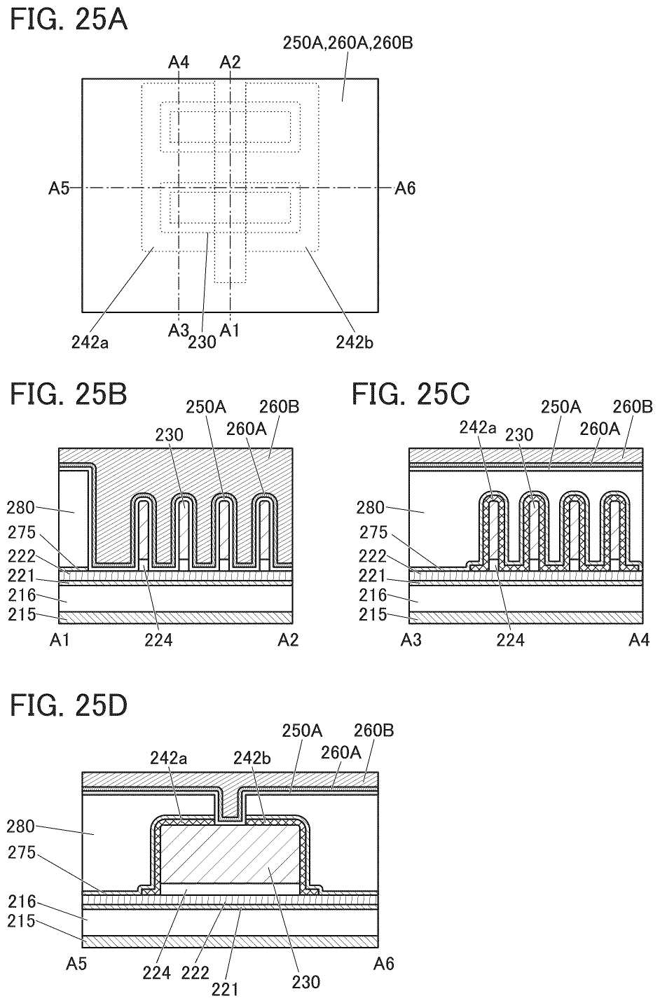

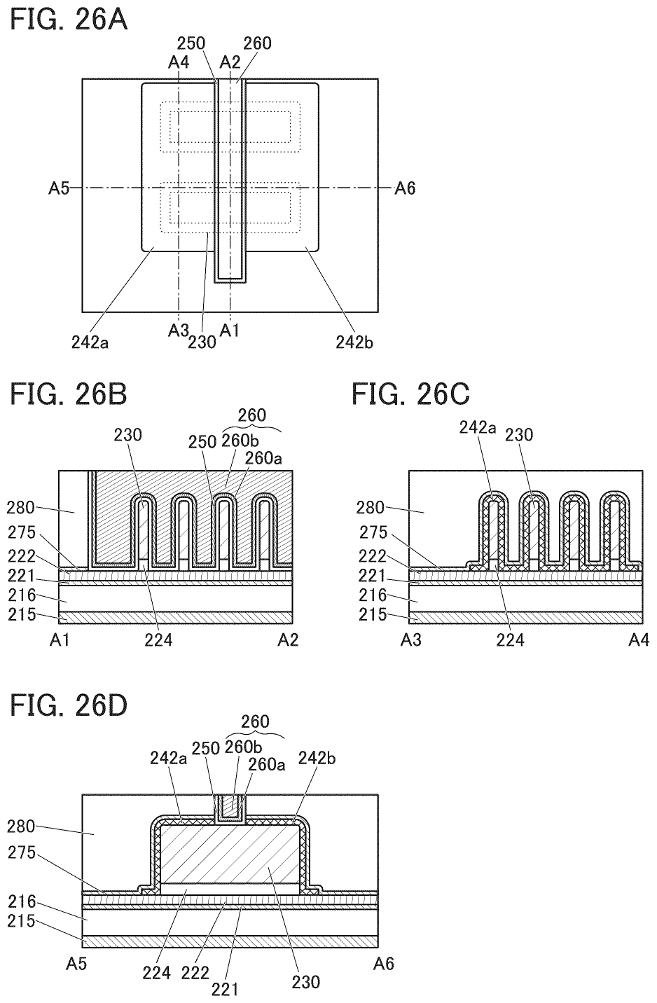

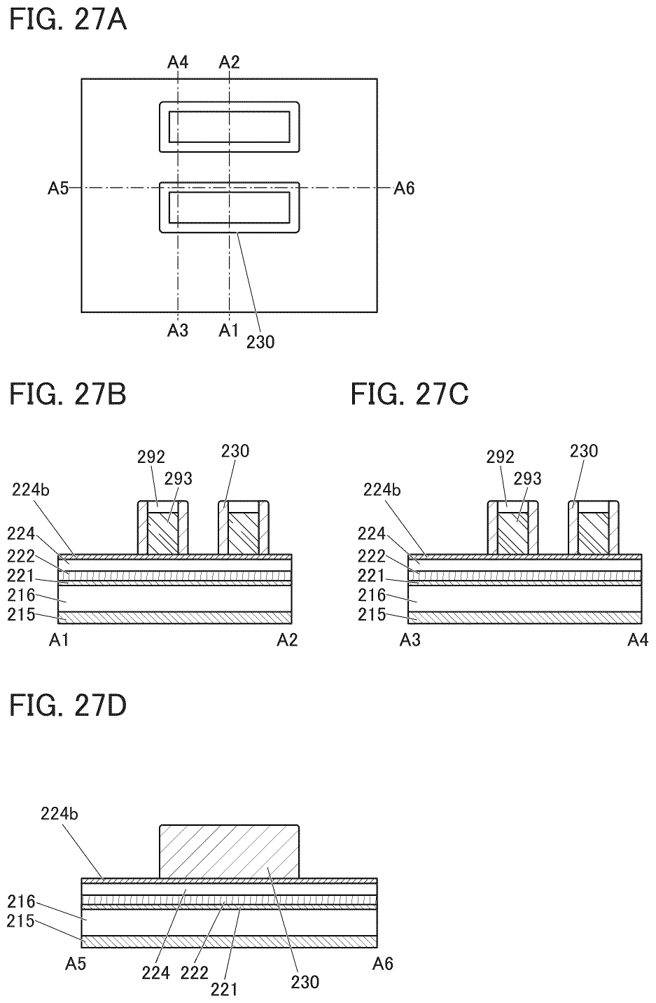

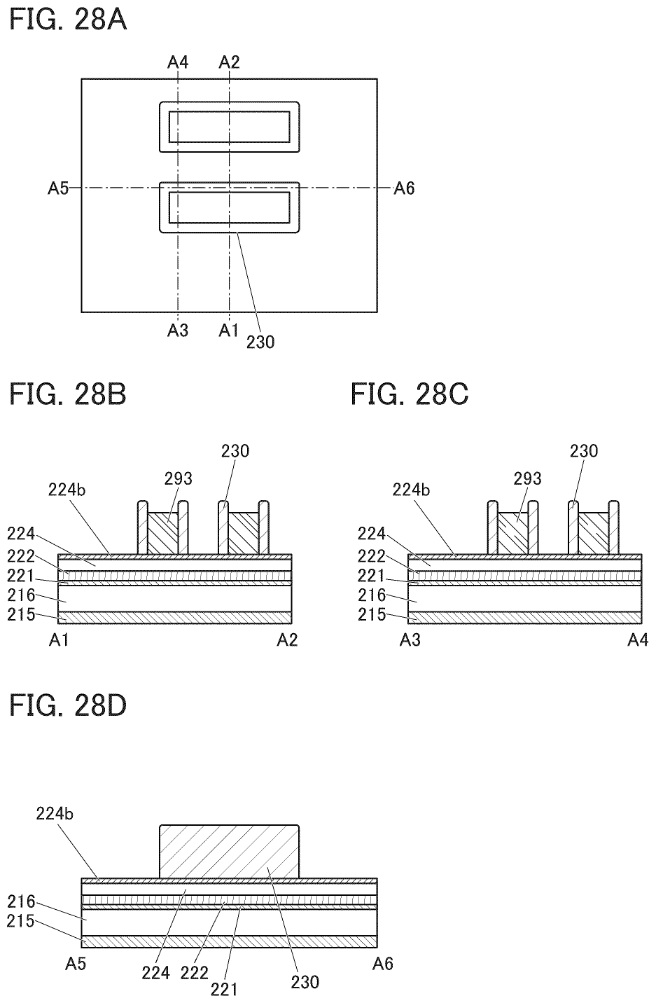

FIG. 13A, FIG. 14A, FIG. 15A, FIG. 16A, FIG. 17A, FIG. 18A, FIG. 19A, FIG. 20A, FIG. 21A, FIG. 22A, FIG. 23A, FIG. 24A, FIG. 25A, FIG. 26A, FIG. 27A, and FIG. 28A are plan views. FIG. 13B, FIG. 14B, FIG. 15B, FIG. 16B, FIG. 17B, FIG. 18B, FIG. 19B, FIG. 20B, FIG. 21B, FIG. 22B, FIG. 23B, FIG. 24B, FIG. 25B, FIG. 26B, FIG. 27B, and FIG. 28B are cross-sectional views taken along the dashed-dotted lines A1-A2 in FIG. 13A, FIG. 14A, FIG. 15A, FIG. 16A, FIG. 17A, FIG. 18A, FIG. 19A, FIG. 20A, FIG. 21A, FIG. 22A, FIG. 23A, FIG. 24A, FIG. 25A, FIG. 26A, FIG. 27A, and FIG. 28A, which correspond to cross-sectional views of the transistor 200 in the channel width direction. FIG. 13C, FIG. 14C, FIG. 15C, FIG. 16C, FIG. 18C, FIG. 19C, FIG. 20C, FIG. 21C, FIG. 22C, FIG. 23C, FIG. 24C, FIG. 25C, FIG. 26C, FIG. 27C, and FIG. 28C are cross-sectional views taken along the dashed-dotted lines A3-A4 in FIG. 13A, FIG. 14A, FIG. 15A, FIG. 16A, FIG. 17A, FIG. 18A, FIG. 19A, FIG. 20A, FIG. 21A, FIG. 22A, FIG. 23A, FIG. 24A, FIG. 25A, FIG. 26A, FIG. 27A, and FIG. 28A, which correspond to cross-sectional views of the transistor 200 in the channel width direction. FIG. 13D, FIG. 14D, FIG. 15D, FIG. 16D, FIG. 18D, FIG. 19D, FIG. 20D, FIG. 21D, FIG. 22D, FIG. 23D, FIG. 24D, FIG. 25D, FIG. 26D, FIG. 27D, and FIG. 28D are cross-sectional views taken along the dashed-dotted lines A5-A6 in FIG. 13A, FIG. 14A, FIG. 15A, FIG. 16A, FIG. 17A, FIG. 18A, FIG. 19A, FIG. 20A, FIG. 21A, FIG. 22A, FIG. 23A, FIG. 24A, FIG. 25A, FIG. 26A, FIG. 27A, and FIG. 28A, which correspond to cross-sectional views of the transistor 200 in the channel length direction. For simplification, some components are not illustrated in the plan views in FIG. 13A, FIG. 14A, FIG. 15A, FIG. 16A, FIG. 17A, FIG. 18A, FIG. 19A, FIG. 20A, FIG. 21A, FIG. 22A, FIG. 23A, FIG. 24A, FIG. 25A, FIG. 26A, FIG. 27A, and FIG. 28A.

In the following steps, an insulating material for forming an insulator, a conductive material for forming a conductor, or a semiconductor material for forming a semiconductor can be formed by a sputtering method, a chemical vapor deposition (CVD) method, a molecular beam epitaxy (MBE) method, a pulsed laser deposition (PLD) method, an ALD method, or the like as appropriate.

Examples of the sputtering method include an RF sputtering method using a high-frequency power source for a sputtering power source, a DC sputtering method using a DC power source, and a pulsed DC sputtering method in which voltage applied to an electrode is changed in a pulsed manner. The RF sputtering method is mainly used for forming an insulating film, and the DC sputtering method is mainly used for forming a metal conductive film. The pulsed DC sputtering method is mainly used for forming a compound such as an oxide, a nitride, or a carbide by a reactive sputtering method.

Note that CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature by a PECVD method. A TCVD method does not use plasma and thus causes less plasma damage to an object to be processed. For example, a wiring, an electrode, an element (e.g., a transistor or a capacitor), or the like included in a semiconductor device may be charged up by receiving charge from plasma. In that case, accumulated charge may break the wiring, electrode, element, or the like included in the semiconductor device. A TCVD method, which does not use plasma, does not cause such plasma damage, and thus can increase the yield of the semiconductor device. A TCVD method yields a film with few defects because of no plasma damage during film formation.

As the ALD method, a thermal ALD method, in which a precursor and a reactant react with each other only by a thermal energy, a PEALD method, in which a reactant excited by plasma is used, or the like can be used.

A CVD method and an ALD method differ from a sputtering method in which particles ejected from a target or the like are deposited. Thus, a CVD method and an ALD method can provide good step coverage, almost regardless of the shape of an object to be processed. In particular, an ALD method allows excellent step coverage and excellent thickness uniformity and can be suitably used to cover a surface of an opening portion with a high aspect ratio, for example. Note that an ALD method has a relatively low film formation rate; hence, in some cases, an ALD method is preferably combined with another film formation method with a high film formation rate, such as a CVD method.

By a CVD method, a film with a desired composition can be formed by adjusting the flow rate ratio of the source gases. For example, a CVD method enables a film with a gradually-changed composition to be formed by changing the flow rate ratio of the source gases during film formation. In the case where a film is formed while the flow rate ratio of the source gases is being changed, as compared to the case where a film is formed using a plurality of film formation chambers, the time taken for the film formation can be shortened because the time taken for transfer and pressure adjustment is omitted. Hence, the productivity of the semiconductor device can be improved in some cases.

An ALD method, in which a plurality of different kinds of precursors are introduced at a time, enables formation of a film with a desired composition. In the case where a plurality of different kinds of precursors are introduced, the cycle number of precursor deposition is controlled, whereby a film with a desired composition can be formed.

In the following steps, dry etching, wet etching, or the like can be used in etching treatment.

As an etching gas for the dry etching treatment, for example, a gas containing halogen can be used.

As the gas containing halogen, for example, an etching gas containing one or more of fluorine, chlorine, and bromine can be used. A fluorocarbon gas, a hydrofluorocarbon gas, a SF₆ gas, a Cl₂ gas, a BCl₃ gas, a SiCl₄ gas, a BBr₃ gas, and the like can be used alone or in combination. As the fluorocarbon gas, a gas represented by CₓF_{y} (y≤2x+2) can be used. Examples of the fluorocarbon gas satisfying y=2x+2 include saturated carbon fluoride compounds such as CF₄, C₂F₆, C₃F₈, C₄F₁₀, and C₅F₁₂. Examples of the fluorocarbon gas satisfying y<2x+2 include unsaturated carbon fluoride compounds such as C₂F₄, C₂F₂, C₃F₇, C₃F₄, C₄F₈, C₄F₆, C₄F₄, C₄F₂, C₅F₁₀, C₅F₈, C₅F₆, and C₅F₄. Examples of the hydrofluorocarbon gas include a CHF₃ gas and a CH₂F₂ gas.

In the case where the gas containing halogen is used as the etching gas, an oxygen (O₂) gas, a carbonic acid gas, a nitrogen (N₂) gas, a helium gas, an argon gas, a hydrogen gas, a hydrocarbon gas, or the like can be added as appropriate.

A gas containing a hydrocarbon gas or a hydrogen gas and not containing a halogen gas can also be used as the etching gas.

As the hydrocarbon gas, for example, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used.

In the case where the hydrocarbon gas is used as the etching gas, a nitrogen gas, a helium gas, an argon gas, a hydrogen gas, or the like can be added as appropriate.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, different high-frequency voltages may be applied to one of the parallel plate electrodes. Further alternatively, high-frequency voltages with the same frequency may be applied to the parallel plate electrodes. Still further alternatively, high-frequency voltages with different frequencies may be applied to the parallel plate electrodes. A dry etching apparatus including a high-density plasma source can be used. As the dry etching apparatus including a high-density plasma source, an inductively coupled plasma (ICP) etching apparatus can be used, for example. The etching apparatus can be set as appropriate depending on an object to be etched.

First, a substrate (not illustrated) is prepared, and the insulator 215 is formed over the substrate (see FIGS. 13A to 13D). As described above, the insulator 215 can be formed with the same insulator as either the insulator 282 or the insulator 283 or a stacked film including both of them. The insulator 215 can be formed by, for example, a sputtering method, a CVD method, an MBE method, a PLD method, or an ALD method. A sputtering method that does not need to use a molecule containing hydrogen as a film formation gas is preferably used, in which case the hydrogen concentration in the insulator 215 can be reduced.

Next, the insulator 216 is formed over the insulator 215 (see FIGS. 13A to 13D). The insulator 216 is preferably formed by a sputtering method. By using a sputtering method that does not need to use a molecule containing hydrogen as a film formation gas, the hydrogen concentration in the insulator 216 can be reduced. Note that the insulator 216 may be formed by a CVD method, an MBE method, a PLD method, an ALD method, or the like as well as a sputtering method. In this embodiment, silicon oxide is formed as the insulator 216 by a sputtering method.

The insulator 215 and the insulator 216 are preferably formed successively without exposure to the air. For example, a multi-chamber film formation apparatus is used. As a result, the amount of hydrogen in the formed insulator 215 and the insulator 216 can be reduced, and furthermore, entry of hydrogen in the films between film formation steps can be inhibited.

An opening reaching the insulator 215 is formed in the insulator 216 and the conductor 205 is formed in the opening, so that the transistor 200 illustrated in FIGS. 12A to 12D can be formed. The conductor 205 is formed in the following manner: a conductive film that can be used for the conductor 205 is formed to fill the opening and part of the conductive film is removed by CMP treatment.

Next, the insulator 221 is formed over the insulator 216 (see FIGS. 13A to 13D).

An insulator having a barrier property against oxygen, hydrogen, and water is used as the insulator 221. The insulator 221 can be formed by, for example, a sputtering method, a CVD method, an MBE method, a PLD method, or an ALD method. In this embodiment, silicon nitride is formed as the insulator 221 by a PEALD method.

Next, the insulator 222 is formed over the insulator 221 (see FIGS. 13A to 13D).

As the insulator 222, an insulator containing an oxide of one or both of aluminum and hafnium is preferably formed. As the insulator containing an oxide of one or both of aluminum and hafnium, aluminum oxide, hafnium oxide, or an oxide containing aluminum and hafnium (hafnium aluminate) is preferably used, for example. Alternatively, a hafnium zirconium oxide is preferably used. The insulator containing an oxide of one or both of aluminum and hafnium has a barrier property against oxygen, hydrogen, and water. When the insulator 222 has a barrier property against hydrogen and water, diffusion of hydrogen and water contained in a component provided around the transistor into the transistor through the insulator 222 is inhibited, and accordingly oxygen vacancies are less likely to be generated in the oxide semiconductor 230.

The insulator 222 can be formed by, for example, a sputtering method, a CVD method, an MBE method, a PLD method, or an ALD method. In this embodiment, hafnium oxide is formed as the insulator 222 by a thermal ALD method.

Next, the insulator 224 is formed over the insulator 222 (see FIGS. 13A to 13D).

An insulator having thermal stability, such as silicon oxide or silicon oxynitride, is preferably used as the insulator 224. In the etching treatment for the insulator 224, the etching rate of the insulator 222 is preferably low. The insulator 224 may be formed using a material that can be etched at the time of removing the layer 292 described later. The insulator 224 can be formed by, for example, a sputtering method, a CVD method, an MBE method, a PLD method, or an ALD method. In this embodiment, silicon oxide is formed as the insulator 224 by a PEALD method.

The use of silicon nitride having a function of inhibiting diffusion of hydrogen as the insulator 221 can inhibit diffusion of hydrogen from a layer below the transistor 200. Furthermore, the use of hafnium oxide having a function of capturing or fixing hydrogen as the insulator 222 enables hydrogen contained in the oxide semiconductor 230 to be captured or fixed in the insulator 222. This can reduce the hydrogen concentration in the oxide semiconductor 230 and in the vicinity thereof.

Next, a coating film 293f is formed over the insulator 224. Then, a coating film 292f is formed over the coating film 293f (see FIGS. 13A to 13D). The coating film 293f and the coating film 292f may have a function of improving adhesion between a resist mask described later and the insulator 224. The coating film 293f may have a function of improving adhesion between the coating film 292f and the insulator 224. The coating film 293f and the coating film 292f are formed by a spin coating method, for example. The coating film 293f and the coating film 292f are formed using a non-photosensitive organic resin.

The coating film 292f functions as a mask in etching treatment for processing the coating film 293f. Thus, the etching rate of the coating film 292f is preferably lower than that of the coating film 293f in the etching treatment for the coating film 293f. For example, the coating film 293f is a film containing carbon, and the coating film 292f is a film containing silicon and carbon. Specifically, for example, a film containing silicon, oxygen, and carbon can be used as the coating film 292f. For example, a film including a polymer containing silicon and oxygen can be used. In this embodiment, an SOC film is formed as the coating film 293f, and an SOG film is formed as the coating film 292f. As the SOG film, for example, a film containing polysiloxane can be formed by a spin coating method.

The coating film 293f and the coating film 292f each contain an organic solvent such as alcohol or ether at the time of application, but such an organic substance contained may be reduced or removed in later steps or when the semiconductor device is completed. For example, when the SOG film is used as the coating film 292f and treatment such as heat treatment is performed after the application, an inorganic insulating film can sometimes be formed depending on the components of the SOG film, the conditions of the treatment, and the like. Note that the coating films are provided as necessary; only one of the coating films may be used or the coating films are not necessarily provided in the case where a resist mask to be described later can adequately work.

Next, a resist mask 291 is formed over the coating film 292f by a lithography method (see FIGS. 13A to 13D). For the resist mask 291, a photosensitive organic resin that is also referred to as a photoresist is used. For example, a positive or negative photoresist can be used. The photoresist used for the resist mask 291 can be formed to have a uniform thickness by a spin coating method, for example.

In the lithography method, first, a resist is exposed to light through a mask. Next, a region exposed to light is removed or left using a developing solution, so that a resist mask is formed. Then, etching is conducted with the resist mask, whereby a conductor, a semiconductor, an insulator, or the like can be processed into a desired shape. For example, the resist mask can be formed by exposing the resist to KrF excimer laser light, ArF excimer laser light, extreme ultraviolet (EUV) light, or the like. A liquid immersion technique may be employed in which a portion between a substrate and a projection lens is filled with a liquid (e.g., water) to perform light exposure. An electron beam or an ion beam may be used instead of the above-mentioned light. Note that a mask is unnecessary in the case of using an electron beam or an ion beam in some cases.

Heat treatment may be performed after the application of the coating film 293f, the coating film 292f, and a film to be the resist mask 291. For example, the heat treatment is performed at 60° C. or higher.

First, the coating film 292f is processed using the resist mask 291 to form the layer 292. In the case where the SOG film is used as the coating film 292f, for example, a fluorocarbon gas, a hydrofluorocarbon gas, or the like can be used; specifically, CF₄, CHF₃, or the like can be used as an etching gas, for example. An oxygen gas, a nitrogen gas, an argon gas, a helium gas, or the like can also be used.

Next, the coating film 293f is processed using the layer 292 as a mask to form the layer 293 (see FIGS. 14A to 14D). In the case where the SOC film is used as the coating film 293f, for example, an H₂ gas and an N₂ gas can be used as the etching gases. Oxygen and nitrogen, carbon dioxide and carbon monoxide, or the like may be used as the etching gases. Since the SOG film is used as the layer 292, the layer 292 can be prevented from disappearing in the etching step of the coating film 293f. A change in the shape of the layer 292 in the etching step of the coating film 293f is extremely small; thus, the side surface of the layer 293 can be perpendicular or substantially perpendicular to the formation surface (here, the insulator 224). This structure enables a plurality of transistors to be provided in a smaller area at higher density.

The resist mask 291 is preferably removed during the processing of the coating film 293f. The use of an organic film containing carbon, such as the SOC film, as the coating film 293f facilitates removal of the resist mask 291. In the case where the resist mask 291 remains after the formation of the layer 293, the resist mask 291 is preferably removed.

The layer 293 and the layer 292 function as a template for forming the oxide semiconductor 230.

A gas is sometimes adsorbed on an organic resin. In addition, a solvent at the time of the application sometimes remains in the organic resin. Thus, a gas might be released from the layer 293 and the layer 292 by heat applied in a later step, e.g., heat applied at the time of forming a film to be the oxide semiconductor 230 (an oxide semiconductor film 230f described later). Hence, heat treatment is preferably performed after the formation of the layer 293. For example, the heat treatment is preferably performed at higher than or equal to 150° C., further preferably higher than or equal to 200° C. and lower than or equal to 400° C., typically 300° C. or around 300° C. In the case where the heat treatment temperature is 300° C. or around 300° C., the heat treatment time is longer than or equal to 30 seconds and shorter than or equal to 1 hour, for example. The heat treatment can be performed in an atmosphere containing one or more of a nitrogen gas and noble gases. The heat treatment may be performed under reduced pressure.

The heat treatment can reduce the amount of gas released from the layer 293 and the layer 292 in the subsequent formation of the oxide semiconductor film 230f, thereby reducing the influence of the gas release on the film formation atmosphere and the film formation pressure in the formation of the oxide semiconductor film 230f. In addition, separation of the oxide semiconductor film 230f, changes in the shapes of the layer 293 and the layer 292, or the like due to the gas release can be inhibited. Note that the heat treatment sometimes reduces the volume of especially the layer 293. For example, a 2% or more and 15% or less volume reduction may occur. It is preferable that the shape of the layer 293 not be significantly changed by the volume reduction.

Next, the oxide semiconductor film 230f to be the oxide semiconductor 230 is formed to cover the layer 293 and the layer 292 (see FIGS. 15A to 15D). The oxide semiconductor film 230f is a metal oxide film to be the oxide semiconductor 230 in a later step, and the above-described metal oxide film can be used as the oxide semiconductor film 230f. The oxide semiconductor film 230f can be formed by a sputtering method, a CVD method, an MBE method, a PLD method, or an ALD method.

The oxide semiconductor film 230f is formed along the layer 293 and the layer 292. It is particularly preferable to use an organic resin for the layer 293. An organic resin can be removed more easily than an inorganic insulator. This can reduce damage to the oxide semiconductor 230 in a later step of removing the layer 293. On the other hand, an organic resin is damaged by plasma treatment or the like more easily than an inorganic insulator in some cases. Thus, the oxide semiconductor film 230f is preferably formed by a method that causes minimal damage. For example, a layer of the oxide semiconductor film 230f that is in contact with the layer 293 is preferably formed by an ALD method.

Since an ALD method offers good coverage, a film can be suitably formed by an ALD method even on a sidewall of a layer having a high aspect ratio, such as the layer 293.

The oxide semiconductor 230 preferably has a high aspect ratio; thus, the oxide semiconductor film 230f is preferably thin. Hence, the oxide semiconductor film 230f is preferably formed by an ALD method that allows the thickness of a thin film to be adjusted.

The oxide semiconductor film 230f formed in this manner is in contact with the side surfaces of the layer 293 and the layer 292 and the top surface of the layer 292.

Here, the oxide semiconductor film 230f is preferably formed by the same method as the oxide semiconductor 30 described above. When the oxide semiconductor film 230f is formed in this manner, the oxide semiconductor film 230f and the oxide semiconductor 230 are formed in parallel or substantially parallel with the formation surface.

In the case where the oxide semiconductor 230 has a three-layer structure of the oxide semiconductors 230a to 230c as illustrated in FIG. 2B and the like, for example, a film to be the oxide semiconductor 230a and a film to be the oxide semiconductor 230c are formed by an ALD method, and a film to be the oxide semiconductor 230b is formed by a sputtering method. Specifically, the film to be the oxide semiconductor 230a can be formed to have an atomic ratio of In:Zn=2:1 or in the neighborhood thereof. Alternatively, indium oxide may be used for the film to be the oxide semiconductor 230a. The film to be the oxide semiconductor 230b can be formed using an oxide target having an atomic ratio of In:Sn:Zn=4:0.1:1 or in the neighborhood thereof. The film to be the oxide semiconductor 230c can be formed to have an atomic ratio of In:Zn=2:1 or in the neighborhood thereof. Alternatively, indium oxide may be used for the film to be the oxide semiconductor 230c.

Next, heat treatment is preferably performed. The heat treatment is preferably performed in a temperature range where the oxide semiconductor film 230f does not become polycrystal. The heat treatment for the oxide semiconductor film 230f is performed by the same method as the heat treatment for the oxide semiconductor 30 described above.

For example, heat treatment can be performed at 450° C. for one hour at a flow rate ratio of a nitrogen gas to an oxygen gas of 4:1.

When the oxide semiconductor 230 is formed by the above-described method and heat treatment is performed, the oxide semiconductor 230 can be the AG CAAC. Accordingly, the on-state current, the S value, the field-effect mobility, the frequency characteristics, and the like of the transistor 200 can be improved, so that a semiconductor device can have excellent electrical characteristics. Moreover, a highly reliable semiconductor device can be provided.

The heat treatment is preferably performed in a nitrogen gas atmosphere, an inert gas atmosphere, or an atmosphere containing an oxidizing gas at 10 ppm or more, 1% or more, or 10% or more. The heat treatment may be performed under reduced pressure. Alternatively, the heat treatment may be performed in the following manner: heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment is preferably highly purified. The amount of moisture contained in the gas used in the above heat treatment is preferably 1 ppb or less, further preferably 0.1 ppb or less, still further preferably 0.05 ppb or less. The heat treatment using a highly purified gas can prevent entry of moisture or the like into the oxide semiconductor film 230f and the like as much as possible. Note that a highly purified gas can also be used in heat treatment before this step and heat treatment after this step.

With the heat treatment using the above-described oxygen gas, impurities such as carbon, water, and hydrogen in the oxide semiconductor film 230f can be reduced. Impurities in the film are reduced in the above manner, whereby the crystallinity of the oxide semiconductor film 230f can be improved and a dense structure can be obtained. Accordingly, the crystal region in the oxide semiconductor film 230f can be increased, and in-plane variation in a crystal region in the oxide semiconductor film 230f can be reduced. Thus, in-plane variation in electrical characteristics of the transistor can be reduced.

The heat treatment can supply oxygen to the oxide semiconductor film 230f to reduce oxygen vacancies in the oxide semiconductor film 230f. Thus, the reliability of the transistor 200 can be improved.

By the heat treatment, hydrogen contained in the oxide semiconductor film 230f is transferred to the insulator 222 and is absorbed by the insulator 222. In other words, hydrogen contained in the oxide semiconductor film 230f diffuses into the insulator 222. Accordingly, the hydrogen concentration in the insulator 222 increases, whereas the hydrogen concentration in the oxide semiconductor film 230f decreases. Note that the insulator 221 is provided in contact with the bottom surface of the insulator 222, whereby entry of moisture or impurities such as hydrogen from the component below the insulator 221, which is caused by the heat treatment, can be prevented.

Specifically, the oxide semiconductor film 230f (to be the oxide semiconductor 230 later) functions as the channel formation region of the transistor 200. The transistor 200 formed using the oxide semiconductor film 230f with a reduced hydrogen concentration is preferable because of its high reliability.

Next, part of the oxide semiconductor film 230f is removed by anisotropic etching (see FIGS. 16A to 16D). A portion of the oxide semiconductor film 230f that is parallel to the substrate surface is mainly etched, so that the oxide semiconductor 230 having a sidewall shape is formed in contact with the side surfaces of the layer 293 and the layer 292. Although FIGS. 16B and 16C illustrate a structure in which both the A1 side (A3 side) and the A2 side (A4 side) of the upper portion of the oxide semiconductor 230 have a curved shape, the present invention is not limited thereto, and only the side of the oxide semiconductor 230 that is not in contact with the layer 292 and the layer 293 may have a curved shape.

The oxide semiconductor 230 having a high aspect ratio can be formed by anisotropic etching. The use of the oxide semiconductor 230 enables the transistor 200 to have a larger channel width without an increase in the area occupied by the transistor 200, so that the on-state current and frequency characteristics of the transistor 200 can be increased. In addition, the contact area between the oxide semiconductor 230 and each of the conductor 242a and the conductor 242b can be increased without an increase in the area occupied by the transistor 200, so that the on-state current and frequency characteristics of the transistor 200 can be increased.

As illustrated in FIG. 16A, the top surface shape of the oxide semiconductor 230 is an enclosing shape with no endpoints. The oxide semiconductor 230 can be regarded as having an opening in the center portion. In the case where the oxide semiconductor 230 has a three-layer structure of the oxide semiconductors 230a to 230c as described above, the oxide semiconductor 230a is the closest to a region where the stack of the layer 293 and the layer 292 has been formed, followed in order by the oxide semiconductor 230b and the oxide semiconductor 230c in the enclosing-shaped oxide semiconductor 230. Thus, as illustrated in FIG. 10A, the oxide semiconductor 230c, the oxide semiconductor 230b, the oxide semiconductor 230a, the oxide semiconductor 230a, the oxide semiconductor 230b, and the oxide semiconductor 230c are symmetrically arranged in this order in a cross-sectional view in the channel width direction.

Although the structure in which the two enclosing-shaped oxide semiconductors 230 are provided is described above, the present invention is not limited thereto. For example, one or three or more enclosing-shaped oxide semiconductors 230 may be provided. The enclosing-shaped oxide semiconductors 230 may be bonded to each other to form the oxide semiconductor 230 having a plurality of openings. For example, as illustrated in FIG. 4A, the oxide semiconductor 230 can have a shape in which three openings are arranged in the A1-A2 direction in a top view. In that case, three stacks each including the layer 293 and the layer 292 are formed to be adjacent to each other at a short distance in the step illustrated in FIGS. 14A to 14D. For another example, as illustrated in FIG. 4B, the oxide semiconductor 230 can have a lattice shape in a top view. In that case, a lattice-shaped trench is formed in the stack of the layer 293 and the layer 292 in the step illustrated in FIGS. 14A to 14D.

Although the oxide semiconductor 230 has an enclosing shape in the top view of FIG. 16A, part of the oxide semiconductor 230 may be further removed by etching treatment. For example, in the top view of FIG. 16A, the oxide semiconductor 230 can be partly removed to have a rectangular shape extending in the A5-A6 direction.

A dry etching method is preferably used for anisotropic etching of the oxide semiconductor film 230f.

The anisotropic etching is preferably performed under the conditions where the selectivity with respect to the layer 292 and the insulator 224 is high. That is, the etching rate of the oxide semiconductor film 230f is preferably higher than those of the layer 292 and the insulator 224. In the case where the oxide semiconductor film 230f is etched by dry etching, hydrofluorocarbon, CH₄, BBr, HBr, SiCl₄, BCl₃, Cl₂, or the like can be used as an etching gas. In addition to these gases, Ar, O₂, H₂, N₂, or the like can be used. Specifically, a mixed gas of CH₄ and Ar can be used, for example.

Although FIGS. 16A to 16D illustrate the structure in which the two stacks each including the layer 293 and the layer 292 and the two oxide semiconductors 230 are provided in the transistor 200, the present invention is not limited thereto. As illustrated in FIG. 17A, the two stacks each including the layer 293 and the layer 292 and the two oxide semiconductors 230 may be provided in each of two transistors (a transistor 200_1 and a transistor 200_2). Alternatively, as illustrated in FIG. 17B, a structure may be employed in which stacks each including the layer 293 and the layer 292 and having different widths are provided and three fin-shaped oxide semiconductors 230 are provided in each of the transistor 200_1 and the transistor 200_2 in a cross-sectional view in the A1-A2 direction. In that case, the oxide semiconductor 230 is partly removed to have a linear top surface shape extending in the A5-A6 direction, so that the oxide semiconductor 230 of the transistor 200_1 and the oxide semiconductor 230 of the transistor 200_2 are separated from each other.

Next, the layer 292 is removed (see FIGS. 18A to 18D). At this time, part of the insulator 224 is sometimes also etched by the etching treatment for the layer 292 as illustrated in FIGS. 18B to 18D. For example, when the insulator 224 is formed using a material containing oxygen and silicon, the insulator 224 can sometimes be etched at the same time as the layer 292. In this embodiment, for example, the SOG is used for the layer 292 and silicon oxide is used as the insulator 224, so that the layer 292 and the insulator 224 are etched at the same time. The insulator 224 is etched using the layer 293 and the oxide semiconductor 230 as masks.

The layer 292 can be etched by a dry etching method or a wet etching method. In the case where the SOG is used for the layer 292, for example, dry etching can be performed using an etching gas containing a fluorocarbon gas, a hydrofluorocarbon gas, or the like.

Next, the layer 293 is removed (see FIGS. 19A to 19D). The layer 293 can be removed under the conditions used for the processing of the layer 293. In particular, the etching rate of the oxide semiconductor 230 is preferably low. In the case where the SOC is used for the layer 293, for example, dry etching can be performed using an etching gas containing one or more of oxygen, carbon dioxide, and carbon monoxide. For another example, plasma treatment can be performed in an atmosphere containing oxygen, ozone, nitrogen, dinitrogen monoxide, argon, or the like. Here, microwave treatment can be performed as the plasma treatment.

When the layer 293 is removed under the above etching conditions, damage to the surface of the oxide semiconductor 230, deposition of a reaction product on the surface of the oxide semiconductor 230, and the like can be inhibited. The crystallinity of the oxide semiconductor 230 sometimes increases depending on the etching conditions of the layer 293. It is particularly preferable to perform plasma treatment using microwaves, in which case the crystallinity of the oxide semiconductor 230 can be increased.

Next, a region of the insulator 224 that does not overlap with the oxide semiconductor 230 is etched (see FIGS. 20A to 20D). Through the etching, the oxide semiconductor 230 and the insulator 224 can have substantially the same top surface shapes.

In the case where the step of etching the insulator 224 illustrated in FIGS. 20A to 20D is not performed, the semiconductor device illustrated in FIGS. 5A to 5D can be fabricated. In the step illustrated in FIGS. 20A to 20D, the insulator 224 can be etched using the oxide semiconductor 230 as a mask, for example. Such etching might cause damage to the oxide semiconductor 230 used as the mask. In addition, part of the oxide semiconductor 230 used as the mask is sometimes etched by the etching treatment for the insulator 224, so that the shape, the height H, the width L, and the like of the oxide semiconductor 230 might be changed. The process can be simplified by omitting the etching step illustrated in FIGS. 20A to 20D. Furthermore, damage to the oxide semiconductor 230 can be reduced, so that the reliability of the semiconductor device can be increased. By contrast, when the step illustrated in FIGS. 20A to 20D is performed, the structure illustrated in FIGS. 1A to 1D can be formed, in which case a gate electric field from the conductor 260 can be adequately applied even to the lower end portion of the oxide semiconductor 230 both on the outer side and the inner side of the enclosing-shaped oxide semiconductor 230.

Next, a conductive film 242f is formed over the insulator 222 and the oxide semiconductor 230 (see FIGS. 21A to 21D). As the conductive film 242f, a conductor corresponding to the conductor 242a and the conductor 242b is used.

The conductive film 242f can be formed by, for example, a sputtering method, a CVD method, an MBE method, a PLD method, or an ALD method. For example, tantalum nitride is formed as the conductive film 242f by a sputtering method. The conductor 242a and the conductor 242b can each have a stacked-layer structure as illustrated in FIG. 11B and the like. In that case, the conductive film 242f has a stacked-layer structure, for example. The conductive film 242f can have a stacked-layer structure of tantalum nitride and tungsten over the tantalum nitride, for example. When the conductive film 242f is formed to cover the oxide semiconductor 230, the contact area between the oxide semiconductor 230 and each of the conductor 242a and the conductor 242b can be increased without an increase in the area occupied by the transistor 200. This enables the transistor 200 to have a high on-state current and excellent frequency characteristics.

Next, the conductive film 242f is processed into an island shape by a lithography method to form a conductor 242A (see FIGS. 22A to 22D). At this time, the conductor 242A is preferably formed to cover the oxide semiconductor 230. The insulator 222 in a region not overlapping with the conductor 242A is exposed.

The processing can be performed by a dry etching method or a wet etching method. A dry etching method is suitable for fine processing. Refer to the above description for the conditions and an apparatus for the dry etching method.

The side surface of the conductor 242A may be perpendicular or substantially perpendicular to the top surface of the insulator 222. This structure enables a plurality of transistors to be provided in a smaller area at higher density.

Not being limited to the above, the side surfaces of the oxide semiconductor 230 and the conductor 242A may each have a tapered shape. The taper angle of the side surfaces of the oxide semiconductor 230 and the conductor 242A may be, for example, greater than or equal to 60° and less than 90°. With such tapered side surfaces, the coverage with the insulator 275 and the like in a later step can be improved, so that the number of defects such as voids can be reduced.

In the lithography method, first, a resist is exposed to light through a mask. Next, a region exposed to light is removed or left using a developing solution, so that a resist mask is formed. Then, etching is conducted with the resist mask, whereby a conductor, a semiconductor, an insulator, or the like can be processed into a desired shape. For example, the resist mask can be formed by exposing the resist to KrF excimer laser light, ArF excimer laser light, extreme ultraviolet (EUV) light, or the like. A liquid immersion technique may be employed in which a portion between a substrate and a projection lens is filled with a liquid (e.g., water) to perform light exposure. An electron beam or an ion beam may be used instead of the above-mentioned light. Note that a mask is unnecessary in the case of using an electron beam or an ion beam in some cases.

To remove the resist mask which is no longer needed after the processing, dry etching treatment such as ashing using oxygen plasma (hereinafter, referred to as oxygen plasma treatment in some cases) or wet etching treatment may be performed. Alternatively, wet etching treatment may be performed after dry etching treatment, or dry etching treatment may be performed after wet etching treatment.

A hard mask formed of an insulator or a conductor may be used under the resist mask. In the case of using a hard mask, a hard mask with a desired shape can be formed in the following manner: an insulating film or a conductive film that is the material of the hard mask is formed over the conductive film 242f, a resist mask is formed thereover, and then the hard mask material is etched. The etching of the conductive film 242f and the like may be performed after or without removal of the resist mask. In the latter case, the resist mask sometimes disappears during the etching. The hard mask may be removed by etching after the etching of the conductive film 242f. The hard mask does not need to be removed when the hard mask material does not affect the following process or can be utilized in the following process.

The SOC film and the SOG film may be formed between an object to be processed and the resist mask. Using the SOC film and the SOG film as masks can improve the durability of a mask pattern. For example, the SOC film, the SOG film, and the resist mask are formed in this order over the object to be processed and lithography can be performed.

Next, the insulator 275 is formed to cover the conductor 242A, and the insulator 280 is formed over the insulator 275 (see FIGS. 23A to 23D). Any of the above-described insulators can be used as the insulator 275 and the insulator 280.

Here, the insulator 275 is preferably in contact with the top surface of the insulator 222.

As the insulator 280, an insulator having a flat top surface is preferably formed in the following manner: an insulating film to be the insulator 280 is formed and then the insulating film is subjected to CMP treatment. Note that silicon nitride may be formed over the insulator 280 by a sputtering method, for example, and then subjected to CMP treatment until the insulator 280 is exposed.

The insulator 275 and the insulator 280 can be formed by, for example, a sputtering method, a CVD method, an MBE method, a PLD method, or an ALD method.

As the insulator 275, an insulator having a function of inhibiting transmission of oxygen is preferably used. For example, silicon nitride is preferably formed by a PEALD method as the insulator 275. Alternatively, as the insulator 275, it is preferable that aluminum oxide be formed by a sputtering method and silicon nitride be formed thereover by a PEALD method. When the insulator 275 has such a structure, the function of inhibiting diffusion of oxygen and impurities such as water and hydrogen can be improved.

In this manner, the oxide semiconductor 230 and the conductor 242A can be covered with the insulator 275 having a function of inhibiting diffusion of oxygen. This can inhibit direct diffusion of oxygen from the insulator 280 or the like into the oxide semiconductor 230 and the conductor 242A in a later step.

Silicon oxide is preferably formed by a sputtering method as the insulator 280. When an insulating film to be the insulator 280 is formed by a sputtering method in an oxygen-containing atmosphere, the insulator 280 containing excess oxygen can be formed. By using a sputtering method that does not need to use a molecule containing hydrogen as a film formation gas, the hydrogen concentration in the insulator 280 can be reduced. Note that heat treatment may be performed before the formation of the insulating film. The heat treatment may be performed under reduced pressure, and the insulating film may be successively formed without exposure to the air. Such treatment can remove moisture and hydrogen adsorbed on the surface of the insulator 275 and the like and reduce the moisture concentration and the hydrogen concentration in the oxide semiconductor 230. The heat treatment can be performed under the above-described heat treatment conditions.

Next, the conductor 242A, the insulator 275, and the insulator 280 are processed by a lithography method to form an opening reaching the oxide semiconductor 230 and the insulator 222 (see FIGS. 24A to 24D). Here, the conductor 242A is divided into the conductor 242a and the conductor 242b. The opening is formed in a region overlapping with the oxide semiconductor 230.

The above-described method can be used as appropriate as the lithography method. In order to process the opening in the insulator 280 finely, an electron beam or short-wavelength light such as EUV light is preferably used in the lithography method.

The processing is preferably performed by a dry etching method. A dry etching method makes anisotropic etching possible and thus is suitable for forming an opening having a high aspect ratio. Refer to the above description for the conditions and an apparatus for the dry etching method.

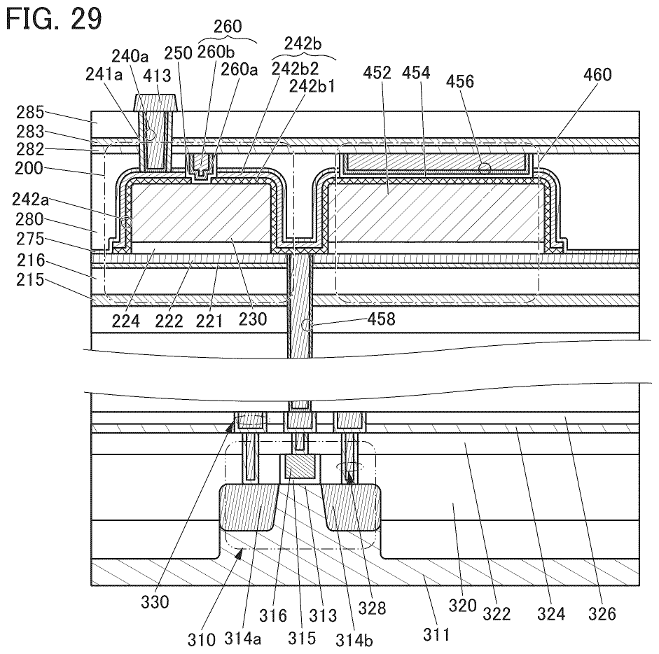

In the case where the structure illustrated in FIG. 11C is formed, the conductor 242al and the conductor 242b1 are preferably formed by further performing etching treatment after the formation of the conductor 242a2 and the conductor 242b2. In the case of such a structure, the transistor 200 and a capacitor 460 described later with reference to FIG. 29 can be formed in parallel. The details will be described later.

Note that ashing treatment using oxygen plasma may be performed after the processing of the conductor 242A. Such oxygen plasma treatment can remove impurities generated by the etching treatment and diffused into the oxide semiconductor 230 or the like. The impurities are generated by a component of the object processed by the above etching treatment and a component contained in a gas or the like used for the etching. Examples of the impurities include chlorine, fluorine, tantalum, silicon, and hafnium. In particular, when a chlorine gas is used in the processing of the conductor 242A as in the above-described etching treatment, the oxide semiconductor 230 is exposed to the atmosphere containing the chlorine gas; thus, chlorine attached to the oxide semiconductor 230 is preferably removed. Removal of impurities attached to the oxide semiconductor 230 in this manner can improve the electrical characteristics and reliability of the transistor.

In order to remove the impurities or the like attached onto the surface of the oxide semiconductor 230 in the etching step, cleaning treatment may be performed. Examples of the cleaning method include wet cleaning using a cleaning solution or the like (which can also be referred to as wet etching treatment), plasma treatment using plasma, and cleaning by heat treatment, and these cleanings may be performed in combination as appropriate. The cleaning treatment sometimes makes the groove deeper.

The wet cleaning may be performed using an aqueous solution in which one or more of ammonia water, oxalic acid, phosphoric acid, and hydrofluoric acid are diluted with carbonated water or pure water; pure water; or carbonated water, for example. Alternatively, ultrasonic cleaning using such an aqueous solution, pure water, or carbonated water may be performed. Further alternatively, these cleanings may be performed in combination as appropriate.

In this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

A frequency greater than or equal to 200 kHz is preferably used for the ultrasonic cleaning, and a frequency greater than or equal to 900 kHz is further preferably used. Damage to the oxide semiconductor 230 and the like can be reduced with this frequency.

The cleaning treatment may be performed a plurality of times, and the cleaning solution may be changed in every cleaning treatment. For example, first cleaning treatment may use diluted hydrofluoric acid or diluted ammonia water and second cleaning treatment may use pure water or carbonated water.

In this embodiment, as the cleaning treatment, wet cleaning is performed with use of diluted ammonia water. The cleaning treatment allows removal of impurities that are attached onto the surface of the oxide semiconductor 230 or the like or diffused into the oxide semiconductor 230 or the like. Furthermore, the crystallinity of the oxide semiconductor 230 can be improved.

After the etching or the cleaning, heat treatment is preferably performed. The heat treatment temperature is higher than or equal to 100° C. and lower than or equal to 650° C., preferably higher than or equal to 250° C. and lower than or equal to 600° C., still further preferably higher than or equal to 300° C. and lower than or equal to 550° C., yet still further preferably higher than or equal to 350° C. and lower than or equal to 400° C. The heat treatment is performed in a nitrogen gas atmosphere, an inert gas atmosphere, or an atmosphere containing an oxidizing gas at 10 ppm or more, 1% or more, or 10% or more. The heat treatment is preferably performed in an oxygen-containing atmosphere. For example, it is preferable that the flow rate ratio of a nitrogen gas to an oxygen gas be 4:1 and the heat treatment be performed at a temperature of 350° C. for one hour. This supplies oxygen to the oxide semiconductor 230 and reduces oxygen vacancies. In addition, the crystallinity of the oxide semiconductor 230 can be improved by the heat treatment. Furthermore, hydrogen remaining in the oxide semiconductor 230 reacts with supplied oxygen, so that the hydrogen can be removed as H₂O (dehydration). This can inhibit recombination of hydrogen remaining in the oxide semiconductor 230 with oxygen vacancies and formation of V_{O}H. Accordingly, a transistor including the oxide semiconductor 230 can have excellent electrical characteristics and high reliability. In addition, variations in electrical characteristics of transistors formed over the same substrate can be reduced. The heat treatment may be performed under reduced pressure. Alternatively, the heat treatment may be performed in the following manner: heat treatment is performed in an oxygen atmosphere, and then another heat treatment is successively performed in a nitrogen atmosphere without exposure to the air. The heat treatment can also serve as the heat treatment performed after the formation of the oxide semiconductor 30c during the formation of the oxide semiconductor 30. Thus, the heat treatment sometimes makes the crystal region of the oxide semiconductor 230 grow.

In the case where heat treatment is performed in a state where the oxide semiconductor 230 is in contact with the conductor 242a and the conductor 242b, the sheet resistance is sometimes reduced in each of a region of the oxide semiconductor 230 that overlaps with the conductor 242a and a region of the oxide semiconductor 230 that overlaps with the conductor 242b. In addition, the carrier concentration may be increased. Thus, the resistance of each of the region of the oxide semiconductor 230 that overlaps with the conductor 242a and the region of the oxide semiconductor 230 that overlaps with the conductor 242b can be lowered in a self-aligned manner.

Next, an insulating film 250A to be the insulator 250 is formed to fill the opening formed in the insulator 280 and the like (see FIGS. 25A to 25D). Here, the insulating film 250A is in contact with the insulator 280, the insulator 275, the conductor 242a, the conductor 242b, the insulator 222, and the oxide semiconductor 230.

The insulating film 250A can be formed by a sputtering method, a CVD method, an MBE method, a PLD method, or an ALD method. For example, the insulating film 250A is preferably formed by an ALD method. Like the above-described insulator 250, the insulating film 250A is preferably formed to have a small thickness, and an unevenness of the thickness needs to be reduced. In the ALD method, a precursor and a reactant (e.g., oxidizer) are alternately introduced to form a film, and the film thickness can be adjusted by the number of repetition times of the sequence of the introduction; thus, accurate adjustment of the film thickness is possible. In addition, the insulating film 250A needs to be formed on the bottom surface and the side surface of the opening so as to have good coverage. One atomic layer can be deposited at a time on the bottom surface and the side surface of the opening by the ALD method, whereby the insulating film 250A can be formed in the opening with good coverage.

When the insulating film 250A is formed by an ALD method, ozone, oxygen, water, or the like can be used as the oxidizer. When an oxidizer without hydrogen, such as ozone or oxygen, is used, the amount of hydrogen diffusing into the oxide semiconductor 230 can be reduced.

The insulator 250 can have a stacked-layer structure. For example, as illustrated in FIG. 2A, the insulator 250 can have a stacked-layer structure of the insulators 250a to 250d. In that case, aluminum oxide can be formed as the insulator 250a by a thermal ALD method, silicon oxide can be formed as the insulator 250b by a PEALD method, hafnium oxide can be formed as the insulator 250c by a thermal ALD method, and silicon nitride can be formed as the insulator 250d by a PEALD method.

Microwave treatment is preferably performed in an oxygen-containing atmosphere after the formation of the insulating film 250A or any of the insulators included in the insulating film 250A. Here, the microwave treatment refers to, for example, treatment using an apparatus including a power source for generating high-density plasma using microwaves. In this specification and the like, a microwave refers to an electromagnetic wave having a frequency higher than or equal to 300 MHz and lower than or equal to 300 GHz.

The microwave treatment is preferably performed with a microwave treatment apparatus including a power source for generating high-density plasma using microwaves, for example. Here, the frequency of the microwave treatment apparatus is preferably set higher than or equal to 300 MHz and lower than or equal to 300 GHz, further preferably higher than or equal to 2.4 GHz and lower than or equal to 2.5 GHz, and can be 2.45 GHz, for example. Oxygen radicals at a high density can be generated with high-density plasma. The electric power of the power source that applies microwaves of the microwave treatment apparatus is preferably set higher than or equal to 1000 W and lower than or equal to 10000 W, further preferably higher than or equal to 2000 W and lower than or equal to 5000 W. The microwave treatment apparatus may be provided with a power source that applies RF to the substrate side. Application of RF to the substrate side allows oxygen ions generated by the high-density plasma to be introduced into the oxide semiconductor 230 efficiently.

The microwave treatment is preferably performed under reduced pressure, and the pressure is preferably higher than or equal to 10 Pa and lower than or equal to 1000 Pa, further preferably higher than or equal to 300 Pa and lower than or equal to 700 Pa. The treatment temperature is preferably lower than or equal to 750° C., further preferably lower than or equal to 500° C., and can be approximately 250° C., for example. The oxygen plasma treatment may be followed successively by heat treatment without exposure to the air. The heat treatment temperature is, for example, preferably higher than or equal to 100° C. and lower than or equal to 750° C., further preferably higher than or equal to 300° C. and lower than or equal to 500° C.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The carrier concentration in the oxide semiconductor 230 can be reduced by thus performing the microwave treatment in an oxygen-containing atmosphere. In addition, preventing introduction of an excess amount of oxygen into the chamber in the microwave treatment can prevent an excessive reduction in the carrier concentration in the oxide semiconductor 230.

The microwave treatment in an oxygen-containing atmosphere converts an oxygen gas into plasma using a high-frequency wave such as a microwave or RF, and applies the oxygen plasma to a region of the oxide semiconductor 230 that is between the conductor 242a and the conductor 242b. By the effects of plasma, a microwave, and the like, V_{O}H in the region can be divided into an oxygen vacancy and hydrogen, and hydrogen can be removed from the region. Here, in the case of the structure illustrated in FIG. 2A and the like, an insulating film (e.g., aluminum oxide) having a function of capturing or fixing hydrogen is preferably used as the insulator 250a. With such a structure, hydrogen generated by the microwave treatment can be captured or fixed in the insulating film 250A. In this manner, the amount of V_{O}H contained in the channel formation region can be reduced. As a result, oxygen vacancies and V_{O}H in the channel formation region can be reduced to lower the carrier concentration. In addition, oxygen radicals generated by the oxygen plasma can be supplied to oxygen vacancies formed in the channel formation region, thereby further reducing oxygen vacancies and lowering the carrier concentration in the channel formation region.

Oxygen implanted into the channel formation region has a variety of forms such as an oxygen atom, an oxygen molecule, an oxygen ion, and an oxygen radical (also referred to as O radical which is an atom, a molecule, or an ion having an unpaired electron). The oxygen implanted into the channel formation region has one or more of the above forms. An oxygen radical is particularly preferable. In addition, the insulator 250 can have a higher film quality, which increases the reliability of the transistor.

Furthermore, the microwave treatment can remove impurities such as carbon in the oxide semiconductor 230. By removing carbon, which is an impurity in the oxide semiconductor 230, the crystallinity of the oxide semiconductor 230 can be increased. Accordingly, the oxide semiconductor 230 can be a CAAC-OS. Particularly in the case where the oxide semiconductor 230 is formed by an ALD method, carbon contained in a precursor is sometimes taken into the oxide semiconductor 230; thus, carbon is preferably removed by the microwave treatment.

Meanwhile, the oxide semiconductor 230 includes a region overlapping with the conductor 242a or the conductor 242b. The region can function as a source region or a drain region. Here, the conductor 242a and the conductor 242b preferably function as a blocking film preventing the effect of the high-frequency wave such as the microwave or the RF, the oxygen plasma, or the like in the microwave treatment in an oxygen-containing atmosphere. Thus, the conductor 242a and the conductor 242b preferably have a function of blocking an electromagnetic wave greater than or equal to 300 MHz and less than or equal to 300 GHz, for example, greater than or equal to 2.4 GHz and less than or equal to 2.5 GHz.

Since the conductor 242a and the conductor 242b prevent the effect of the high-frequency wave such as the microwave or the RF, the oxygen plasma, or the like, the effect does not reach the region of the oxide semiconductor 230 that overlaps with the conductor 242a or the conductor 242b. Hence, a reduction in V_{O}H and supply of an excess amount of oxygen due to the microwave treatment do not occur in the source and drain regions, preventing a decrease in carrier concentration.

In the above manner, oxygen vacancies and V_{O}H can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited and the conductivity (low-resistance regions) before the microwave treatment can be maintained. As a result, a change in the electrical characteristics of the transistor can be inhibited; thus, variations in the electrical characteristics of the transistors in the substrate plane can be inhibited.

The microwave treatment improves the film quality of the insulator 250, thereby inhibiting diffusion of hydrogen, water, impurities, and the like. Accordingly, hydrogen, water, impurities, and the like can be inhibited from diffusing into the oxide semiconductor 230 and the like through the insulator 250 in the following step such as formation of a conductive film to be the conductor 260 or the following treatment such as heat treatment. By thus improving the film quality of the insulator 250, the reliability of the transistor can be improved.

In the case where the insulator 250 has a stacked-layer structure of the insulators 250a to 250d, microwave treatment is preferably performed after the formation of the insulator 250b. Furthermore, microwave treatment may be performed again after the formation of the insulator 250c. As described above, the microwave treatment in an oxygen-containing atmosphere may be performed a plurality of times (at least two or more times). In some cases, the microwave treatment can also serve as the heat treatment performed after the formation of the oxide semiconductor 230. Thus, the microwave treatment sometimes makes the crystal region of the oxide semiconductor 230 grow.

After the microwave treatment, heat treatment may be performed with the reduced pressure being maintained. Such treatment enables hydrogen in the insulating film and the oxide semiconductor 230 to be removed efficiently. Alternatively, the step of performing microwave treatment and then performing heat treatment with the reduced pressure being maintained may be repeated a plurality of cycles. The repetition of the heat treatment enables hydrogen in the insulating film and the oxide semiconductor 230 to be removed more efficiently. Note that the heat treatment temperature is preferably higher than or equal to 300° C. and lower than or equal to 500° C. The heat treatment can also serve as the heat treatment performed after the formation of the oxide semiconductor 230. Thus, the heat treatment sometimes makes the crystal region of the oxide semiconductor 230 grow.

Next, a conductive film 260A to be the conductor 260a and a conductive film 260B to be the conductor 260b are formed in this order (see FIGS. 25A to 25D). The conductive film 260A and the conductive film 260B can be formed by, for example, a sputtering method, a CVD method, an MBE method, a PLD method, a plating method, or an ALD method. In this embodiment, titanium nitride is formed by a CVD method as the conductive film 260A, and tungsten is deposited by a CVD method as the conductive film 260B. Note that the conductive film 260A and the conductive film 260B may be formed while the substrate is being heated. The substrate heating can also serve as the heat treatment performed after the formation of the oxide semiconductor 230. Thus, the substrate heating sometimes makes the crystal region of the oxide semiconductor 230 grow.

Then, the insulating film 250A, the conductive film 260A, and the conductive film 260B are polished by CMP treatment until the insulator 280 is exposed. That is, portions of the insulating film 250A, the conductive film 260A, and the conductive film 260B exposed from the opening are removed. Thus, the insulator 250 and the conductor 260 (the conductor 260a and the conductor 260b) are formed in the opening (see FIGS. 26A to 26D).

Accordingly, the insulator 250 is provided in contact with the insulator 280, the insulator 275, the conductor 242a, the conductor 242b, the oxide semiconductor 230, and the insulator 222 in the opening. The conductor 260 is provided to fill the opening with the insulator 250 therebetween. In this manner, the transistor 200 is formed.

Next, the insulator 282 is formed over the insulator 250, the conductor 260, and the insulator 280 (see FIGS. 1A to 1D). The insulator 282 can be formed by, for example, a sputtering method, a CVD method, an MBE method, a PLD method, or an ALD method. The insulator 282 is preferably formed by a sputtering method. The insulator 282 may be formed in the following manner: a first layer is formed by an ALD method and a second layer is formed over the first layer by a sputtering method.

Forming the insulator 282 in an oxygen-containing atmosphere by a sputtering method can supply oxygen to the insulator 280 during the formation. Thus, excess oxygen can be contained in the insulator 280. The insulator 282 is preferably formed while the substrate is being heated. By forming the insulator 282 in such a manner, a suitable amount of oxygen can be supplied from the insulator 280 to the oxide semiconductor 230 through the insulator 250. Providing the insulator 250a in the insulator 250 can prevent an excess amount of oxygen from being supplied to the insulator 250, thereby preventing the conductor 242a and the conductor 242b in the vicinity of the insulator 250 from being excessively oxidized.

Aluminum oxide is formed using an aluminum target in an atmosphere containing an oxygen gas. The amount of oxygen implanted into the insulator 280 can be controlled depending on the amount of the bias power applied to the substrate in a sputtering method. For example, the amount of oxygen implanted into the insulator 280 is smaller as the bias power is lower, and the amount of oxygen is easily saturated even when the insulator 282 has a small thickness. Furthermore, the amount of oxygen implanted into the insulator 280 is larger as the bias power is higher. With low RF bias power, the amount of oxygen implanted into the insulator 280 can be reduced. Note that in the case where the substrate bias is applied by an RF power source, the RF frequency is preferably 10 MHz or higher. The typical frequency is 13.56 MHz. The higher the RF frequency is, the less damage to the substrate can be.

Forming the second layer by a sputtering method over the first layer formed by an ALD method can protect the upper end portion of the insulator 250 and the top surface of the conductor 260 from an impact of ion collision due to sputtering film formation.

Heat treatment may be performed before the formation of the insulator 282. The heat treatment may be performed under reduced pressure, and the insulator 282 may be successively formed without exposure to the air. Such treatment can remove moisture and hydrogen adsorbed on the surface of the insulator 280 and can reduce the moisture concentration and the hydrogen concentration in the insulator 280. The heat treatment temperature is preferably higher than or equal to 100° C. and lower than or equal to 400° C. In this embodiment, the heat treatment temperature is 250° C.

Next, the insulator 283 is formed over the insulator 282 (see FIGS. 1A to 1D). The insulator 283 can be formed by, for example, a sputtering method, a CVD method, an MBE method, a PLD method, or an ALD method. The insulator 283 is preferably formed by a sputtering method. By using a sputtering method that does not need to use a molecule containing hydrogen as a film formation gas, the hydrogen concentration in the insulator 283 can be reduced. In this embodiment, silicon nitride is formed as the insulator 283 by a sputtering method.

Here, it is preferable to form the insulator 282 and the insulator 283 successively without exposure to the air. Film formation without exposure to the air can prevent attachment of impurities or moisture from the air onto the insulator 282 and the insulator 283, so that an interface between the insulator 282 and the insulator 283 and the vicinity thereof can be kept clean.

In this embodiment, silicon nitride is formed as the insulator 283, and aluminum oxide is formed as the insulator 282. When silicon nitride having a function of inhibiting diffusion of hydrogen is used as the insulator 283 in this manner, diffusion of hydrogen from a layer above the transistor 200 can be inhibited. Furthermore, when aluminum oxide having a function of capturing or fixing hydrogen is used as the insulator 282, hydrogen contained in the insulator 280 or the like can be captured or fixed in the insulator 282. This can reduce the hydrogen concentration in the oxide semiconductor 230 and in the vicinity thereof.

Then, an opening reaching the conductor 242a and an opening reaching the conductor 242b are formed in the insulator 275, the insulator 280, the insulator 282, and the insulator 283 (see FIGS. 1A to 1D). The openings are formed by a lithography method. In the formation of the openings, an object to be processed is preferably processed by a dry etching method. The dry etching method enables anisotropic etching and thus is suitable for forming an opening with a high aspect ratio. In the case of performing anisotropic etching, for example, reactive ion etching is preferably performed. Note that refer to the above description for the conditions and an apparatus for the dry etching method. Although the openings in the top view in FIG. 1A each have a quadrangular shape, the shapes of the openings are not limited thereto. For example, the openings in the top view may each have a circular shape, an almost circular shape such as an elliptical shape, a polygonal shape such as a quadrangular shape, or a polygonal shape such as a quadrangular shape with rounded corners.

Next, heat treatment may be performed after the formation of the openings. The heat treatment temperature is higher than or equal to 100° C. and lower than or equal to 600° C., preferably higher than or equal to 250° C. and lower than or equal to 550° C., further preferably higher than or equal to 350° C. and lower than or equal to 450° C. Note that the heat treatment is preferably performed in a nitrogen gas or inert gas atmosphere. The heat treatment is performed in a state where the conductor 242a and the conductor 242b are exposed; thus, the heat treatment is preferably performed in an atmosphere not containing an oxidizing gas or an oxygen gas. For example, heat treatment is preferably performed at 400° C. in a nitrogen gas atmosphere for one hour. The heat treatment may be performed under reduced pressure. By the heat treatment, oxygen contained in the insulator 280 can be supplied to the oxide semiconductor 230 through the insulator 250. Thus, oxygen vacancies in the channel formation region in the oxide semiconductor 230 can be reduced. The heat treatment can also serve as the heat treatment performed after the formation of the oxide semiconductor 230. Thus, the heat treatment sometimes makes the crystal region of the oxide semiconductor 230 grow.

Here, the side surface of the insulator 280 is exposed in the opening; thus, oxygen contained in the insulator 280 is diffused outwardly by the heat treatment, so that the amount of oxygen contained in the insulator 280 can be controlled. Meanwhile, since the insulator 282 and the insulator 283 each having a barrier property against oxygen are provided over the insulator 280, oxygen is not diffused outwardly from the top surface of the insulator 280. Accordingly, oxygen can be prevented from being excessively diffused from the insulator 280 outwardly and thus oxygen vacancies can be prevented from being formed in the insulator 280. The oxide semiconductor 230, the conductor 242a, and the conductor 242b are covered with the insulator 275. This can prevent direct diffusion of an excess amount of oxygen from the insulator 280 into the oxide semiconductor 230, the conductor 242a, and the conductor 242b in the above heat treatment.

In this manner, the amount of oxygen in the insulator 280 can be adjusted more suitably, and a suitable amount of oxygen can be supplied to the oxide semiconductor 230. Accordingly, oxygen vacancies in the oxide semiconductor 230 can be reduced, and an excess amount of oxygen can be prevented from being supplied to the oxide semiconductor 230. Thus, the electrical characteristics and reliability of the transistor 200 can be improved. Furthermore, a step of exposing the side surface of the insulator 280 can also serve as a step of forming openings in which the conductor 240a and the conductor 240b are embedded; thus, the manufacturing process of the semiconductor device can be simplified.

Next, an insulating film to be the insulator 241 is formed and then subjected to anisotropic etching, so that the insulator 241a is formed in the opening reaching the conductor 242a and the insulator 241b is formed in the opening reaching the conductor 242b (see FIGS. 1A to 1D). The insulating film to be the insulator 241 can be formed by a sputtering method, a CVD method, an MBE method, a PLD method, an ALD method, or the like. The insulating film to be the insulator 241 preferably has a function of inhibiting transmission of oxygen. For example, silicon nitride is preferably formed by a PEALD method. Silicon nitride is preferable because it has a high blocking property against hydrogen.

For anisotropic etching for the insulating film to be the insulator 241, a dry etching method is used, for example. Providing the insulator 241 on the sidewall portions of the openings can inhibit transmission of oxygen from the outside and oxidation of the conductor 240a and the conductor 240b formed in the next step. In addition, diffusion of impurities such as water and hydrogen contained in the insulator 280 or the like into the conductor 240a and the conductor 240b can be prevented. Note that part of each of the top surfaces of the conductor 242a and the conductor 242b may have a depression because of the anisotropic etching.

Next, a conductive film to be the conductor 240a and the conductor 240b is formed. The conductive film to be the conductor 240a and the conductor 240b desirably has a stacked-layer structure including a conductor having a function of inhibiting transmission of impurities such as water and hydrogen. For example, a stacked-layer structure of tantalum nitride, titanium nitride, or the like and tungsten, molybdenum, copper, or the like can be employed. The conductive film to be the conductor 240a and the conductor 240b can be formed by a sputtering method, a CVD method, an MBE method, a PLD method, an ALD method, or the like.

Next, the conductive film to be the conductor 240a and the conductor 240b is partly removed by CMP treatment to expose the top surface of the insulator 283. As a result, the conductive film remains only in the openings, whereby the conductor 240a and the conductor 240b each having a flat top surface can be formed (see FIGS. 1A to 1D). The CMP treatment may remove part of the top surface of the insulator 283.

When the conductor 240a is provided in contact with the conductor 242a in this manner, the conductor 240a functioning as one of the source and the drain of the transistor 200 can be electrically connected to a wiring. When the conductor 240b is provided in contact with the conductor 242b, the conductor 240b functioning as the other of the source and the drain of the transistor 200 can be electrically connected to a wiring.

Note that a conductive film functioning as a wiring or a conductive film functioning as a plug can be formed over the conductor 240a and the conductor 240b.

Through the above steps, the semiconductor device illustrated in FIGS. 1A to 1D can be fabricated.

### Example 2 of Method for Fabricating Semiconductor Device

An example of a method for fabricating the semiconductor device of one embodiment of the present invention will be described with reference to FIGS. 27A to 27D and FIGS. 28A to 28D. Here, the case of fabricating the semiconductor device illustrated in FIGS. 6A to 6D will be described as an example.

A substrate (not illustrated) is prepared, and the insulator 215, the insulator 216, the insulator 221, the insulator 222, and the insulator 224 are formed in this order over the substrate. Subsequently, the insulator 224b is formed over the insulator 224 (see FIGS. 27A to 27D).

Next, the layer 293 and the layer 292 are formed over the insulator 224b (see FIGS. 27A to 27D).

Then, an oxide semiconductor film to be the oxide semiconductor 230 is formed to cover the layer 293 and the layer 292 and part of the film is removed by anisotropic etching, so that the oxide semiconductor 230 is formed in contact with the side surfaces of the layer 293 and the layer 292 (see FIGS. 27A to 27D).

Next, the layer 292 is removed (see FIGS. 28A to 28D). At this time, the insulator 224b is preferably formed using a material with a low etching rate in the etching treatment for removing the layer 292.

The insulator 224b can be formed using any of the materials given as examples of the materials for the insulator 222, for example. A hard-to-etch material such as hafnium oxide can be suitably used as an etching stopper at the time of removing the layer 292, for example.

Next, the layer 293 is removed. Then, with reference to FIGS. 21A to 21D, FIGS. 22A to 22D, FIGS. 23A to 23D, FIGS. 24A to 24D, FIGS. 25A to 25D, and FIGS. 26A to 26D, the conductor 242a, the conductor 242b, the insulator 250, the conductor 260, and the like are formed over the oxide semiconductor 230 and the insulator 224b, whereby the semiconductor device illustrated in FIGS. 6A to 6D can be fabricated.

### Structure Example 2 of Semiconductor Device

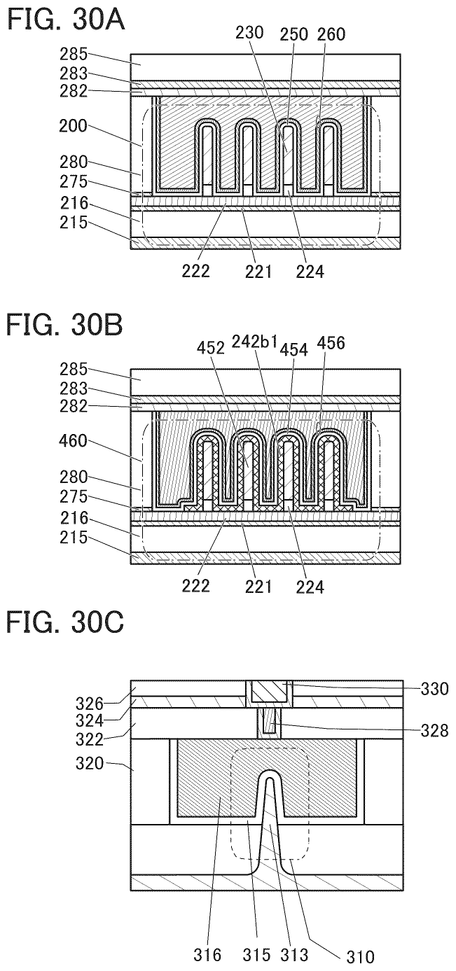

FIG. 29 illustrates a structure example in which the transistor 200, the capacitor 460, and a transistor 310 formed on a silicon substrate function as a 2T1C (two transistors and one capacitor) memory cell. As illustrated in FIG. 29, a layer including the transistor 200 and the capacitor 460 can be provided over a layer including the transistor 310. FIG. 30A is a cross-sectional view of the transistor 200 in the channel width direction, FIG. 30B is a cross-sectional view of the capacitor 460 in the channel width direction of the transistor 200, and FIG. 30C is a cross-sectional view of the transistor 310 in the channel width direction.

The transistor 310 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 310 may be either a p-channel transistor or an n-channel transistor. As the substrate 311, a single crystal silicon substrate can be used, for example.

In the transistor 310, the semiconductor region 313 (part of the substrate 311) in which a channel is formed has a convex shape as illustrated in FIG. 30C. The conductor 316 is provided to cover the top and side surfaces of the semiconductor region 313 with the insulator 315 therebetween. Note that the conductor 316 may be formed using a material for adjusting the work function. The transistor 310 is also referred to as a fin-type transistor because it utilizes a projection of the semiconductor substrate. An insulator functioning as a mask for forming the projecting may be provided in contact with the top surface of the projecting. Although the case where the projection is formed by processing part of the semiconductor substrate is described here, a semiconductor film having a projection may be formed by processing an SOI substrate.

Note that the transistor 310 illustrated in FIG. 29 is an example and the structure is not limited thereto; an appropriate transistor can be used in accordance with a circuit structure or a driving method.

Wiring layers including an interlayer film, a wiring, a plug, and the like may be provided between the components. A plurality of wiring layers can be provided in accordance with the design. In this specification and the like, a wiring and a plug electrically connected to the wiring may be a single component. That is, part of a conductor functions as a wiring in some cases and part of a conductor functions as a plug in other cases.

An insulator 320, an insulator 322, an insulator 324, and an insulator 326 are sequentially stacked over the transistor 310 as interlayer films, for example. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as interlayer films may function as a planarization film that covers a roughness thereunder. For example, the top surface of the insulator 322 may be planarized by planarization treatment using a chemical mechanical polishing (CMP) method or the like to improve planarity.

The transistor 200 and the capacitor 460 are provided over the insulator 326. The transistor 200 illustrated in FIG. 11C is used as the transistor 200 here. The structures of the transistor 200 and the layer including the transistor 200 are the same as those described above and thus are denoted by similar hatching patterns and reference numerals. Refer to the above description for the detailed structures. Note that an insulator 285 is formed over the insulator 283, and a conductor 413 electrically connected to the conductor 240a is formed over the insulator 285. The insulator 285 can be formed using any of the insulating materials that can be used for the insulator 216. The conductor 413 can be formed using any of the conductive materials that can be used for the conductor 242.

The capacitor 460 includes an oxide semiconductor 452, the conductor 242b1 over the oxide semiconductor 452, an insulator 454 over the conductor 242b1, and a conductor 456 over the insulator 454. As illustrated in FIG. 29 and FIGS. 30A and 30B, the oxide semiconductor 452 has a structure similar to that of the oxide semiconductor 230 and thus can be formed in the same step as the oxide semiconductor 230. The conductor 242b1 is shared by the transistor 200 and the capacitor 460. The insulator 454 has a structure similar to that of the insulator 250 and thus can be formed in the same step as the insulator 250. The conductor 456 has a structure similar to that of the conductor 260 and thus can be formed in the same step as the conductor 260.

In the case where the transistor 200 and the capacitor 460 illustrated in FIG. 29 are formed in parallel, etching treatment for the conductor to be the conductor 242b1 is not performed in a region overlapping with the oxide semiconductor 452 of the capacitor 460 so that the oxide semiconductor 452 is covered with the conductor 242b1. Accordingly, the capacitor 460 including the conductor 242b1, the insulator 454, and the conductor 456 can be formed in parallel with the transistor 200.

Here, the capacitor 460 includes the conductor 242b1 functioning as a first electrode, the conductor 456 functioning as a second electrode, and the insulator 454 functioning as a dielectric. That is, the capacitor 460 is a metal-insulator-metal (MIM) capacitor.

The capacitor 460 has a structure similar to that of the transistor 200 and can be formed in parallel with and in the same layer as the transistor 200. Thus, the insulator 454 and the conductor 456 are provided in an opening formed in the insulator 280 and the insulator 275. Note that the capacitor 460 differs from the transistor 200 in that the conductor 242b1 is provided to overlap with the conductor 456 and the insulator 454. Hence, the opening reaches the conductor 242b1, and the insulator 454 is in contact with the top surface of the conductor 242b1 in the opening.

As illustrated in FIG. 30B, the oxide semiconductor 452 of the capacitor 460 has a high aspect ratio like the oxide semiconductor 230; thus, a plurality of oxide semiconductors 452 can be provided. Hence, as in the oxide semiconductor 230, the height of the oxide semiconductor 452 is greater than the width thereof in a cross-sectional view in the channel width direction. In addition, as in the case of the oxide semiconductor 230, there are two or more regions where the oxide semiconductor 452 and the conductor 456 overlap with each other in a top view. This can increase the area where the conductor 242b1, the insulator 454, and the conductor 456, which are provided along the top and side surfaces of the oxide semiconductor 452, face each other. Accordingly, the capacitance can be increased without a significant increase in the area occupied by the capacitor 460.

A conductor 458 is preferably provided in an opening formed in the insulator 215, the insulator 216, and the insulator 221. The conductor 458 can have a structure similar to that of the conductor 240, for example. The top surface of the conductor 458 is in contact with the bottom surface of the conductor 242b1 so that the conductor 242b1 can be electrically connected to the conductor 330. Although one conductor 458 is illustrated in FIG. 29, the present invention is not limited thereto, and the conductor 242b1 and the conductor 330 may be electrically connected to each other through two or more conductors. Furthermore, part of the conductor 242b1 may be embedded in the opening formed in the insulator 215, the insulator 216, and the insulator 221.

With the above structure, one of the source and the drain of the transistor 200, one electrode of the capacitor 460, and the gate of the transistor 310 can be electrically connected to each other to form a 2T1C memory cell. Note that a 1T1C memory cell can also be formed when the transistor 310 is not provided. A 2T0C memory cell can also be formed when the capacitor 460 is not provided.

The transistor 310 is preferably provided to overlap with at least one of the transistor 200 and the capacitor 460. For example, the transistor 310 overlaps with the transistor 200. Such a structure can reduce the area occupied by the memory cell.

Although the transistor 200 includes the oxide semiconductor 230 and the capacitor 460 includes the oxide semiconductor 452 in FIG. 29, the present invention is not limited thereto. For example, as illustrated in FIG. 30B, the insulator 250, the conductor 260, the insulator 454, and the conductor 456 may be formed over the oxide semiconductor 230. That is, the transistor 200 and the capacitor 460 may share the oxide semiconductor 230. This eliminates the need for patterning the oxide semiconductor 230 separately for the transistor 200 and the capacitor 460, thereby reducing the area occupied by the transistor 200 and the capacitor 460.

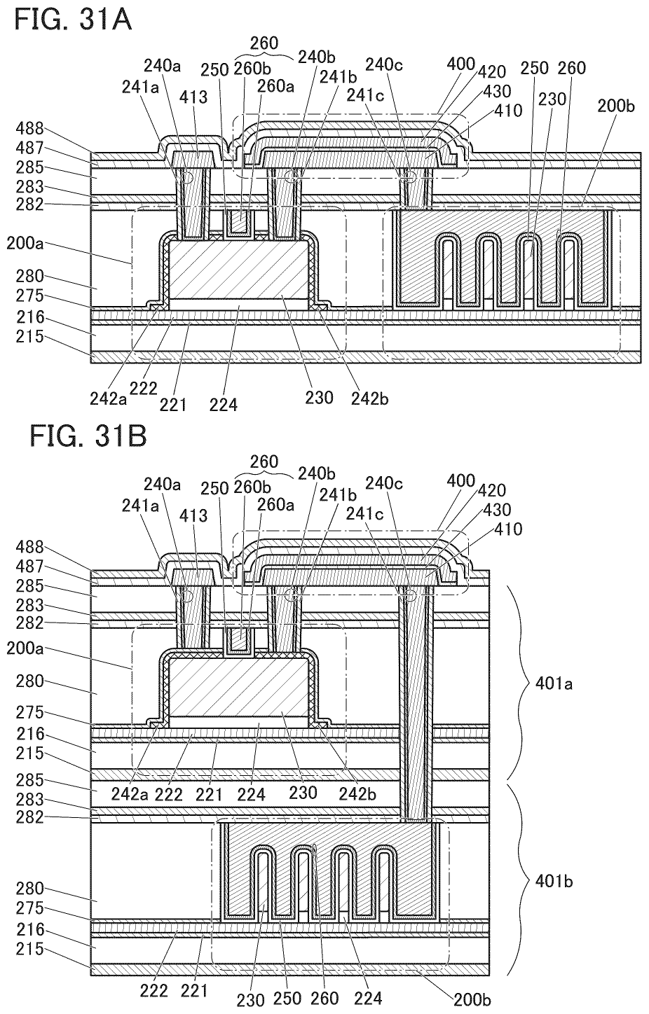

Although the transistor 310 formed on the silicon substrate is provided in FIG. 29, the present invention is not limited thereto. For example, as illustrated in FIG. 31A, two transistors (hereinafter, referred to as a transistor 200a and a transistor 200b) having structures similar to that of the transistor 200 may be provided. Note that the transistor 200a and the transistor 200b are formed in the same layer and provided such that their channel length directions intersect with each other. Since the transistor 200a and the transistor 200b have the structures similar to that of the transistor 200, their components are denoted by hatching patterns and reference numerals similar to those for the components of the transistor 200. Refer to the above description for the detailed structures.

In the structure illustrated in FIG. 31A, a capacitor 400 is provided over the insulator 285. The capacitor 400 includes a conductor 410 over the insulator 285, an insulator 430 over the conductor 410, and a conductor 420 over the insulator 430. The conductor 240b, the insulator 241b, a conductor 240c, and an insulator 241c are provided in contact with the bottom surface of the conductor 410. The conductor 240c and the insulator 241c are formed to fill an opening in the insulator 282, the insulator 283, and the insulator 285 and have structures similar to those of the conductor 240b and the insulator 241b. The bottom surface of the conductor 240c is in contact with the top surface of the conductor 260 of the transistor 200b. With such a structure, one of a source and a drain of the transistor 200a, one electrode of the capacitor 400, and a gate of the transistor 200b are electrically connected to each other.

The capacitor 400 includes the conductor 410 functioning as a first electrode, the conductor 420 functioning as a second electrode, and the insulator 430 functioning as a dielectric. That is, the capacitor 400 is a MIM capacitor.

The conductor 410 and the conductor 420 are formed using any of the conductive materials that can be used for the conductor 260. For example, the conductor 410 and the conductor 420 can be formed using tungsten. When the conductor 420 covers the conductor 410, a region sandwiched between the side surface of the conductor 410 and the conductor 420 can function as the capacitor 400. This can increase the capacitance of the capacitor 400. The conductor 413 can be formed at the same time as the conductor 410.

Although the conductor 410, the conductor 413, and the conductor 420 each have a single-layer structure, the present invention is not limited thereto, and the conductors may each have a stacked-layer structure of two or more layers. For example, a stacked-layer structure of a conductor having a barrier property and a conductor having high conductivity may be employed. For example, a stacked-layer structure of titanium nitride and tungsten over the titanium nitride can be employed.

The insulator 430 of the capacitor 400 is preferably formed using a high-k material. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium. Using such a high-k material allows the insulator 430 to be thick enough to inhibit leakage current and the capacitor 400 to have an adequately high capacitance. Since the insulator 430 is formed to cover the conductor 410, the insulator 430 is preferably formed by a formation method that offers excellent coverage, such as an ALD method or a CVD method.

The insulator 430 may have a stacked-layer structure. It is preferable to employ a stacked-layer structure of a high-k material and a material having higher dielectric strength than the high-k material. Examples of the material having high dielectric strength (a material having a low dielectric constant) include silicon oxide, silicon oxynitride, silicon nitride oxide, silicon nitride, silicon oxide to which fluorine is added, silicon oxide to which carbon is added, and silicon oxide to which carbon and nitrogen are added. The insulator 430 can have a stacked-layer structure of aluminum oxide, which is a high-k material, and silicon oxide having high dielectric strength over the aluminum oxide.

As the insulator 430, for example, an insulator in which zirconium oxide, aluminum oxide, and zirconium oxide are stacked in this order can be used. For another example, an insulator in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor 400.

A material that can show ferroelectricity may be used for the insulator 430. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a x-alumina-type structure.

Although metal oxides and metal nitrides are described above as examples, one embodiment of the present invention is not limited thereto. For example, a metal oxynitride in which nitrogen is added to any of the above-described metal oxides, a metal nitride oxide in which oxygen is added to any of the above-described metal nitrides, or the like may be used.

As the material that can show ferroelectricity, a mixture or compound containing a plurality of materials selected from the above-listed materials can be used, for example. Alternatively, the insulator 430 can have a stacked-layer structure of a plurality of materials selected from the above-listed materials. Since the above-listed materials and the like may change their crystal structures (characteristics) according to a variety of processes and the like as well as film formation conditions, a material that exhibits ferroelectricity is referred to not only as a ferroelectric but also as a material that can show ferroelectricity in this specification and the like.

Although the capacitor 400 of the memory device illustrated in FIG. 31A is a plate capacitor, the capacitor 400 of the memory device described in this embodiment is not limited thereto. For example, the capacitor 400 may have a cylindrical shape or a pillar shape.

An insulator 487 is provided to cover the capacitor 400, and an insulator 488 is provided to cover the insulator 487. An insulator having a function of capturing or fixing hydrogen is preferably used as the insulator 487. For example, aluminum oxide is used as the insulator 487. An insulator having a function of inhibiting hydrogen diffusion is preferably used as the insulator 488. For example, silicon nitride having a higher hydrogen barrier property is used as the insulator 488.

Although the transistor 200a and the transistor 200b are provided in the same layer in FIG. 31A, the present invention is not limited thereto. For example, as illustrated in FIG. 31B, a layer 401a including the transistor 200a may be stacked over a layer 401b including the transistor 200b. Note that the layer 401a and the layer 401b have structures similar to those of the layers including the components from the insulator 215 up to the insulator 285 illustrated in FIG. 31A.

As illustrated in FIG. 31B, the conductor 240c and the insulator 241c are formed in the opening provided in the insulators 282, 283, and 285 in the layer 401b and the insulators 215, 216, 275, 280, 282, 283, and 285 in the layer 401a. With such a structure, the conductor 410 of the capacitor 400 and the conductor 260 of the transistor 200b can be electrically connected to each other. Note that the conductor 410 and the conductor 260 of the transistor 200b are not necessarily connected to each other only through the conductor 240c. The conductor 410 and the conductor 260 of the transistor 200b may be electrically connected to each other through two or more conductors.

The transistor 200b is preferably provided to overlap with at least one of the transistor 200a and the capacitor 400. For example, the oxide semiconductor 230 of the transistor 200b is preferably provided to overlap with at least one of the oxide semiconductor 230 of the transistor 200a and the conductor 410 of the capacitor 400. Such a structure can reduce the area occupied by the memory cell.

This embodiment can be combined with any of the other embodiments as appropriate. In this specification, in the case where a plurality of structure examples are described in one embodiment, the structure examples can be combined as appropriate.

### Embodiment 2

In this embodiment, a semiconductor device 900 of one embodiment of the present invention will be described. The semiconductor device 900 can function as a memory device.

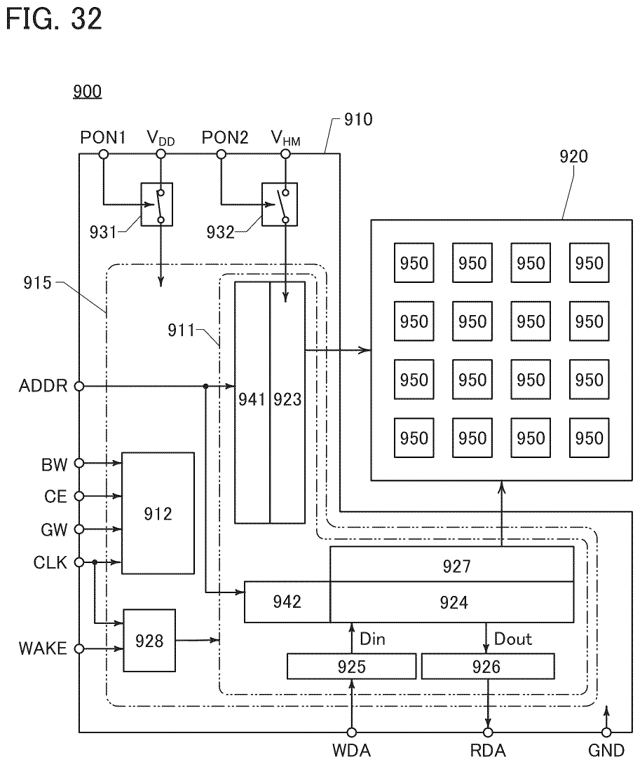

FIG. 32 is a block diagram illustrating a structure example of the semiconductor device 900. The semiconductor device 900 illustrated in FIG. 32 includes a driver circuit 910 and a memory array 920. The memory array 920 includes at least one memory cell 950. FIG. 32 illustrates an example in which the memory array 920 includes a plurality of memory cells 950 arranged in a matrix.

The transistor exemplified in Embodiment 1 can be used for the memory cell 950. With the use of the transistor, the operating speed of the memory device can be improved. This also enables scaling down and higher integration of the memory device. This also enables a higher capacity per area of the memory device.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is write data, and the signal RDA is read data. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is supplied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925 (Input Cir.), an output circuit 926 (Output Cir.), and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has functions of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling supply of V_{DD} to the peripheral circuit 915. The PSW 932 has a function of controlling supply of V_{HM} to the row driver 923. Here, in the semiconductor device 900, a high power supply voltage is V_{DD} and a low power supply voltage is GND (ground potential). In addition, V_{HM} is a high power supply voltage used for setting a word line at a high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 32 but can be more than one. In that case, a power switch is provided for each power domain.

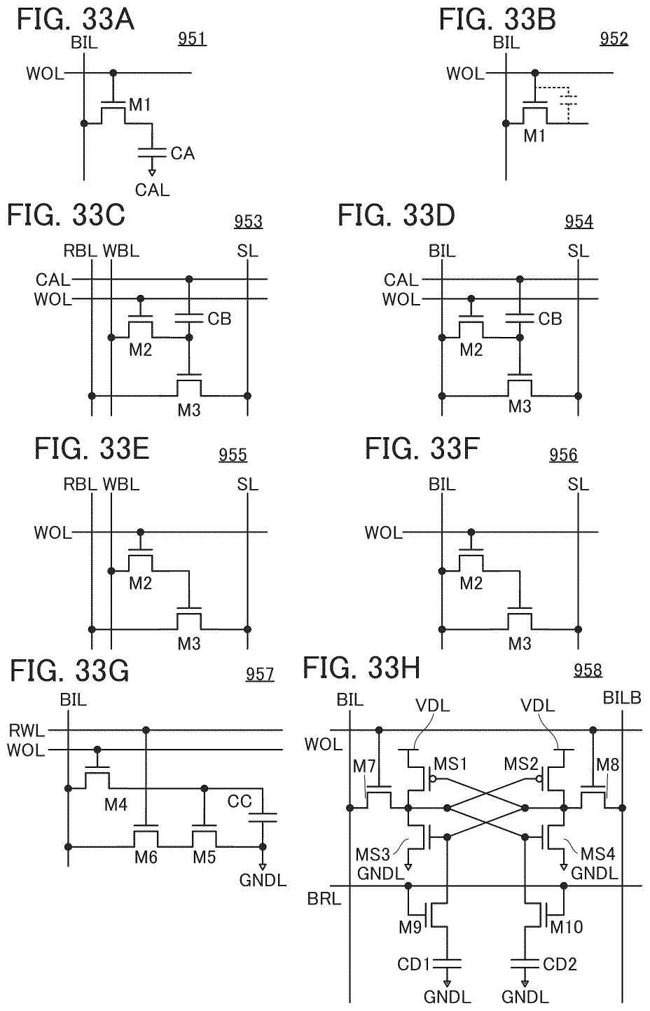

Structure examples of other memory cells each of which can be used as the memory cell 950 will be described with reference to FIGS. 33A to 33H.

### [DOSRAM]

FIG. 33A illustrates a circuit structure example of a memory cell for a DRAM. In this specification and the like, a DRAM including an OS transistor is referred to as a dynamic oxide semiconductor random access memory (DOSRAM). A memory cell 951 includes a transistor M1 and a capacitor CA.

Note that the transistor M1 may include a front gate (simply referred to as a gate in some cases) and aback gate. Here, the back gate may be connected to a wiring supplied with a constant potential or a signal, or the front gate and the back gate may be connected to each other.

A first terminal of the transistor M1 is connected to a first terminal of the capacitor CA. A second terminal of the transistor M1 is connected to a wiring BIL. The gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (referred to as a reference potential in some cases) is preferably applied to the wiring CAL.

Data writing and reading are performed as follows: a high-level potential is applied to the wiring WOL to turn on the transistor M1 so that the wiring BIL is connected to the first terminal of the capacitor CA.

The memory cell that can be used as the memory cell 950 is not limited to the memory cell 951, and the circuit structure can be changed. For example, the structure of a memory cell 952 illustrated in FIG. 33B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. With such a structure, the structure of the memory cell can be greatly simplified.

Note that the OS transistor described in Embodiment 1 is preferably used as the transistor M1. Here, the OS transistor refers to, for example, a transistor including an oxide semiconductor (OS). For example, the transistor 200 and the capacitor 460 illustrated in FIG. 29 can be respectively used as the transistor M1 and the capacitor CA of the memory cell 951. For another example, the transistor 200a and the capacitor 400 illustrated in FIG. 31A or 31B can be respectively used as the transistor M1 and the capacitor CA of the memory cell 951. With the use of the OS transistor described in Embodiment 1, the operating speed of the memory device can be increased. Furthermore, the area occupied by the memory cell can be reduced. The OS transistor has a characteristic of an extremely low off-state current. The use of the OS transistor as the transistor M1 enables an extremely low leakage current of the transistor M1. That is, with the use of the transistor M1, written data can be retained for a long time; thus, the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 33C illustrates a circuit structure example of a gain-cell memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to a wiring SL. Agate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (referred to as a reference potential in some cases) is preferably applied to the wiring CAL.

Data writing is performed as follows: a high-level potential is applied to the wiring WOL to turn on the transistor M2 so that the wiring WBL is connected to the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by application of a predetermined potential to the wiring SL. Current flowing between the source and the drain of the transistor M3 and the potential of the first terminal of the transistor M3 are determined by the potential of the gate of the transistor M3 and the potential of the second terminal of the transistor M3. Accordingly, by reading the potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

For another example, one wiring BIL may be provided instead of the wiring WBL and the wiring RBL. A circuit structure example of the memory cell is illustrated in FIG. 33D. In a memory cell 954, one wiring BIL is provided instead of the wiring WBL and the wiring RBL in the memory cell 953, and the second terminal of the transistor M2 and the first terminal of the transistor M3 are connected to the wiring BIL. In other words, one wiring BIL operates as the write bit line and the read bit line in the memory cell 954.

A memory cell 955 illustrated in FIG. 33E is an example in which the capacitor CB and the wiring CAL in the memory cell 953 are omitted. A memory cell 956 illustrated in FIG. 33F is an example in which the capacitor CB and the wiring CAL in the memory cell 954 are omitted. Such structures enable high integration of the memory cells.

Note that the OS transistor described in Embodiment 1 is preferably used as at least the transistor M2. For example, the transistor 200, the transistor 310, and the capacitor 460 illustrated in FIG. 29 can be respectively used as the transistor M2, the transistor M3, and the capacitor CB of each of the memory cell 953 and the memory cell 954. It is particularly preferable to use the OS transistor described in Embodiment 1 as each of the transistor M2 and the transistor M3. For example, the transistor 200a, the transistor 200b, and the capacitor 400 illustrated in FIG. 31A or 31B can be respectively used as the transistor M2, the transistor M3, and the capacitor CB of each of the memory cell 953 and the memory cell 954. With the use of the OS transistor described in Embodiment 1, the operating speed of the memory device can be increased. Furthermore, the area occupied by the memory cell can be reduced.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When the OS transistor is used as the transistor M3, the memory cell can be configured with the transistors having the same conductivity type.

FIG. 33G illustrates a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is electrically connected to a first terminal of the transistor M5 and a wiring GNDL. A second terminal of the transistor M5 is connected to a first terminal of the transistor M6. Agate of the transistor M5 is connected to the first terminal of the capacitor CC. A second terminal of the transistor M6 is connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed as follows: a high-level potential is applied to the wiring WOL to turn on the transistor M4 so that the wiring BIL is connected to the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that the wiring BIL is electrically connected to the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that the OS transistor described in Embodiment 1 is preferably used as at least the transistor M4. With the use of the OS transistor described in Embodiment 1, the area occupied by the memory cell can be reduced.

Note that Si transistors may be used as the transistors M5 and M6. As described above, a Si transistor may have higher field-effect mobility than an OS transistor depending on the crystal state of silicon used in a semiconductor layer, for example.

When OS transistors are used as the transistors M5 and M6, the memory cell can be configured with the transistors having the same conductivity type.

### [OS-SRAM]

FIG. 33H illustrates an example of a static random access memory (SRAM) including an OS transistor. In this specification and the like, an SRAM including an OS transistor is referred to as an oxide semiconductor SRAM (OS-SRAM). A memory cell 958 illustrated in FIG. 33H is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. Agate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. Agate of the transistor M8 is connected to the wiring WOL.

A second terminal of the transistor MS1 is electrically connected to a wiring VDL. A second terminal of the transistor MS2 is electrically connected to the wiring VDL. A second terminal of the transistor MS3 is electrically connected to the wiring GNDL. A second terminal of the transistor MS4 is electrically connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. Agate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential that has been applied to the wiring BIL (i.e., the signal that has been input to the wiring BIL) is output to the wiring BILB. Since the transistors M9 and M10 are on, the potential of the second terminal of the transistor M7 is retained in the first terminal of the capacitor CD2, and the potential of the second terminal of the transistor M8 is retained in the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed by precharging the wiring BIL and the wiring BILB with a predetermined potential, and then applying a high-level potential to the wiring WOL and the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that OS transistors are preferably used as the transistors M7 to M10. In that case, with the use of the transistors M7 to M10, written data can be retained for a long time, and thus the frequency of refresh operation for the memory cell can be decreased. Alternatively, refresh operation for the memory cell can be omitted. When the OS transistor described in Embodiment 1 is used as each of the transistors M7 to M10, the operating speed of the memory device can be improved. Furthermore, the area occupied by the memory cell can be reduced.

Note that Si transistors may be used as the transistors MS1 to MS4.

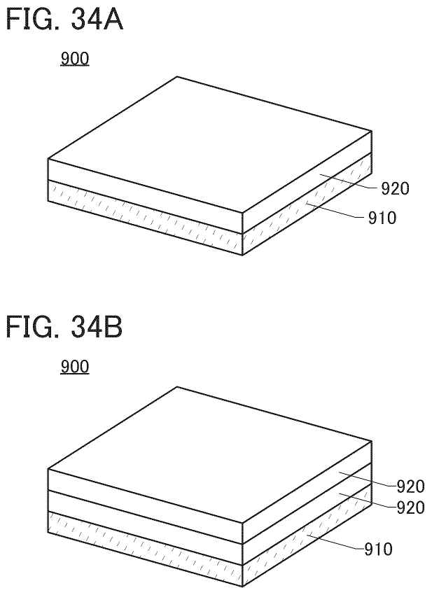

The driver circuit 910 and the memory array 920 included in the semiconductor device 900 may be provided on the same plane. Alternatively, as illustrated in FIG. 34A, the driver circuit 910 and the memory array 920 may be provided to overlap with each other. Providing the driver circuit 910 and the memory array 920 to overlap with each other can shorten a signal propagation distance. As illustrated in FIG. 34B, a plurality of memory arrays 920 may be stacked over the driver circuit 910.

In the above memory array 920, a plurality of memory arrays 920[1] to 920[m] can be stacked. The memory arrays 920[1] to 920[m] included in the memory array 920 are provided in a direction perpendicular to a surface of a substrate on which the driver circuit 910 is provided, in which case the memory density of the memory cells 951 can be increased. The memory arrays 920 can be formed by repeating the same manufacturing process in the vertical direction. The manufacturing cost of the memory array 920 in the semiconductor device 900 can be reduced.

Next, description is made on an example of an arithmetic processing device that can include the semiconductor device, such as the memory device described above.

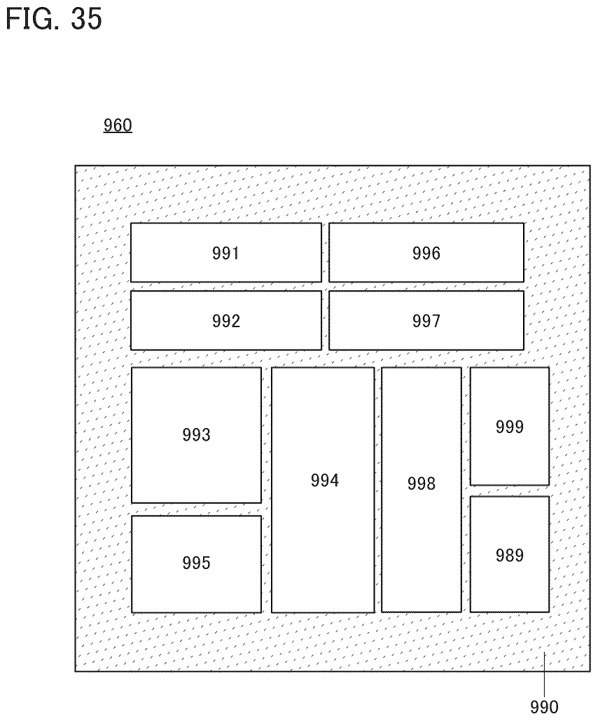

FIG. 35 is a block diagram of an arithmetic device 960. The arithmetic device 960 illustrated in FIG. 35 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 35 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in that case, the driver circuit 910 is preferably included in part of the cache interface 989.

Note that it is also possible that the cache 999 is not provided and only the memory array 920 is used as a cache.

The arithmetic device 960 illustrated in FIG. 35 is only an example with a simplified structure, and the actual arithmetic device 960 has a variety of structures depending on the application. For example, what is called a multicore structure is preferably employed in which a plurality of cores each including the arithmetic device 960 in FIG. 35 operate in parallel. The larger number of cores can further enhance the arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 35, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, power supply voltage is supplied to the memory cell in the register 996. When data retention by the capacitor is selected, the data is rewritten into the capacitor, and supply of power supply voltage to the memory cell in the register 996 can be stopped.

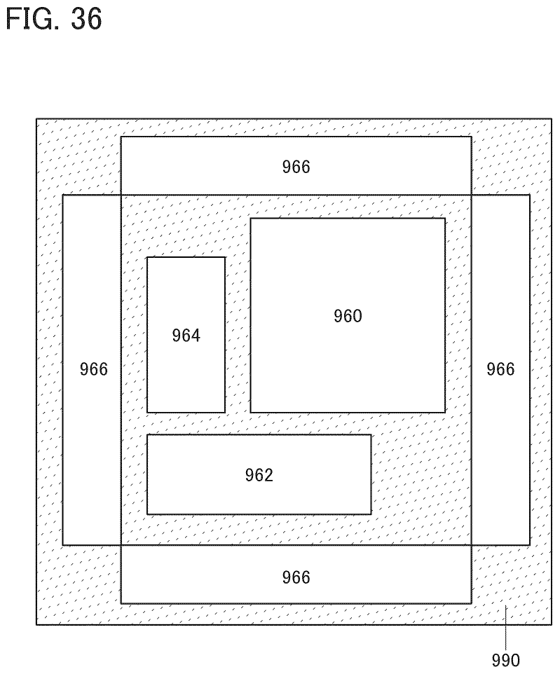

FIG. 36 illustrates an example in which not only the arithmetic device 960 but also a memory device 962, an interface circuit 964, input/output portions 966, and the like are provided over the substrate 990.

The memory device 962 can be used as a main memory or a cache at a lower level than the cache 999. The memory device 962 is connected to the cache interface 989 in the arithmetic device 960 through the interface circuit 964. The memory device 962 is connected to a main memory provided in another chip through the interface circuit 964 and the input/output portions 966.

The semiconductor device 900 including the memory array 920 can be used as the memory device 962.

The interface circuit 964 is provided with a variety of interface circuits and bus lines. The interface circuit 964 may also include a power supply circuit, a clock generation circuit, or the like.

An inter-integrated circuit (I2C), a serial peripheral interface (SPI), a general-purpose input/output (GPIO), or the like can be provided in the interface circuit 964, for example.

The input/output portions 966 each include an input portion to which a signal, a potential, and the like are input from the outside and an output portion from which a signal is output to the outside. The input/output portion 966 includes a plurality of connection terminals and is connected to a substrate different from the substrate 990 through a connection wiring. The input/output portion 966 may also include a buffer circuit, a protection circuit, or the like.

As a method for connecting the substrate 990 to another substrate, wire bonding using a gold or copper wiring, flip-chip bonding using a bump, direct bonding (hybrid bonding) using a direct bonding technique such as Cu-to-Cu bonding, or the like can be used. Alternatively, as a bonding method not using a substrate, a method may be used in which two or more layers are bonded to each other with insulating films and then a through electrode is formed to connect electrodes and the like provided in the layers. It is particularly preferable to use the direct bonding or the method using a through electrode, in which case the pitch between the connection electrodes can be extremely narrow, enabling an enormous number of connection electrodes to be arranged at high density and the amount of data transmitted between the layers to be increased.

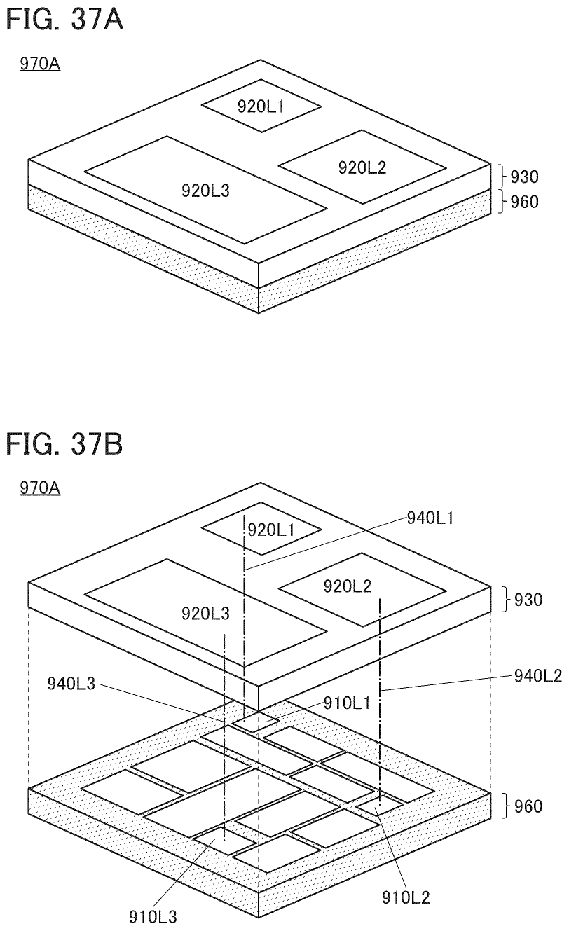

The memory array 920 and the arithmetic device 960 can be provided to overlap with each other. FIGS. 37A and 37B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 37B.

Providing the arithmetic device 960 and the layer 930 including the memory arrays to overlap with each other can shorten the connection distance therebetween. Accordingly, the communication speed therebetween can be increased. Moreover, a short connection distance leads to lower power consumption.

As a method for stacking the arithmetic device 960 and the layer 930 including the memory arrays, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu-to-Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In that case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has a higher capacity and a lower access frequency than the cache.

As illustrated in FIG. 37B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 989 or may be connected to the cache interface 989. Similarly, each of the driver circuits 910L2 and 910L3 may function as part of the cache interface 989 or may be connected to the cache interface 989.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

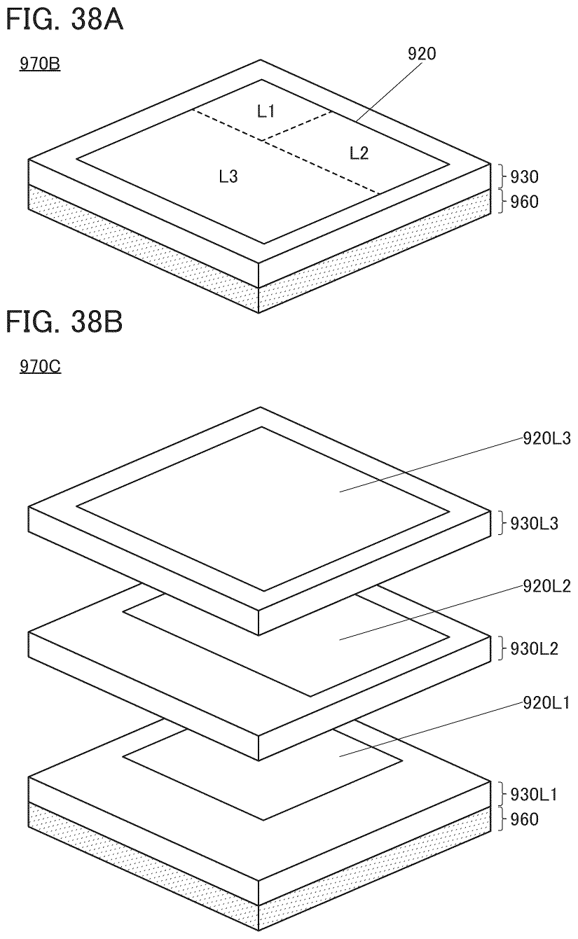

The layer 930 including one memory array 920 may be provided to overlap with the arithmetic device 960. FIG. 38A is a perspective view of a semiconductor device 970B.

In the semiconductor device 970B, one memory array 920 can be divided into a plurality of areas having different functions. FIG. 38A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 38B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

Note that this embodiment can be combined with any of the other embodiments in this specification as appropriate.

### Embodiment 3

In this embodiment, application examples of the memory device of one embodiment of the present invention will be described.

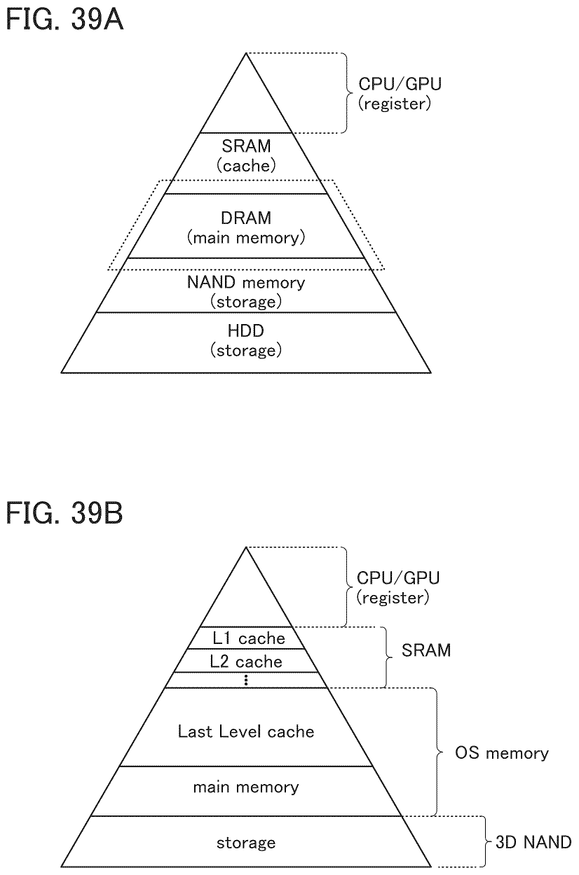

First, the hierarchy of memory devices used for a semiconductor device is described. FIG. 39A shows a conventional hierarchy of memory devices.

In FIG. 39A, the memory devices closer to a processor (e.g., a CPU or a GPU) are accessed more frequently, and a longer length of the bottom of a region means a higher data capacity. The memory devices closer to the processor require a higher operating speed, whereas the memory devices farther from the processor require a higher memory capacity and a higher memory density. In FIG. 39A, a register is shown as a memory included in the processor such as a CPU or a GPU, an SRAM is shown as a cache memory, a DRAM is shown as a main memory, and a NAND memory and a hard disk drive (HDD) are shown as storages, for example.

The memory included in the processor such as a CPU or a GPU is used for temporary storage of arithmetic operation results, for example, and thus is very frequently accessed by an arithmetic processing device. Accordingly, a high operating speed is required rather than a memory capacity. The register also has a function of retaining settings of the arithmetic processing device, for example.

The cache has a function of duplicating and retaining part of data retained in the main memory. Duplicating frequently used data and retaining the duplicated data in the cache facilitate rapid data access. The cache requires a lower memory capacity than the main memory, but requires a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be stored for a long time and programs used in the arithmetic processing device, for example. Thus, the storage needs to have a high memory capacity and a high recording density rather than an operating speed. For example, a high-capacity nonvolatile memory device such as an HDD or a NAND memory like a 3D NAND memory can be used.

In one embodiment of the present invention, at least the DRAM used as a main memory among the memory devices shown in FIG. 39A is replaced with a memory device including an oxide semiconductor (an OS memory). Since requiring refresh operation and performing destructive reading, the DRAM consumes much higher power than other memory devices. Thus, power consumption can be significantly reduced by not using the DRAM. Note that in FIG. 39A, the memory devices to be replaced with the OS memory are denoted by dashed lines. That is, not only the DRAM used as a main memory but also some of the SRAMs used as caches and some of the NAND memories used as storages can be replaced with the OS memory.

FIG. 39B shows an example of the semiconductor device of one embodiment of the present invention. FIG. 39B is a schematic view showing the hierarchy of various memory devices used in the semiconductor device.

FIG. 39B shows a plurality of caches (an L1 cache and an L2 cache) and a last level cache (LLC).

The L1 cache is at the highest level among the caches and followed by the L2 cache. The higher-level cache is accessed by the processor more frequently and thus is required to operate at higher speed. Since the operating speed can be increased by reducing the data capacity, the higher-level cache preferably has a lower data capacity. The higher-level cache is physically closer to the processor and thus preferably has a shorter wiring length. Therefore, the high-level cache is preferably provided in a layer where the processor is provided. The low-level cache may be provided in a layer different from the layer where the processor is provided.

The lowest-level cache can be referred to as an LLC. The LLC does not require a higher operating speed than a higher-level cache, but desirably has a high memory capacity. An after-mentioned OS memory of one embodiment of the present invention operates at high speed and can retain data for a long time, and thus can be suitably used as the LLC. Note that the OS memory of one embodiment of the present invention can also be used as a final level cache (FLC).

The SRAM can be used as the caches. The OS memory can be suitably used as the LLC and the main memory. The memory devices operate at high speed and can retain data for a long time.

In the structure described here, the DRAM that has been conventionally used as a main memory or the like is replaced with the OS memory of one embodiment of the present invention. With such a structure, the power consumption can be dramatically reduced (e.g., reduced to 1/100 or 1/1000 or less); thus, global expansion of information processing devices, such as computers and servers, having such a structure will greatly contribute to global warming mitigation.

Note that this embodiment can be combined with any of the other embodiments in this specification as appropriate.

### Embodiment 4

This embodiment describes an electronic component, an electronic device, a large computer, space equipment, and a data center (also referred to as DC) that can include any of the semiconductor devices described in the above embodiments. An electronic device, a large computer, space equipment, and a data center each employing the semiconductor device of one embodiment of the present invention are effective in improving performance, for example, reducing power consumption.

### [Electronic Device]

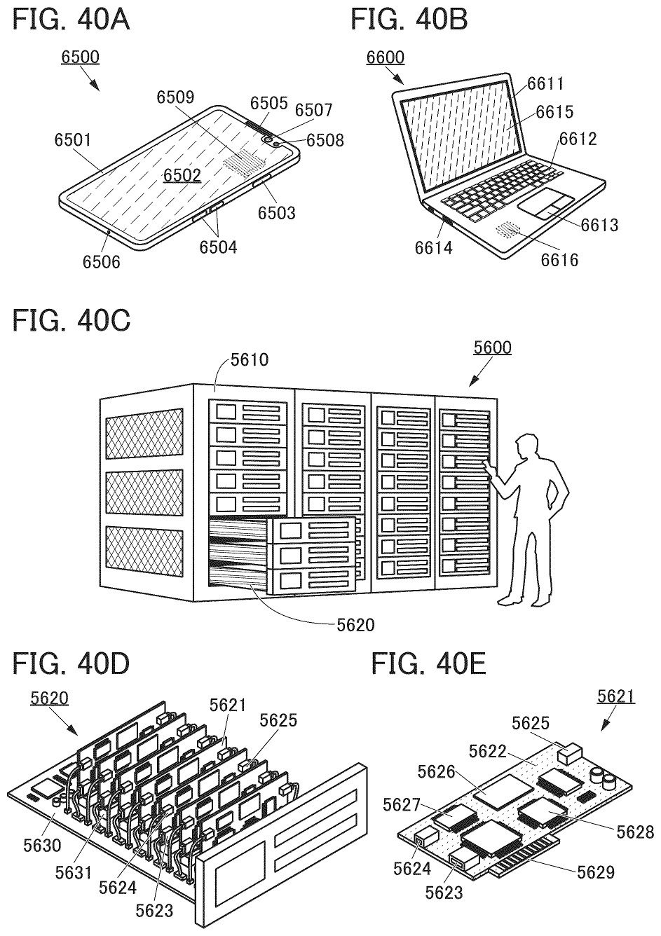

FIG. 40A is a perspective view of an electronic device 6500. The electronic device 6500 in FIG. 40A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic device 6600 illustrated in FIG. 40B is an information terminal that can be used as a laptop personal computer. The electronic device 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 40C is a perspective view of a large computer 5600. In the large computer 5600 illustrated in FIG. 40C, a plurality of rack mount computers 5620 are stored in a rack 5610. Note that the large computer 5600 may be referred to as a supercomputer.

The computer 5620 can have a structure illustrated in a perspective view in FIG. 40D, for example. In FIG. 40D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 40E is an example of a processing board provided with a CPU, a GPU, a memory device, and the like. The PC card 5621 includes a board 5622. The board 5622 includes the connection terminals 5623, 5624, and 5625, semiconductor devices 5626, 5627, and 5628, and a connection terminal 5629. FIG. 40E also illustrates semiconductor devices other than the semiconductor devices 5626, 5627, and 5628, and refer to the following description of the semiconductor devices 5626, 5627, and 5628 for these semiconductor devices.

The connection terminal 5629 has a shape enabling insertion of the connection terminal 5629 into the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can serve as, for example, interfaces for performing power supply, signal input, or the like to the PC card 5621. For another example, they can serve as interfaces for outputting signals calculated by the PC card 5621. Examples of the standards for the connection terminals 5623, 5624, and 5625 include USB, Serial ATA (SATA), and Small Computer System Interface (SCSI). In the case where video signals are output from the connection terminals 5623, 5624, and 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings on the board 5622, the semiconductor device 5627 and the board 5622 can be electrically connected to each other. Examples of the semiconductor device 5627 include an FPGA, a GPU, and a CPU.

The semiconductor device 5628 includes a plurality of terminals, and when the terminals are reflow-soldered, for example, to wirings on the board 5622, the semiconductor device 5628 and the board 5622 can be electrically connected to each other. An example of the semiconductor device 5628 is a memory device.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment such as devices processing and storing information.

The semiconductor device of one embodiment of the present invention can include an OS transistor. A change in electrical characteristics of the OS transistor due to exposure to radiation is small. That is, the OS transistor is highly resistant to radiation, and thus can be suitably used even in an environment where radiation can enter. For example, the OS transistor can be suitably used in outer space.

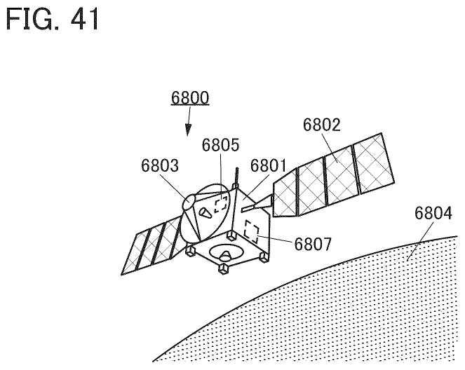

FIG. 41 illustrates an artificial satellite 6800 as an example of space equipment. The artificial satellite 6800 includes a body 6801, a solar panel 6802, an antenna 6803, a secondary battery 6805, and a control device 6807. In FIG. 41, a planet 6804 in outer space is illustrated. Note that outer space refers to, for example, space at an altitude greater than or equal to 100 km, and the outer space in this specification may also include thermosphere, mesosphere, and stratosphere.

Although not illustrated in FIG. 41, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the solar panel is irradiated with a slight amount of sunlight, the amount of generated electric power is small. Accordingly, a sufficient amount of electric power required for operation of the artificial satellite 6800 may be difficult to generate. In order to operate the artificial satellite 6800 even with a small amount of generated electric power, the artificial satellite 6800 is preferably provided with the secondary battery 6805. Note that such a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics of the OS transistor due to exposure to radiation is smaller than a change in electrical characteristics of a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of the space equipment in this embodiment, one embodiment of the present invention is not limited to this example. The semiconductor device of one embodiment of the present invention can be suitably used for space equipment such as a spacecraft, a space capsule, or a space probe, for example.

As described above, an OS transistor has excellent effects of a wide memory bandwidth and high resistant to radiation as compared with a Si transistor.

### [Data Center]

The semiconductor device of one embodiment of the present invention can be suitably used for, for example, a storage system in a data center or the like. The data center is required to perform long-term management of data such as guarantee of data immutability. In the case where data is managed for a long term, it is necessary to increase the scale of data center facility for installation of storages and servers for storing an enormous amount of data, stable electric power for data retention, cooling equipment for data retention, or the like.

With the use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be improved.

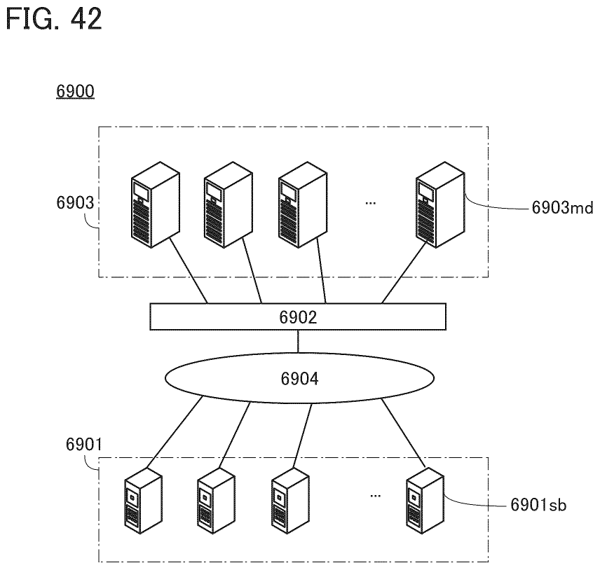

FIG. 42 illustrates a storage system that can be used in a data center. A storage system 6900 illustrated in FIG. 42 includes a plurality of servers 6901sb as a host 6901. The storage system 6900 includes a plurality of memory devices 6903md as a storage 6903. In the illustrated example, the host 6901 and the storage 6903 are connected to each other through a storage area network 6904 and a storage control circuit 6902.

The host 6901 corresponds to a computer which accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in the storage. In the storage system, in order to solve the problem of low access speed of the storage 6903, a cache memory is normally provided in the storage to shorten the time taken for data storage and output.

The above-described cache memory is used in the storage control circuit 6902 and the storage 6903. The data transmitted between the host 6901 and the storage 6903 is stored in the cache memories in the storage control circuit 6902 and the storage 6903 and then output to the host 6901 or the storage 6903.

The use of an OS transistor as a transistor for storing data in the cache memory to retain a potential corresponding to data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. Although there is a growing demand for more energy accompanying with higher performance and higher integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

The configurations, structures, methods, and the like described in this embodiment can be used in an appropriate combination with any of the configurations, structures, methods, and the like described in the other embodiments and the like.

This application is based on Japanese Patent Application Serial No. 2023-143046 filed with Japan Patent Office on Sep. 4, 2023, the entire contents of which are hereby incorporated by reference.

What is claimed is:

1. A method for fabricating a semiconductor device, comprising:
forming a first coating film over a first insulator and a second coating film over the first coating film;
forming a first layer by partly removing the second coating film;
forming a second layer by partly removing the first coating film using the first layer as a mask;
performing heat treatment;
forming a first oxide semiconductor to cover a top surface of the first insulator, a side surface of the second layer, and a side surface and a top surface of the first layer;
forming a second oxide semiconductor in contact with the side surface of the second layer by processing the first oxide semiconductor by anisotropic etching;
removing the first layer; and
exposing a side surface of the second oxide semiconductor covered with the second layer by removing the second layer.

2. The method for fabricating a semiconductor device, according to claim 1,
wherein the first coating film is an organic resin, and
wherein the second coating film comprises silicon, oxygen, and carbon.

3. The method for fabricating a semiconductor device, according to claim 1, wherein the first insulator is partly removed when the first layer is removed.

4. The method for fabricating a semiconductor device, according to claim 1, wherein the heat treatment is performed at higher than or equal to 200° C. and lower than or equal to 400° C.

5. The method for fabricating a semiconductor device, according to claim 1, wherein the second layer is removed by microwave treatment.

6. The method for fabricating a semiconductor device, according to claim 1,
wherein the first oxide semiconductor is formed through a step of forming a third oxide semiconductor, a step of forming a fourth oxide semiconductor over the third oxide semiconductor, and a step of forming a fifth oxide semiconductor over the fourth oxide semiconductor,
wherein the third oxide semiconductor and the fifth oxide semiconductor are formed by an ALD method using an oxidizer and a precursor comprising indium, and
wherein the fourth oxide semiconductor is formed by a sputtering method using a sputtering target comprising zinc.

7. A method for fabricating a semiconductor device, comprising:
forming a second insulator over a first insulator;
forming a first coating film over the second insulator and a second coating film over the first coating film;
forming a first layer by partly removing the second coating film;
forming a second layer by partly removing the first coating film using the first layer as a mask;
performing heat treatment;
forming a first oxide semiconductor to cover a top surface of the second insulator, a side surface of the second layer, and a side surface and a top surface of the first layer;
forming a second oxide semiconductor in contact with the side surface of the second layer by processing the first oxide semiconductor by anisotropic etching;
removing the first layer and a region of the second insulator overlapping with neither the second layer nor the second oxide semiconductor;
exposing a side surface of the second oxide semiconductor covered with the second layer by removing the second layer;
forming a first conductor to cover a top surface of the first insulator and a side surface of the second oxide semiconductor;
forming a third insulator over the first conductor;
forming an opening portion in the third insulator by partly removing the third insulator;
removing a region of the first conductor overlapping with the opening portion;
forming a fourth insulator over the third insulator and in the opening portion in the third insulator, wherein the fourth insulator is formed to cover a side surface of the second oxide semiconductor in the opening portion; and
forming a second conductor over the fourth insulator.

8. The method for fabricating a semiconductor device, according to claim 7,
wherein the first coating film is an organic resin, and
wherein the second coating film comprises silicon, oxygen, and carbon.

9. The method for fabricating a semiconductor device, according to claim 7, wherein the heat treatment is performed at higher than or equal to 200° C. and lower than or equal to 400° C.

10. The method for fabricating a semiconductor device, according to claim 7, wherein the second layer is removed by microwave treatment.
